(19) United States
(12) Patent Application Publication
(10) Pub. No.: US 2023/0422590 A1
(43) Pub. Date: Dec. 28, 2023

(54) PRESSURE ASSISTED FABRICATION OF SOLAR CELLS AND LIGHT EMITTING DEVICES

(71) Applicant: Worcester Polytechnic Institute, Worcester, MA (US)

(72) Inventors: Winston O. Soboyejo, Northborough, MA (US); Oluwaseun K. Oyewole, Worcester, MA (US); Deborah O. Oyewole, Worcester, MA (US); Omolara Oyelade, Worcester, MA (US); Sharafadeen Adeniji, Worcester, MA (US); Jaya Cromwell, Worcester, MA (US)

(73) Assignee: Worcester Polytechnic Institute, Worcester, MA (US)

(21) Appl. No.: 18/244,641

(22) Filed: Sep. 11, 2023

Related U.S. Application Data
(63) Continuation of application No. PCT/US2022/020063, filed on Mar. 11, 2022.
(60) Provisional application No. 63/159,693, filed on Mar. 11, 2021.

(51) Int. Cl. H10K 71/60; H10K 30/40; H10K 71/40

(52) U.S. Cl. CPC H10K 71/60; H10K 30/40; H10K 71/40; H10K 30/50

(57) ABSTRACT

Methods and systems for fabricating photovoltaic devices are provided. A method includes forming a photovoltaic device comprising an active layer with one or more interfacial layers adjacent the active layer, wherein the active layer comprises a photovoltaic material and the one or more interfacial layers comprise a material configured to collect charge carriers generated in the photovoltaic material; applying pressure onto the photovoltaic device to increase an amount of electrical contact between the active layer and the one or more interfacial layer; and annealing the photovoltaic device.

### RELATED APPLICATIONS

This application is a continuation of International PCT Application No. PCT/US2022/020063, filed Mar. 11, 2022, which claims the benefit of and priority to U.S. Provisional Patent Application No. 63/159,693, filed on Mar. 11, 2021, the entirety of this application is hereby incorporated herein by reference.

### FIELD

The present disclosure relates to a system and method suitable for the fabrication pressure-assisted processing of solar cells and light emitting devices. In particular, the present disclosure relates to fabricating perovskite solar cells and perovskite light emitting devices with improved efficiencies and performance.

### BACKGROUND

During fabrications of photovoltaic films, particles of silicone, silicon, silica, textile polymer and other organic materials of diameter ranging from ˜0.1 to 20 μm that are present in clean room environments can be embedded between the layers. The presence of these particles reduces the performance of the film. There is a need to combat this problem.

### SUMMARY

According to aspects illustrated herein, there is provided a method for fabricating photovoltaic devices, the method includes forming a photovoltaic device comprising an active layer with one or more interfacial layers adjacent the active layer, wherein the active layer comprises a photovoltaic material and the one or more interfacial layers comprise a material configured to collect charge carriers generated in the photovoltaic material; applying pressure onto the photovoltaic device to increase an amount of electrical contact between the active layer and the one or more interfacial layer; and annealing the photovoltaic device.

In some embodiments, the photovoltaic material is perovskite material. In some embodiments, the applying pressure comprises applying a pressure between 5 and 10 MPa. In some embodiments, the one or more interfacial layers comprise an electron transport layer in electrical contact with the active layer. In some embodiments, the photovoltaic device is annealed at a temperature between 140 and 160 Celsius. In some embodiments, applying pressure deforms the active layer around one or more interlayer particles disposed between the active layer and the one or more interfacial layers. In some embodiments, the pressure is determined based on a thickness of the active layer. In some embodiments, the efficiency of the photovoltaic device is increased between 10% and 15%. In some embodiments, the turn-on voltage of the photovoltaic device is reduced by 1 Volt. In some embodiments, the forming a photovoltaic device comprises: depositing, on a substrate, a first conductive layer; depositing, on the first conductive layer, a first interfacial layer comprising an electron transport material; depositing the active layer on the first interfacial layer; depositing, on the active layer, a second interfacial layer comprising a hole transport material; depositing, on the second interfacial layer, a second conductive layer on the hole transport layer, and wherein the pressure is applied after the second conductive layer is deposited to increase the amount of contact between the layers.

According to aspects illustrated herein, there is provided a system for fabricating photovoltaic devices comprising: a photovoltaic device comprising an active layer with one or more interfacial layers the active layer, wherein the active layer comprises a photovoltaic material and the one or more interfacial layers comprise a material configured to collect charge carriers generated in the photovoltaic material; a pressure applicator configured to apply pressure onto the photovoltaic device to increase an amount of electrical contact between the active layer and the one or more interfacial layer; and an oven configured to anneal the photovoltaic device.

In some embodiments, the photovoltaic material is perovskite material. In some embodiments, the pressure is between 5 and 10 MPA. In some embodiments, the one or more interfacial layers comprise an electron transport layer in electrical contact with the active layer. In some embodiments, the efficiency of the photovoltaic device is increased by up to 15%. In some embodiments, the photovoltaic device comprises: depositing, on a substrate, a first conductive layer; depositing, on the first conductive layer, a first interfacial layer comprising an electron transport material; depositing the active layer on the first interfacial layer; depositing, on the active layer, a second interfacial layer comprising a hole transport material; depositing, on the second interfacial layer, a second conductive layer on the hole transport layer, and wherein the pressure is applied after the second conductive layer is deposited to increase the amount of contact between the layers. In some embodiments, the photovoltaic device is annealed at a temperature between 140 and 160 Celsius.

According to aspects illustrated herein, there is provided a method for fabricating photovoltaic devices, the method comprising: forming a photovoltaic device comprising an active layer comprising perovskite material and one or more interfacial layers adjacent the active layer, wherein the active layer comprises a photovoltaic material and the one or more interfacial layers comprise a material configured to collect charge carriers generated in the photovoltaic material; applying pressure onto the photovoltaic device, the pressure being sufficient to deforms the active layer around one or more interlayer particles disposed between the active layer and the one or more interfacial layers to increase an amount of electrical contact between the active layer and the one or more interfacial layer; and annealing the photovoltaic device.

In some embodiments, applying pressure between 5 and 10 MPA comprises applying a pressure of 7 MPa. In some embodiments, the photovoltaic device is annealed at a temperature between 140 and 160 Celsius.

### BRIEF DESCRIPTION OF THE FIGURES

The presently disclosed embodiments will be further explained with reference to the attached drawings, wherein like structures are referred to by like numerals throughout the several views. The drawings shown are not necessarily to scale, with emphasis instead generally being placed upon illustrating the principles of the presently disclosed embodiments. Although the present disclosure will be described with reference to the example embodiment or embodiments illustrated in the figures, many alternative forms can embody the present disclosure. One of skill in the art will additionally appreciate different ways to alter the parameters of the embodiment(s) disclosed in a manner still in keeping with the spirit and scope of the present disclosure.

FIG. 1A depicts a device architecture for a photovoltaic device;

FIG. 1B depicts a block diagram of a system for manufacturing photovoltaic devices;

FIGS. 1C-1F depict schematic of surface contact models due to no pressure;

FIGS. 1G-1J depict schematic of surface contact models due to moderate pressure;

FIGS. 1K and 1L depict schematic of surface contact models due to high pressure;

FIG. 1M is a flow chart of a method for pressure fabrication of a substrate;

FIG. 2A depicts a device architecture for a perovskite solar cell;

FIGS. 2B and 2C depict a schematic of the pressure treatment for the pressure-assisted perovskite solar cells fabrication process;

FIG. 3A depicts an embodiment of a device architecture for a perovskite light emitting device;

FIG. 3B depicts a schematic of the pressure treatment for the pressure-assisted perovskite light emitting devices fabrication process;

FIG. 3C depicts an embodiment of a device architecture for a perovskite light emitting device;

FIG. 3D depicts a schematic of the pressure treatment for the pressure-assisted perovskite light emitting devices fabrication process;

FIG. 3E depicts an embodiment of a device architecture for a perovskite light emitting device;

FIG. 3F depicts schematics of the pressure application procedures, showing before press, press and lift of the PDMS anvil;

FIG. 3G depicts a set-up of pressure application on the devices for press and lift-up of the anvil;

FIG. 3H depicts a set-up of pressure application on the devices for press and lift-up of the anvil;

FIGS. 3I-3L depict analytical modeling of interfacial surface contact;

FIGS. 4A and 4B depict an FEA Model for the pressure treatment in the pressure-assisted fabrication of perovskite solar cells;

FIG. 5A depicts an analytical modeling, showing the effects of pressure on interfacial contact for different thicknesses of the films with a particle size of 1 μm;

FIG. 5B depicts an analytical modeling, showing the effects of pressure on interfacial contact for perovskite film of thickness 200 nm with different sizes of the particles;

FIGS. 6A-6D depict the stress distribution and the interfacial contact when pressures are applied for different mechanical properties of clean room dust particles;

FIG. 7 depicts the effects of pressure on optical properties of perovskite films;

FIGS. 8A-8C depict XRD pattern and SEM images of pressure-assisted perovskite films;

FIGS. 8D-8F depicts the microstructural images of the films;

FIGS. 9A and 9B depict the effects of current density-voltage and power density-voltage of performance of perovskite solar cells, respectively;

FIG. 10A depicts the effects of pressure on power conversion efficiency and fill factor;

FIG. 10B depicts the effects of pressure on short circuit current density and open circuit voltage;

FIG. 10C depicts the effects of pressure on maximum current density and maximum voltage;

FIG. 11 depicts a FEA Model for the pressure treatment in the pressure-assisted fabrication of perovskite solar cells;

FIG. 12 depicts contact length versus applied pressure for different sizes of the particles;

FIG. 13 depicts the effects of pressure on absorbance of PLED emitter. The inset show the increase in absorbance with applied pressure;

FIG. 14A depicts absorption coefficient versus photon energy for emitter (CH₃NH₃PbI₃₋ₓClₓ) at different applied pressures, the inset shows the difference in band gap with and without pressure;

FIG. 14B depicts effect of applied pressure on the band gap of the emitter;

FIGS. 15A-15F depict an XRD showing the peaks at different pressure and (d-f) SEM images of CH₃NH₃PbI₃₋ₓClₓ film;

FIGS. 16A and 16B depict the effects of pressure on current-voltage curves of PLEDs showing the estimation of turn-on voltage;

FIG. 16C depicts the effects of pressure on turn-on voltage of PLEDs;

FIGS. 17A and 17B depict an FEA model for the pressure treatment in the pressure-assisted fabrication of perovskite light emitting devices, with FIG. 17A depicting a model of the device showing the boundary conditions and FIG. 17B depicting a mesh density of the model.

FIG. 18A depicts effects of pressure on contact length for different thicknesses of the perovskite films;

FIG. 18B depicts different particle sizes or film roughness values;

FIGS. 19A-19F depict computational modeling of interfacial surface contacts in perovskite light emitting devices;

FIG. 20A depicts effects of applied pressure on the absorbance of PeLED emitter (CH₃NH₃PbI₃₋ₓClₓ) and the inset show the increase in absorbance with very high applied pressures;

FIG. 20B depicts PL spectra of the perovskite emitter at different applied pressures;

FIG. 20C depicts effect of applied pressure on the bandgap of the emitter;

FIG. 20D depicts XRD patterns of the pressure-assisted perovskite film;

FIG. 20E depicts effects of applied pressure on the XRD peak intensity;

FIG. 20F depicts an SEM image of the perovskite film;

FIG. 21A depicts the effects of pressure on current-voltage curves of PLEDs showing the estimation of turn-on voltage;

FIG. 21B depicts the effects of pressure on turn-on voltage of PLEDs.

FIGS. 22A-22C depict cross sectional SEM images;

FIG. 22D depicts effects of pressure on the trap filled voltage, trap density, and mobility for hole-only devices;

FIG. 23A depicts an analytical modeling of pressure effects on contact length ratios, L_{C}/L, showing the effects of pressure on the surface contacts for different thicknesses of the films for particle size of 1 μm;

FIG. 23B depicts an analytical modeling depicts an analytical modeling of pressure effects on contact length ratios, L_{C}/L, showing the effects of pressure on surface contacts for different sizes of the particles for a film thickness of 250 nm;

FIGS. 24A and 24B depict the results of the finite element simulations (before and after pressure application, respectively), for the interfacial surface contact between perovskite layer and mesoporous TiO2 layer;

FIGS. 24C-24D depict improvements in pressure-induced contacts at other interfaces in the device structure;

FIG. 24E depicts infiltration of mesoporous structure with perovskite;

FIG. 24F depicts damage from sink-in of the perovskite layer into mesoporous;

FIG. 24G depicts the axisymmetric boundary condition;

FIGS. 24H-M depict the interfacial surface contacts increasing with increasing pressure;

FIGS. 24N-24S depict the effects of pressure and the material properties of the interlayer particles on the surface contact.

FIG. 25A depicts the XRD patterns of the as-prepared perovskite films and those produced via pressure-assisted fabrication;

FIGS. 25B-25D depict the SEM images of the perovskite films with the pressure-induced crystallization;

FIG. 25E depicts optical absorbance of perovskite film;

FIG. 25F depicts a plot of (αhv)² versus photon energy;

FIGS. 26A-26L depict the device parameters before and after applying pressure;

FIG. 27 depicts localized stress in an interfacial layer crack or notch within the multilayered structure of a perovskite solar cell subjected to remote pressure or stress;

FIGS. 28A-28E depict the pressure-assisted fabrication technique for devices with a large active area;

FIGS. 29A-29C depict schematics of the interfacial surface contact;

FIG. 29D-29F depict an axisymmetric model of interfacial surface contact;

FIGS. 30A-30C depicts a set-up of pressure application on the devices for press and lift-up of the anvil;

FIGS. 31A-31F depict the SEM images of the evolving microstructures of the annealed P3HT:PCBM films (on PEDOT:PSS/ITO-coated glasses);

FIG. 31G-31L depict AFM images of annealed P3HT:PCBM films;

FIGS. 32A-32D depict crystallinity of the P3HT:PCBM films;

FIGS. 32E-32I depict 2-D GIWAXS images of P3HT:PCBM films at different annealing temperatures;

FIGS. 33A-33D depict optical absorbance spectra and transient photoconductivity of P3HT:PCBM films;

FIG. 33E depicts optical absorbance of pressure-assisted film that was annealed at 100° C.;

FIGS. 33F and 33G depict photoinduced change in complex THz photoconductivity;

FIGS. 33H-33J depict effects of thermal annealing on long-range conductivity (σ_{DS}) and carrier mobility of films;

FIGS. 34A-34E depict characteristics performance of OSCs at different applied pressures and thermal annealing temperatures;

FIGS. 35A-35D depict modeling of effects of mechanical pressure on interfacial surface contacts;

FIGS. 35E-35H depict effects of applied pressure on interfacial surface contacts for different layers of organic solar cells; and

FIG. 35I depicts FEA Model for the pressure treatment of OSCs; and

FIGS. 35J-35M depict interfacial contacts with particles of different mechanical properties.

While the above-identified drawings set forth presently disclosed embodiments, other embodiments are also contemplated, as noted in the discussion. This disclosure presents illustrative embodiments by way of representation and not limitation. Numerous other modifications and embodiments can be devised by those skilled in the art which fall within the scope and spirit of the principles of the presently disclosed embodiments.

### DETAILED DESCRIPTION

The present disclosure relates to fabricating photovoltaic devices with improved efficiencies and performance. Such devices typically comprise of multiple layers of different materials. The present disclosure provides a system and method that utilizes the application of pressure during fabrication of such photovoltaic devices to improve the interfacial contact between the layers. In particular, the present disclosure utilizes the application of pressure during the manufacturing process to increase the efficiency of photovoltaic devices by increasing contact between layers when impurity particles are present.

The present disclosure improves the fabrication of the photovoltaic devices 100. As used in the present disclosure, the term “photovoltaic device” may refer to a photovoltaic junction (for example, p-i-n junction) as well as a complete photovoltaic device, such as a solar cell or light emitting diode. In some embodiments, the photovoltaic device 100 can be organic photovoltaic cells, solar cells, light emitting diodes, thin film batteries, solid-state batteries, supercapacitors, and similar light absorbing or emitting devices.

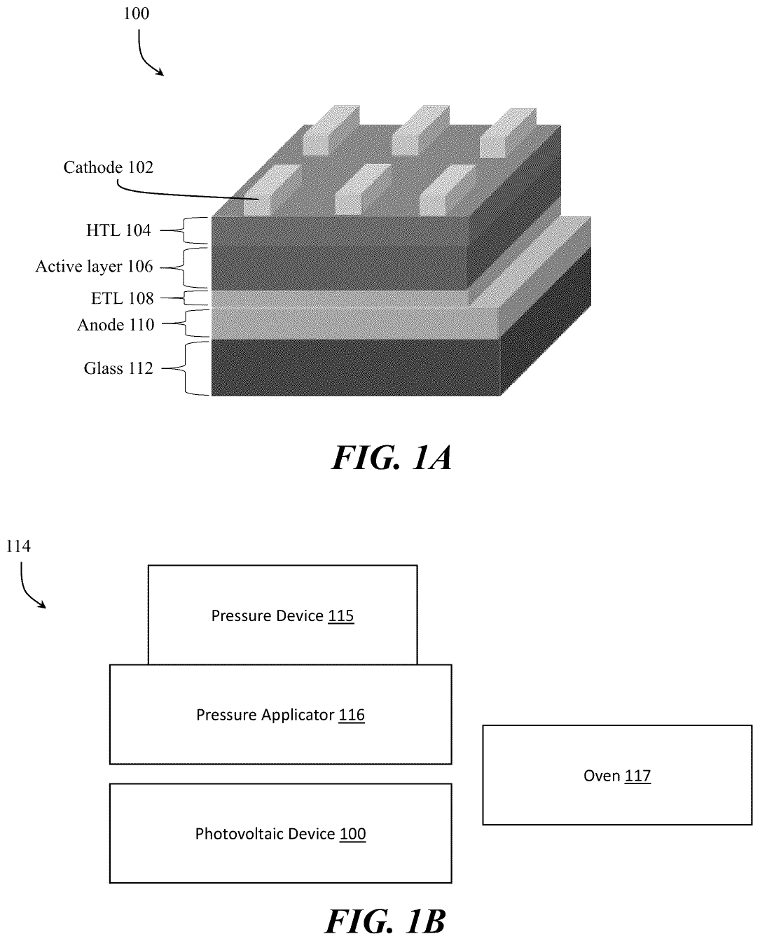

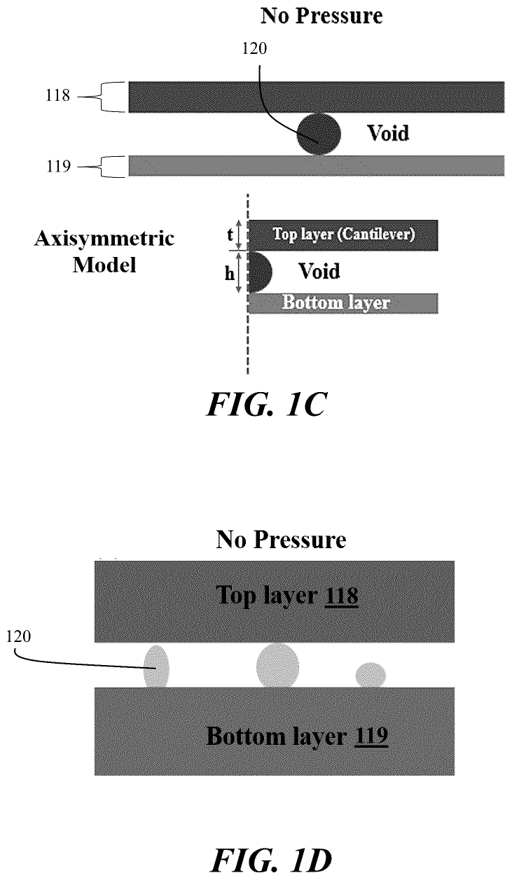

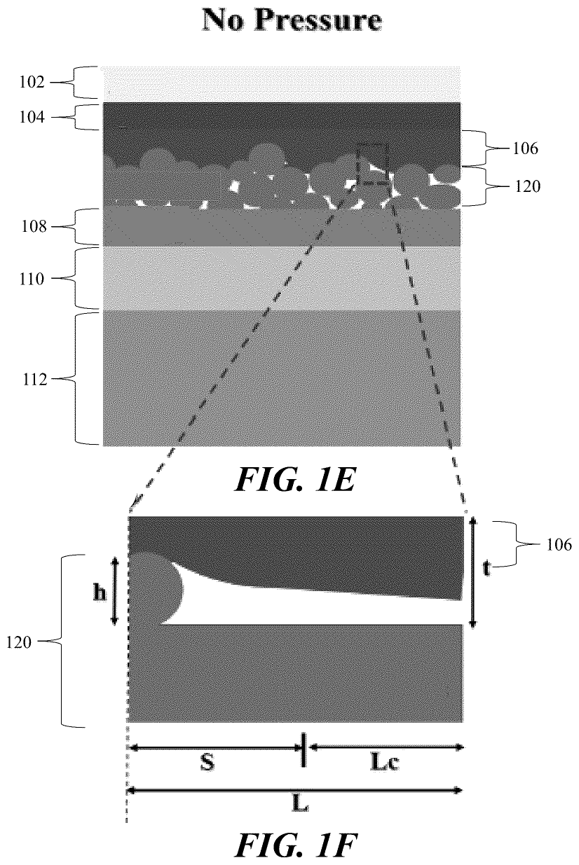

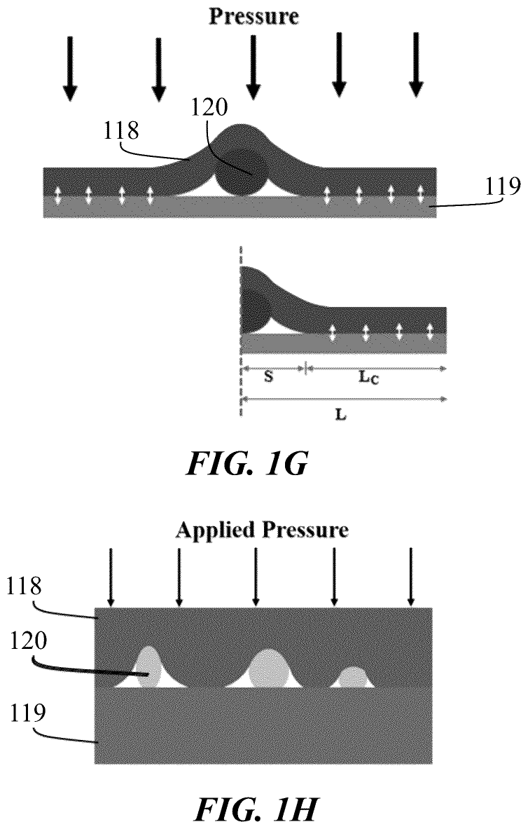

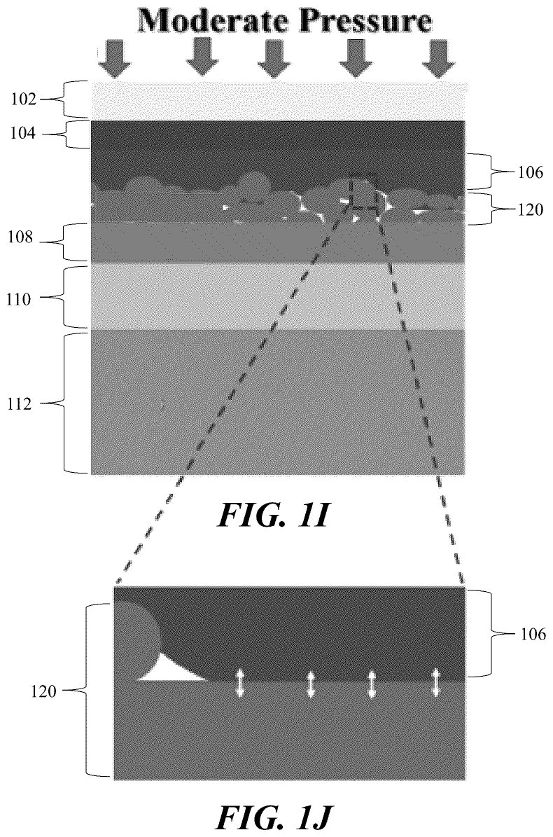

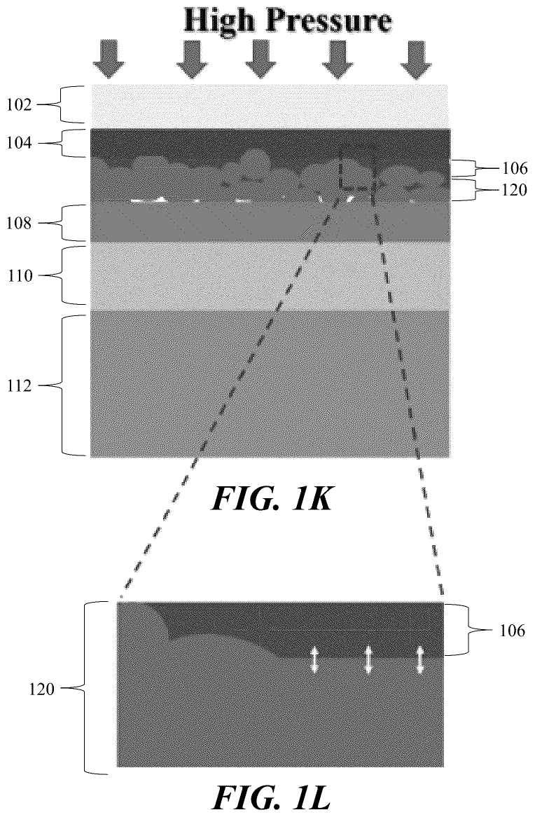

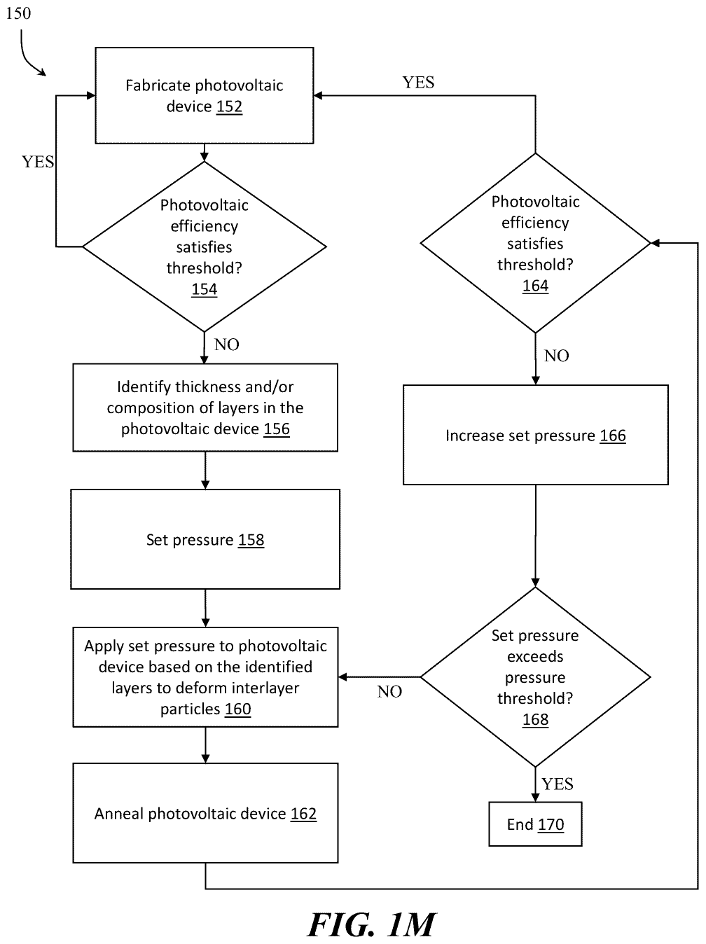

Referring to FIG. 1A, a photovoltaic device 100 may include a cathode 102, a hole transport layer (HTL) 104, an active layer 106, an electron transport layer (ETL) 108, anode 110, and a substrate 112.

The cathode 102 can be an electrode from which current leaves the cell 110. The cathode can include materials such as but not limited to gold, silver, and copper. In some embodiments, the cathode 102 has a thickness of 150 nm.

The HTL 104 can be a p-type layer for attracting holes from the active layer and repelling electrons. The HTL 104 can include materials such as but not limited to a Spiro-OMeTAD a composite of poly(3,4-ethylenedioxythiophene)-poly(styrenesulfonate) (PEDOT:PSS), or poly(3,4-ethylenedioxythiophene)-poly(styrenesulfonate) (PEDOT:PSS) and molybdenum (VI) oxide (MoO₃).

The active layer 106 comprises a photovoltaic material configured facilitate photon absorption and generation of excitons. The active layer can have varying thicknesses, such as 100-400 nm. For reference, airborne particles in semiconductor clean room environment typically have a diameter of 1 μm, which is four times the thickness of an active layer with a thickness of 250 nm. The active layer can include materials such as but not limited to perovskite (e.g., CH₃NH₃PbI₃₋ₓClₓ), organic materials, fullerene derivative (6,6)-phenyl-C₆₁-butyric acid methyl ester (PCBM), amorphous silicon, biohybrid, cadmium telluride (CdTe), copper indium gallium selenide, crystalline silicon, float-zone silicon, gallium arsenide germanium (GaAs), Hybrid, tandem-cell using a-Si/μc-Si, monocrystalline solar (mono-Si), nanocrystal solar, organic materials, inorganic materials, photoelectrochemical, plasmonic, polycrystalline (multi-Si), quantum dot, solid-state, or crystalline silicon.

In some embodiments, synthetic perovskite materials are possible inexpensive base materials for high-efficiency commercial photovoltaics. The ease of solution processing, without high temperature heating, and the tunable optical band gaps of perovskite in the visible region, make them promising materials for optoelectronic devices at low cost. The high-power conversion of perovskite solar cells and the performance characteristics of perovskite light emitting diodes (PLEDs) have led to increased interest in perovskite. Since these structures can be produced using low-cost processing techniques, this suggests that perovskite solar cells have the potential to compete with silicon solar cells that are now used in the photovoltaic industry. Perovskite solar cells can also be manufactured using the same thin-film manufacturing techniques as that used for thin film silicon solar cells and can achieve a conversion efficiency of up to 15%. Furthermore, since perovskite solar cells are produced relatively at low temperatures, (<120° C.), a wider range of potential substrates and electrode materials can be integrated into their multilayer structures. These include polymer-based flexible substrates with well adhered layers, as well as transparent substrates that work under low temperature condition. Hence perovskite solar cells have the potential to offer low cost, stability, efficiency and added functionality. Perovskite materials used as light emitting diodes have strong photoluminescent (PL) properties with narrow full width at half maximum (FWHM) less than 20 nm. They also exhibit size independent high color purity, which make them to be good candidates for applications in emitters. Their high color purity has also made them attractive alternatives to conventional organic and inorganic light emitters.

The ETL 108 can be an n-type material to convey electrons away from the active material to the anode and repel holes towards the active layer. The ETL 108 can include materials such as but not limited to a mesoporous Titanium (IV) Oxide (m-TiO₂) layer (e.g., hole-transport layer (PEDOT:PSS) or a Al₂O₃ mesoporous layer. Other materials commonly used in the industry can also be used to form the photovoltaic device 100 of the present disclosure.

The anode 110 can be an electrode through which current enters into the photovoltaic device 100. The anode 110 can include materials such as but not limited to Fluorine-doped tin oxide (FTO).

The substrate 112 can be an electrical insulator for the photovoltaic device 100. The substrate 112 can include materials such as but not limited to electrical insulators, glass, borosilicate glass, polymers, such as SU-8, polyimide, polyethylene naphthalate (PEN), polyethylene terephthalate (PET), or metals, such as stainless steel or aluminum.

FIG. 1B depicts a block diagram of a system 114 for manufacturing photovoltaic devices. The system 114 can include a pressure applicator 116 configured to come in contact with the photovoltaic device 100 and apply pressure or compression to the photovoltaic device 100. In some embodiments, the system 114 further includes a pressure device 115 configured to enable the pressure applicator to apply pressure or compression. The pressure applicator 116 and the pressure device 115 may be of a mechanical type (for example, a piston and an actuator) or of a pneumatic type (for example, an inflatable bladder and a pump). The system 114 can include an oven 117 configured to anneal the photovoltaic device 100. The oven 117 can be a furnace, heater, or any other heating device used in semiconductor device fabrication.

Referring to FIGS. 1C-1F, the photovoltaic device 100 (e.g., organic, inorganic, and hybrid light emitting devices) can be fabricated through layer-by-layer deposition of thin films. For example, a top layer 118 can be deposited on a bottom layer 119. The top layer 118 and the bottom layer 119 can be any of the layers described in FIG. 1A. The deposition techniques can include solution processing or evaporation. Photovoltaic devises can be fabricated using systems and methods located within clean rooms. Clean rooms and the deposited materials themselves, however, can include environmental dust particles or undissolved/unfiltered particles that are difficult to entirely remove from the environment. During fabrications of layered thin films, particles of silicone, silicon, silica, textile polymer and other organic materials of diameter ranging from ˜0.1 to 20 μm that are present in clean room environments can be embedded between the layers of devices. The presence of these particles reduces the effective contact areas of the bi-material pairs that are relevant to the photovoltaic devices. The interfacial contact between layers of photovoltaic devices is important for effective transportation of charges and work function alignment.

When using deposition methods and systems the deposited layers can create and trap interfacial void(s) therebetween due to the interlayer particles 120 such as environmental dust particles or undissolved/unfiltered particles of the of the solution processed components. For example, if the top layer 118 is the active layer 106 and the bottom layer 119 is the ETL 108, then the interlayer particles 120 present on the ETL 108 would create a void when the active layer 106 is deposited over the ETL 108 onto the interlayer particles 120, even though the active layer 106 is intended to be applied directly on the ETL 108. In another example, if the top layer 118 is the HTL 104 and the bottom layer 119 is the active layer 106, then the interlayer particles 120 present on the active layer 106 would create a void when the HTL 104 is deposited over the active layer 106 onto the interlayer particles 120, even though the HTL 104 is intended to be applied directly on the active layer 106.

The interlayer particles 120 can be stiff, semi-rigid or compliant materials. When the interlayer particles 120 between layers are stiff (ITO, MoO₃, TiO₂, quartz, etc.), it could be difficult to achieve interfacial layer contacts between the ETL 108 and the active layer 106, as void length depends on modulus and height of the interlayer particle(s) 120. Usually, the size of the trapped particles varies between approximately 0.1 μm and 20 μm in diameter. Rigid particles can also sink into the compliant adjacent layers. It is important to have good interfacial surface contacts between layers (without significant voids) for work function alignment enhancement among the constituted layers of the photovoltaic devices, but impurity particles between layers inhibit such contacts.

FIGS. 1G-1L depict photovoltaic devices, corresponding to the devices fabricated using traditional methods depicted in FIGS. 1C-1F, except that the photovoltaic devices 100 are fabricated with the application of pressure during the fabrication process to increase the contact between adjacent layers. In some embodiments, one or more of the layers of the photovoltaic devices of the present disclosure are in a form of a thin film. In some embodiments, the active layer 106 can have varying thicknesses, such as 100-400 nm. In some embodiments, the cathode 102 has a thickness of 150 nm. For reference, airborne particles in semiconductor clean room environment typically have a diameter of 1 μm, which is four times the thickness of an active layer 106 with a thickness of 250 nm. The structure and properties of thin films subjected to compression determine the kind of deformation exhibited by the film. These films are deformed when pressure is applied to improve the interfacial surface contact. The deformation of a thin film around interfacial compliant particles can be idealized by the displacement of the layers described herein. The schematics of the layers before and after deformation are shown in FIGS. 1G-1L. When the film deflects, the layer increases a surface area of contact with adjacent layers.

FIGS. 1G-1J depict schematic of surface contact models due to moderate pressure. The interfacial contacts between the layers 118 and 119 (for example, the ETL layer) and the layer 106 (for example, the active layer) can be enhanced, even with interlayer particles 120 present, by a supplication of pressure (compression treatment) onto the surface layer. The application of pressure can deform one or more layer of the photovoltaic devices about the interlayer particles to increase the effective contact area between the layers of the photovoltaic devices. Such an application of pressure can lead to a close packing and reduce the interatomic distances, which could change the electronic orbitals and bonding patterns. The application of pressure can also promote adhesion between layers and suppress crack formation along the interface of thin film-substrate bi-materials. Different pressure values can be used to transform the structural, optical, magnetic, electronic transport properties of organic and inorganic solids. By applying pressure to the photovoltaic device, the voids between the layers caused by interlayer particles 120 can be removed to instead establish interfacial surface contacts between layers for work function alignment enhancement among the constituted layers of the photovoltaic devices.

Understanding the effect of pressure on the layers of the photovoltaic devices enables tuning of material properties through compression. This can result in dramatic improvements in the performance of photovoltaic devices. For example, the system and method of the present disclosure can improve the power conversion efficiencies of the PSCs from ˜8% to ˜12%, as well as reductions in the turn-on voltages of the photovoltaic devices from 2.5 V to 1.5 V. The improvements in the performance characteristics are shown to be associated with improved surface contacts that give rise to improvements in light and charge transport.

However, while a sufficient pressure needs to be applied to deform one or more layers, the pressure that is too high can also damage the photovoltaic devices of the present disclosure. For example, FIGS. 1K and 1L depict schematic of surface contact models due to high pressure. At higher pressures (e.g., above 15 MPa), the interlayer particles 120 can sink into the layers such as the active layer 106. The sink in of the interlayer particles 120 can induce damage in surrounding layers in ways that can result in reduced photoconversion efficiencies of the photovoltaic device 100. In some embodiments, the applied pressure may be between about 2 MPA and 15 MPA. In some embodiments, the applied pressure may be between about 5 MPA and 12 MPA. In some embodiments, the applied pressure may be between about 6 MPA and 10 MPA. In some embodiments, the pressure may be less than 10 MPA. In some embodiments, the applied pressure may be at 7 MPA.

FIG. 1M is a flow chart of a method 150 for pressure fabrication of a solar cells. The method can include fabricating a photovoltaic device (STEP 152). The method can include determining if the photovoltaic efficiency satisfies a threshold (STEP 154). If the photovoltaic efficiency of the photovoltaic device satisfies a photovoltaic efficiency threshold, the method can proceed to STEP 152 to prepare another photovoltaic device. If the photovoltaic efficiency fails to satisfy the threshold or if a further increase in efficiency is desired regardless of the photovoltaic efficiency, the method can include identifying thickness and/or composition of layers in the photovoltaic device (STEP 156). The method can include setting a pressure (STEP 158). The method can include applying the set pressure to the photovoltaic devices to deform interlayer particles (STEP 160). The method can include annealing the photovoltaic device (STEP 162). The method can include determining if the photovoltaic efficiency satisfies a photovoltaic efficiency threshold after applying the pressure (STEP 164). If the photovoltaic efficiency of the photovoltaic device satisfies a threshold after applying the pressure, the method proceeds to STEP 152 to prepare another photovoltaic device. If the photovoltaic efficiency fails to satisfy the photovoltaic efficiency threshold, the method can include increasing the applied pressure (STEP 166). The method can include determining if the set pressure exceeds a pressure threshold (STEP 168). If the set pressure is less than the pressure threshold, the method can include applying the increased pressure (STEP 160). If the set pressure exceeds the pressure threshold, the method terminates (STEP 170). Any of the steps can be optional or performed in a different order. For example, STEP 162 can be skipped such that the photovoltaic device is not annealed, and instead the method proceeds from STEP 160 to STEP 164.

The method can include fabricating a photovoltaic device (STEP 152). In some embodiments, this step includes the steps: a first electrode layer is deposited on a substrate. An electron transport layer is deposited on the first electrode layer, an active layer is deposited on the electron transport layer, a hole transport layer is deposited on the active layer, and a second electrode layer is deposited on the hole transport layer. Other additional layers may also be added.

The method can include determining if the photovoltaic efficiency satisfies a photovoltaic efficiency threshold (STEP 154). The photovoltaic efficiency of the photovoltaic device can be identified with tests. For example, by testing for Power Conversion Efficiency (PCE), conductivity, or optical absorption. If the photovoltaic efficiency of the photovoltaic device satisfies a photovoltaic efficiency threshold, the method proceeds to STEP 152 to prepare another photovoltaic device. For example, if the photovoltaic device 100 is sufficiently conductive, then the photovoltaic device 100 is ready for mass production.

If the photovoltaic efficiency fails to satisfy the threshold or if a further increase in efficiency is desired regardless of the photovoltaic efficiency level, pressure may be applied to one or more layers of the photovoltaic device. The method can include identifying thickness and/or composition of layers in the photovoltaic device (STEP 156). The identified thickness and/or composition of layers can be used to determine whether the photovoltaic efficiency of the photovoltaic device 100 of the present disclosure can be improved by applying pressure.

The method can include setting a pressure (STEP 158). In some embodiments, the set pressure can be predetermined. The set pressure can be based on the identified thickness and/or composition of layers. In some embodiments, the set pressure can be proportional to the thickness of the active layer of the photovoltaic devices 100. For example, the set pressure can be higher if the active layer is thicker. In some embodiments, the set pressure can be based on the composition of the photovoltaic device 100. For example, the set pressure can be from 0 MPa to 15 MPa. In some embodiments, the applied pressure may be between about 2 MPA and 15 MPa. In some embodiments, the applied pressure may be between about 5 MPA and 12 MPA. In some embodiments, the applied pressure may be between about 6 MPA and 10 MPA. In some embodiments, the pressure may be less than 10 MPA. In some embodiments, the applied pressure may be at 7 MPA. In some embodiments, the pressure may be selected based on a historical data or based on an estimate.

The method can include applying the pressure to the photovoltaic devices to deform particles present on the layer (STEP 160). As shown in FIG. 1B, the pressure can be applied to the photovoltaic devices 100 by the photovoltaic device 115 driving the pressure applicator 116. The pressure applicator can apply the pressure with a pressure applicator. In some embodiments, the pressure device uses the pressure applicator to apply compression to the photovoltaic device at a predetermined rate and holds the pressure at up to the set pressure for a predetermined of time. For example, at a rate of 1 mm/min for 10 minutes.

The method can include annealing the photovoltaic device (STEP 162). The photovoltaic device can be annealed at different temperatures such as 25, 100, 150, 200, or 250 C. For example, the annealed temperature can be from 50 to 100 C. In some embodiments, the annealed temperature can be between about 100 and 150 C. In some embodiments, the annealed temperature may be between about 150 and 200 C. In some embodiments, the annealed temperature may be between about 200 and 250 C. In some embodiments, the annealed temperature may be 150 C. In some embodiments, the annealed temperature may be 200 C. In some embodiments, the annealed temperature may be selected based on a historical data or based on an estimate.

The method can include determining if the photovoltaic efficiency satisfies a threshold after applying the pressure (STEP 164). The photovoltaic efficiency can be based on optical absorption or conductivity. The photovoltaic efficiency of the photovoltaic device can be identified with tests. For example, by testing for Power Conversion Efficiency (PCE), conductivity, or absorption.

If the photovoltaic efficiency of the photovoltaic device satisfies a threshold after applying the pressure, the method proceeds to STEP 152 to prepare another photovoltaic device. For example, if the photovoltaic device 100 is sufficiently conductive, then the photovoltaic device 100 is ready for mass production.

If the photovoltaic efficiency fails to satisfy the threshold, the method can include increasing the set pressure (STEP 166). For example, if the previously set and applied pressure was 4 MPa, the pressure can be increasing the set pressure to 5 MPa.

The method can include determining if the set pressure exceeds a pressure threshold (STEP 166). The set pressure is compared to the pressure threshold to determine whether the set pressure exceeds the pressure threshold. In some embodiments, the pressure threshold can be 7 MPa. In some embodiments, the pressure threshold can be 5 MPa. The set pressure can be based on the identified thickness and/or composition of layers. In some embodiments, the set pressure can be proportional to the thickness of the active layer of the photovoltaic devices 100. For example, the set pressure can be higher for if the active layer is thicker. In some embodiments, the set pressure can be based on the composition of the photovoltaic device 100. For example, the set pressure can be 5 MPa or 7 MPa.

If the set pressure is less than the pressure threshold, the method can include applying the increased pressure (STEP 160). For example, a set pressure of 5 MPa is less than the pressure threshold of 7 MPa, so the pressure of 5 MPa can be applied.

If the set pressure exceeds the pressure threshold, the method terminates (STEP 168). For example, a set pressure of 8 MPa would exceed the pressure threshold of 7 MPa. Applying pressures that exceed the pressure threshold can damage the photovoltaic device 100, so the method terminates.

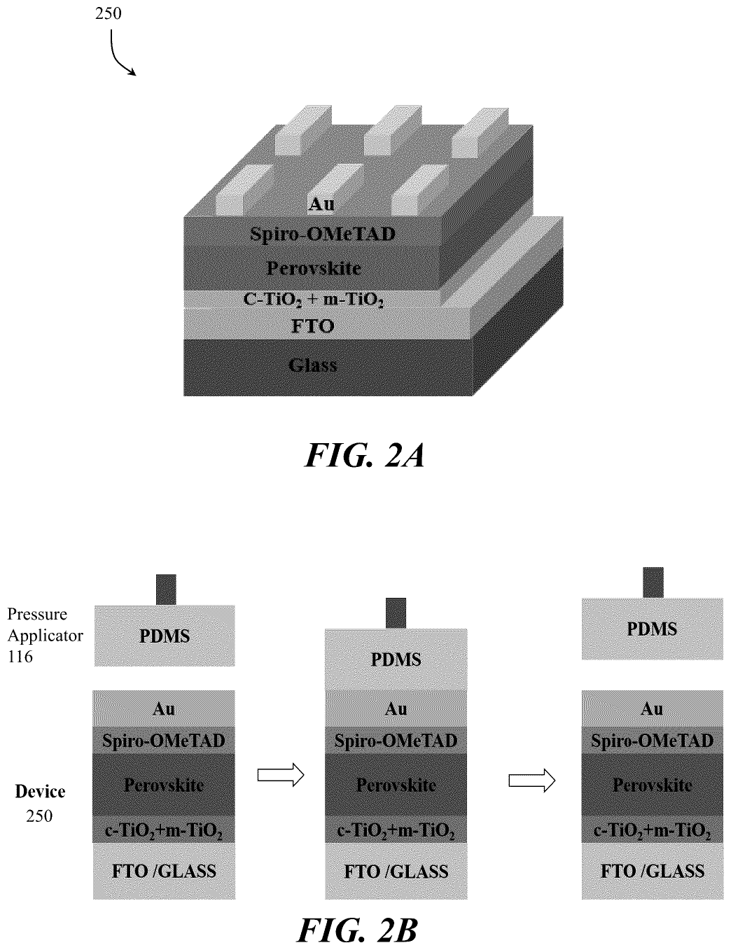

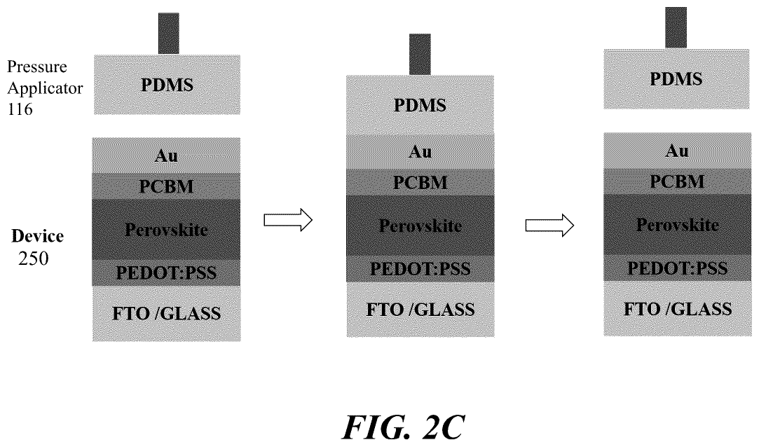

Referring to FIGS. 2A-2C, in some embodiments, the systems and methods of the present disclosure can be utilized to fabricate pressure-assisted perovskite solar cells. FIG. 2A depicts an example perovskite solar cell device architecture for use in accordance with the present disclosure. For example, referring to FIG. 2A, the perovskite solar cells can include a Fluorine-doped tin oxide (FTO)-coated glass layer, a compact Titanium (IV) Oxide (c-TiO₂) layer, a mesoporous Titanium (IV) Oxide (m-TiO₂) layer (e.g., hole-transport layer (PEDOT:PSS)), a perovskite layer, a 2, 2′, 7, 7′-tetrakis (N,N-di-p-methoxyphenylamine)-9, 9′-spirobifluorene (Spiro-OMeTAD) layer, and a gold (Au) layer or other conductive layer.

Referring to FIGS. 2B and 2C, a pressure treatment process can be applied to perovskite solar cell device 250 after the base device architecture is fabricated. In some embodiments, the pressure applicator 116 can be fabricated to the size and dimensions of the surface area of the perovskite solar cell device 250 and be configured to apply the pressure to the surface of the fabricated device. The pressure applicator 116 can be constructed from a variety of silicone materials. For example, the pressure applicator 116 can be constructed from a polydimethylsiloxane (PDMS) material, which can be constructed from a mixture of Sylgard 184 silicone elastomer base and curing agent in ratio 10:1 by weight. In some embodiments, pressure can be applied to the top cathodic layer of the device. The pressure applicator 116 can be used to apply pressure to a top layer of the device 250 or a combination of layers using a range of pressures. For example, the pressure applicator 116 can apply pressure values in the range of 0-17 MPa) to the Au and Spiro-OMeTAD) layers of the perovskite solar cell device 250. In some embodiments, 6 MPa of pressure can be applied to the solar cell device 250. The application of pressure by the pressure applicator 116 can deform the top layer(s) (e.g., the Au layer and the Spiro-OMeTAD) layer) around any particles present on the next layer (e.g., the PCBM layer and/or perovskite layer), as shown in FIGS. 1C and 1D. The current density-voltage characteristics are shown to be significantly improved by this pressure treatment.

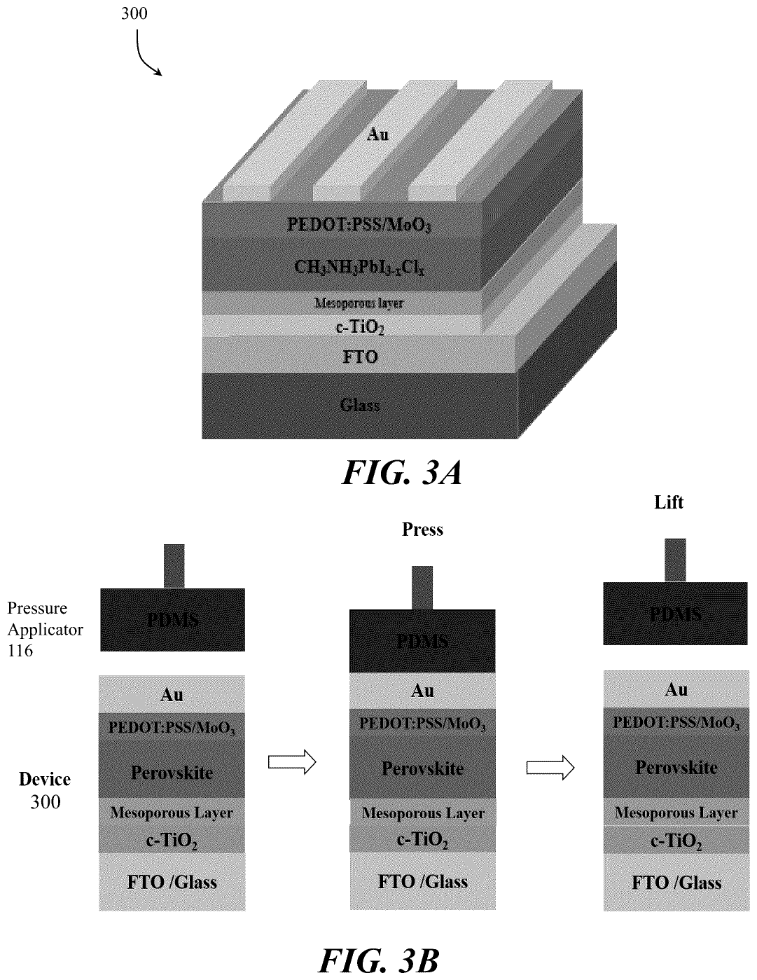

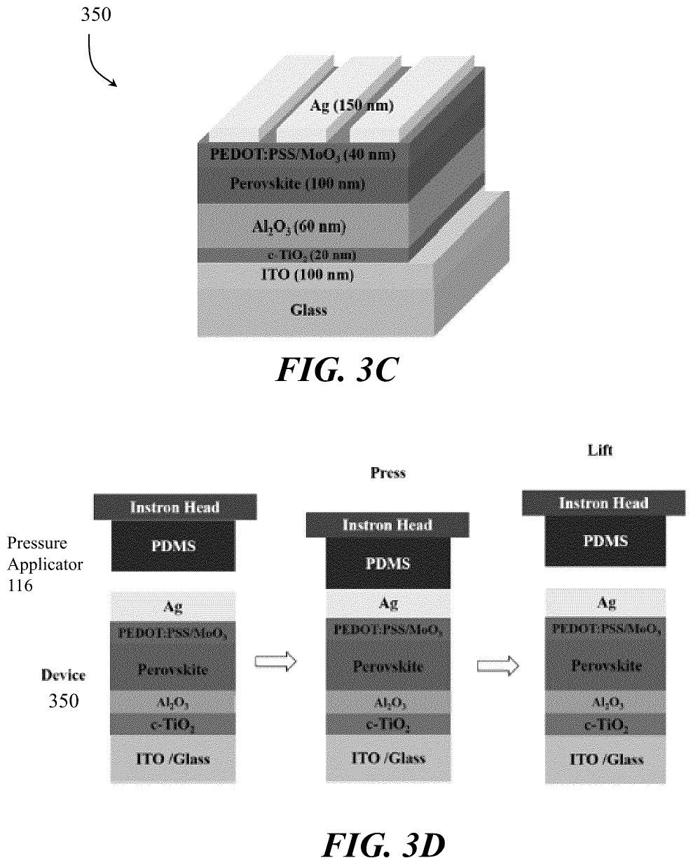

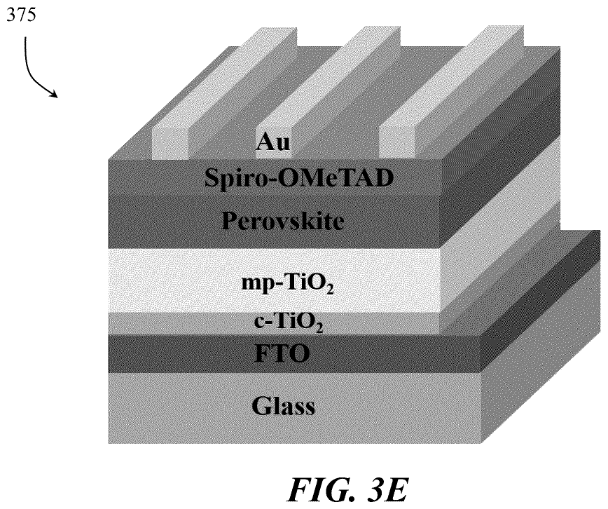

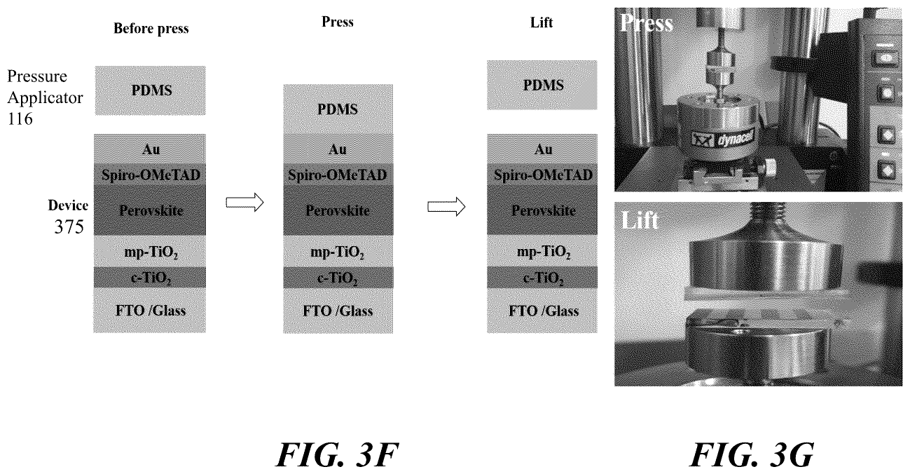

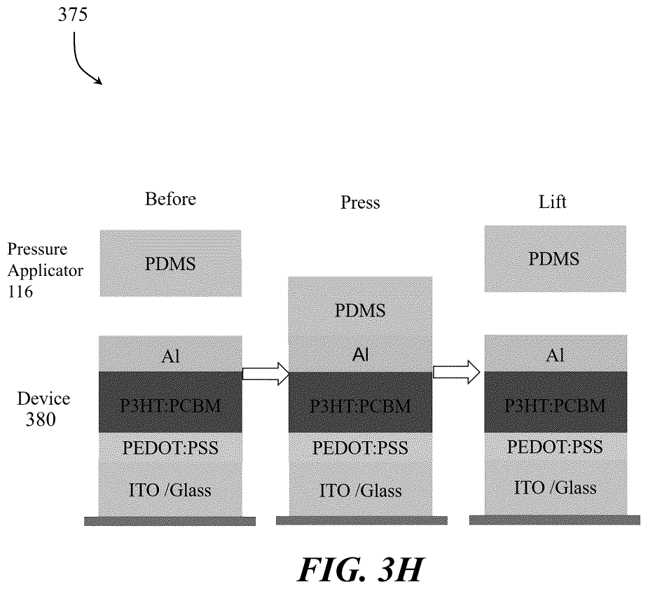

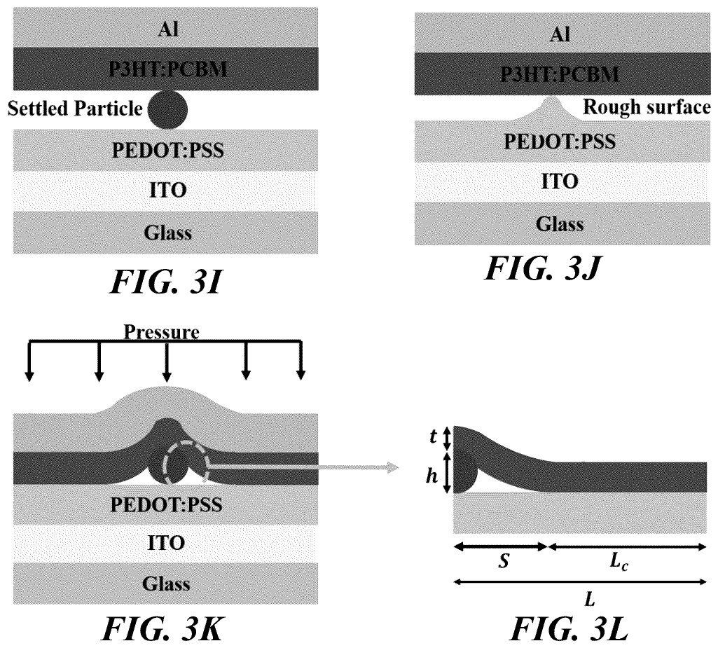

Referring to FIGS. 3A and 3B, in some embodiments, the systems and methods of the present disclosure can be utilized to fabricate pressure-assisted perovskite light emitting devices (PLEDs) 300. FIG. 3A depicts an example perovskite light emitting device architecture. For example, referring to FIG. 3A, the device 300 can include a Fluorine-doped tin oxide (FTO)-coated glass layer, compact titanium oxide (c-TiO₂) layer, a mesoporous layer, a perovskite layer (e.g., CH₃NH₃PbI₃₋ₓClₓ), a composite of poly(3,4-ethylenedioxythiophene)-poly(styrenesulfonate) (PEDOT:PSS) layer, and a gold layer (Au) or other conductive layer.

Referring to FIG. 3B a pressure treatment process can be applied to device 300 once the base device architecture is fabricated. In some embodiments, a pressure applicator 116 can be fabricated to the size and dimensions of the surface area of the device 300 and be configured to apply the pressure to the surface of the fabricated device. The pressure applicator 116 can be constructed from a variety of silicone materials, for example, using polydimethylsiloxane (PDMS), which can be constructed from a mixture of Sylgard 184 silicone elastomer base and curing agent in ratio 10:1 by weight. The pressure applicator 116 can be used to apply pressure to a top layer of the device 300 or a combination of layers using a range of pressures. For example, the pressure applicator 116 can apply pressure values in the range of 0-12 MPa to the Au and PEDOT:PSS layers of the device 300. In some embodiments, pressures of ˜9 MPa can be applied for fabricating PLEDs. The application of pressure by the pressure applicator 116 can deform the top layer(s) (e.g., the Au layer and the PEDOT:PSS layer) around any particles present on the next layer (e.g., the PEDOT:PSS layer and/or perovskite layer), as shown in FIGS. 1C and 1D. The current density-voltage characteristics are shown to be significantly improved by this pressure treatment.

Referring to FIGS. 3C and 3D, in some embodiments, the systems and methods of the present disclosure can be utilized to fabricate perovskite light emitting diodes (PeLEDs) devices 350. FIG. 3C depicts an example device architecture. The device 350 can include Indium tin oxide (ITO)-coated glass substrates, compact titanium oxide (c-TiO₂) layer, a mesoporous layer of Al₂O₃ nanoparticles (20 wt. % in isopropanol), a mixed halide perovskite (e.g., CH₃NH₃PbI₃₋ₓClₓ), a composite of poly(3,4-ethylenedioxythiophene)-poly(styrenesulfonate) (PEDOT:PSS) and molybdenum (VI) oxide (MoO₃), and a 150 nm thick silver layer or other conductive layer.

Referring to FIG. 3D, a pressure treatment process can be applied to device 350 once the base device architecture is fabricated. In some embodiments, a pressure applicator 116 can be fabricated to the size and dimensions of the surface area of the device 350 and be configured to apply the pressure to the surface of the fabricated device. The pressure applicator 116 can be constructed from a variety of silicone materials, for example, using polydimethylsiloxane (PDMS), which can be constructed from a mixture of Sylgard 184 silicone elastomer base and curing agent in ratio 10:1 by weight. The mixture can be poured into a glass mold of dimension 20 mm 20 mm 5 mm and then degassed in a vacuum oven for 30 min. This can allow all bubbles to disappear at 25 kPa. The degassed PDMS can then be cured for 2 h at 60° C.

The pressure applicator 116 can be used to apply pressure to a top layer of the device 350 or a combination of layers using a range of pressures. For example, the pressure applicator 116 can apply pressure values in the range of 0-12 MPa to the device 350. In another example, the pressure applicator 116 can be operated in a compression mode, while its head is set to absolutely ramp at 1.0 mm/min and holds on the devices for 10 min at a pressure of 1 MPa. The application of pressure by the pressure applicator 116 can deform the top layer(s) (e.g., the Au layer and the PEDOT:PSS layer) around any particles present on the next layer (e.g., the PEDOT:PSS layer and/or perovskite layer), as shown in FIGS. 1C and 1D. The current density-voltage characteristics are shown to be significantly improved by this pressure treatment.

FIG. 3E depicts an embodiment of a device architecture for a perovskite light emitting device. The device 350 can include Fluorine-doped tin oxide (FTO)-coated glass, compact titanium oxide (c-TiO₂) layer, a mesoporous layer of TiO2 nanoparticles, a mixed halide perovskite (e.g., CH₃NH₃PbI₃₋ₓClₓ), a solution of 2, 2′, 7, 7′-tetrakis (N,N-di-p-methoxyphenylamine)-9, 9′-spirobifluorene (Spiro-OMeTAD), and a 80.0 nm thick gold (Au) layer or other conductive layer.

FIGS. 3F and 3G depict schematics of the pressure application procedures, showing before press, press and lift of the pressure applicator 116. A pressure treatment process can be applied to device 375 once the base device architecture is fabricated. In some embodiments, a pressure applicator 116 can be fabricated to the size and dimensions of the surface area of the device 375 and be configured to apply the pressure to the surface of the fabricated device 375.

FIG. 3H depicts a set-up of pressure application on the devices for press and lift-up of the anvil. A pressure treatment process can be applied to device 380 once the base device architecture is fabricated. In some embodiments, a pressure applicator 116 can be fabricated to the size and dimensions of the surface area of the device 380 and be configured to apply the pressure to the surface of the fabricated device. FIGS. 3I-3L depict analytical modeling of interfacial surface contact on device 380. FIG. 3I depicts an idealized particle without no pressure. FIG. 3J depicts with an idealized surface roughness without pressure. FIG. 3K and FIG. 3L depicts after application of pressure.

In some embodiments, a method for fabricating perovskite solar cell devices is provided. In some embodiments, the method can include providing a perovskite layer; depositing one or more layers on the perovskite layer; and applying pressure onto the one or more layers to deform the one or more layers around any particles present on the perovskite layer.

In some embodiments, the method can include providing a substrate, depositing a compact titanium oxide layer on the substrate, depositing a perovskite layer on the oxide layer, depositing an interfacial layer on the perovskite layer, depositing a conductive layer on the interfacial layer; and applying pressure onto the conductive layer and the interfacial layer to deform the conductive layer and the interfacial layer around any particles present on the perovskite layer.

In some embodiments the substrate can be a Fluorine-doped tin oxide (FTO)-coated glass layer and a mesoporous Titanium (IV) Oxide (m-TiO2) layer. The interfacial layer can be a 2, 2′, 7, 7′-tetrakis (N,N-di-p-methoxyphenylamine)-9, 9′-spirobifluorene (Spiro-OMeTAD) layer. The conductive layer can be a gold (Au) layer. The pressure is applied by a polydimethylsiloxane (PDMS) anvil.

In some embodiments a method for fabricating perovskite light emitting devices (PLEDs) is provided. The method can include providing a substrate, depositing a compact titanium oxide layer on the substrate, depositing a mesoporous layer on the oxide layer, depositing a perovskite layer on the mesoporous layer, depositing an interfacial layer on the perovskite layer, depositing and etching a conductive layer on the interfacial layer and applying pressure onto the conductive layer and the interfacial layer to deform the conductive layer and the interfacial layer around any particles present on the perovskite layer.

In some embodiments the substrate can be a Fluorine-doped tin oxide (FTO)-coated glass layer. The interfacial layer can be composite of poly(3,4-ethylenedioxythiophene)-poly(styrenesulfonate) (PEDOT:PSS) layer. The conductive layer can be a gold (Au) layer. The pressure can be applied by a polydimethylsiloxane (PDMS) anvil.

In some embodiments, a system for manufacturing perovskite devices is provided. The system can include a fabricated perovskite device, the perovskite device comprising a bottom layer, a top layer, and one or more particles therebetween and an anvil configured to apply pressure to the top surface of the perovskite device to deform the top layer around any particles present on the bottom layer and increase contact between the top layer and the bottom layer.

In some embodiments the top layer can be an interfacial layer and a conductive layer. The bottom layer can be a perovskite layer.

### EXAMPLES

The following examples are put forth so as to provide those of ordinary skill in the art with a complete disclosure and description of how to make and use the assay, screening, and therapeutic methods of the disclosure, and are not intended to limit the scope of what the inventors regard as their disclosure.

The information in the examples is provided using a combination of computational, analytical and experimental methods. The interfacial contacts are modeled using a model that incorporates layer mechanical properties into a cantilever model in which interfacial dust particles limits the contacts between layers in perovskite device architectures. The predictions from the model shows that the interfacial surface contacts increase with increasing applied pressure. The current-voltage characteristics of methylammonium lead mixed halides (CH₃NH₃PbI₃₋ₓClₓ) perovskite solar cells are also shown to improve with the application of pressure (˜0-5 MPa). Numerical finite element simulations were used to study the contacts between layers in the perovskite device architectures by using the Young's moduli measurements obtained from nanoindentation techniques. These were incorporated into finite element models that were used for the simulation of the pressure-assisted perovskite device architecture fabrication process. The effects of applied pressure on perovskite devices with impurity particles embedded between the hole transport layer (HTL) and the active layers were also explored.

The contact profile of the initial interfaces around these particles has been studied by analytical models for organic solar cells and light emitting devices. As shown in FIGS. 1A and 1B, if h is the height of the impurity particle, t is the thickness top layer (cantilever) that deformed upon pressure application, the length of the void and contact length can be denoted as S and L_{c}, respectively. The length of cantilever beam is L. The relationship between the contact length and the applied pressure can be shown by equation 1:

$$\frac{{L}_{c}}{L} = 1 - {[ \frac{3 ( \frac{E}{1 - {v}^{2}} ) {t}^{3} h}{2 {PL}^{4}} ]}^{1 / 4} ,$$

where L_{c} is the contact length, P is the applied pressure, h is the height (size) of the particle, E is the Young's modulus of the beam, v and L is the length of the beam.

Since the material and geometric properties of the thin film layers are known, the contact length, the void length and the adhesion energy between the various interfaces that make up the perovskite light emitting devices can be determined accurately, with the aid of force microscopy or interfacial fracture mechanics methods, by getting the Young's modulus from nano-indentation. These calculations were utilized in the following examples to determine the optimal pressures applied, in accordance with the present disclosure, and subsequent improvements to the operation of the perovskite devices resulting from the applied pressures.

### Example 1—Perovskite Solar Cells

Example 1 shows that the efficiencies of the solar cells increases from ˜8% to ˜12% with increasing applied pressure, for pressure between 0 and 5.0 MPa, with over 50% improvement. However, for pressures beyond 5.0 MPa, the solar cell efficiencies decrease with increasing pressure. The implications of the results are discussed for the pressure-assisted fabrication of perovskite solar cells. These results were derived from Example 1 below.

### Processing of Perovskite Solar Cells

Fluorine-doped tin oxide (FTO)-coated glass, lead (II) iodide (PbI2), methylammonium chloride (MACl), titanium diisopropoxide bis (acetylacetone), titanium oxide paste, 2, 2′, 7, 7′-tetrakis (N,N-di-p-methoxyphenylamine)-9, 9′-spirobifluorene (Spiro-OMeTAD), lithium bis (trifluoromethylsulphony) imide (Li-FTSI), tris(2-(1H-pyrazol-1-yl)-4-ter-butylpyridine)-cobalt (III) tris(bis(trifluoromethylsulfonyl) imide) (FK209) and 4-tert-butylpyridine (tBP) were purchased from Sigma Aldrich. Also, acetone, isopropyl alcohol (IPA), dimethylformamide (DMF) were purchased from Fisher Scientific. The FTO-coated glass was cleaned successively (for 15 minutes each) in deionized water, acetone and IPA within an ultrasonic bath. The cleaned glass was then blow-dried in nitrogen gas, prior to UV/Ozone cleaning for 20 minutes to remove organic residuals.

Subsequently, an electron transport material (ETL) was spin coated onto the cleaned FTO-coated glass. First, a compact titanium oxide (c-TiO₂) was spin-coated from 0.15 M of titanium diisopropoxide bis (acetylacetone) in 1-butanol at 2000 rpm for 30 s. This was followed by 5 min annealing at 150° C. before spin coating 0.3 M of titanium diisopropoxide bis (acetylacetone) at 2000 rpm for 30 s. The deposited c-TiO2 was then annealed at 500° C. for 30 min and it was then allowed to cool down to room temperature using a Lindberg/Blue furnace. A mesoporous TiO₂ (m-TiO₂) was spin coated from a solution of titanium oxide paste in ethanol (1:5 w/w) as 5000 rpm for 30 before sintering at 500° C. for 30 min in the Lindberg/Blue furnace. The substrate was then transferred into a nitrogen filled glove box, where the photoactive perovskite and the hole injection layers were deposited.

A perovskite solution was prepared from a mixture of 0.231 g of PbI₂ and 0.0797 g of MACl in 1 ml of DMF. This was then stirred at 60° C. for 6 hours in the nitrogen filled glove box. The solution was filtered using a 0.2 μm mesh filter before spin-coating onto m-TiO₂/c-TiO₂/FTO-coated glass at 2000 rpm for 50 s. After 30 s the spin coating of the perovskite layer, 300 μl of chlorobenzene was then dispensed on the film. The perovskite film was then annealed at 90° C. for 30 min to crystalize. Finally, a solution of spiro-OMeTAD was spin coated at 5000 rpm for 30 s. The Spiro-OMeTAD solution was prepared from a mixture of 72 mg of Spiro-OMeTAD in 1 ml of chlorobenzene, 17.5 μl of Li-FTSI (500 mg of Li-FTSI in 1 ml of acetonitrile), 29 μl of FK209 (100 mg in 1 ml of acetonitrile) and 28.2 μl of tBP. The film was then kept in a desiccator overnight before a 70 nm thick gold (Au) layer was then thermally evaporated onto the Spiro-OMeTAD using Edward E306A. The evaporation was carried out under a vacuum pressure of ˜1.5×10⁻⁵ Torr at a rate of 0.15 nm/s. A shadow mask was used to define a device area of 0.15 cm2. The architecture of the device is presented in FIG. 2B.

### Pressure Experiments

A range of pressures values (0-17 MPa) were applied to fabricated perovskite solar cells devices. This was done using a 5848 MicroTester Instron with a PDMS anvil placed on the device. First, the PDMS anvil was fabricated from a mixture Sylgard 184 silicone elastomer base and Sylgard 184 silicone elastomer curing agent (Dow Corning Corporation, Midland, MI) in ratio 10:1 by weight. The mixture was degassed and cured at 65° C. for 2 hours in a mold with shining silicon base. The PDMS anvil was then cut out into the dimension of the device layer surface area.

The schematic of the pressure experiment set-up, for the improvement in device performance, is shown in FIGS. 3A and 3B. The head of the Instron was set to ramp in compression at a rate of 1 mm/min and hold at 2 MPa for 10 min. This was repeated using different pressures (from 0 MPa to 17 MPa) on the perovskite solar cells and perovskite layer.

### Characterization

The current density-voltage (J-V) characteristics of the fabricated perovskite solar cells were measured before and after the pressure treatment using a Keithley SMU2400 system that was connected to an Oriel simulator under AM1.5 illumination of 100 mW/cm². The J-V curves of devices (with zero pressure) were first measured before subsequent J-V measurements of the devices that were subjected to applied pressures of 0-17 MPa.

The optical absorbance of the as-prepared and pressure-assisted perovskite layers was measured using Avantes UV-VIS spectrophotometer. The X-ray diffraction patterns of as-prepared and pressure-assisted perovskite layers were taken using X-ray diffractometer. The microstructural changes of the as-prepared and pressure-assisted perovskite layers were observed using scanning electron microscope (SEM).

### Computational Modeling

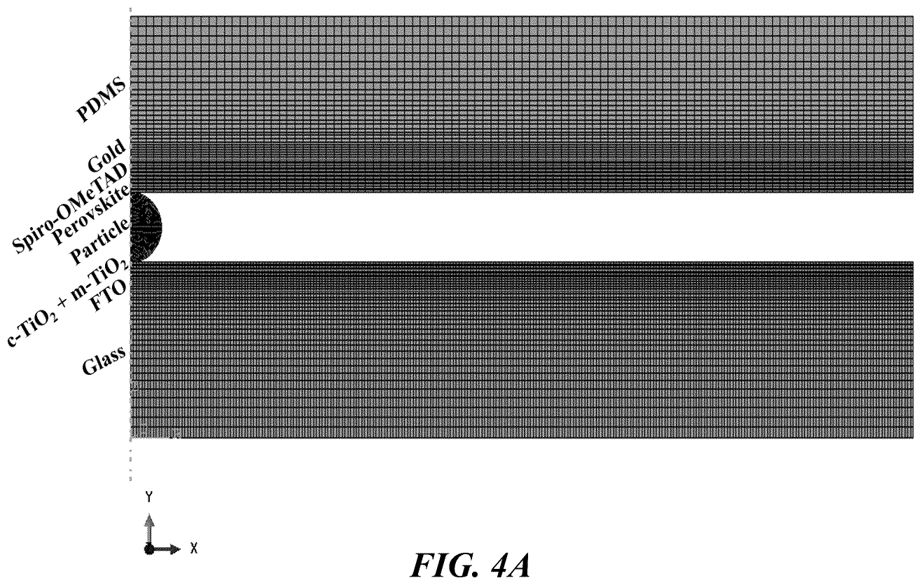

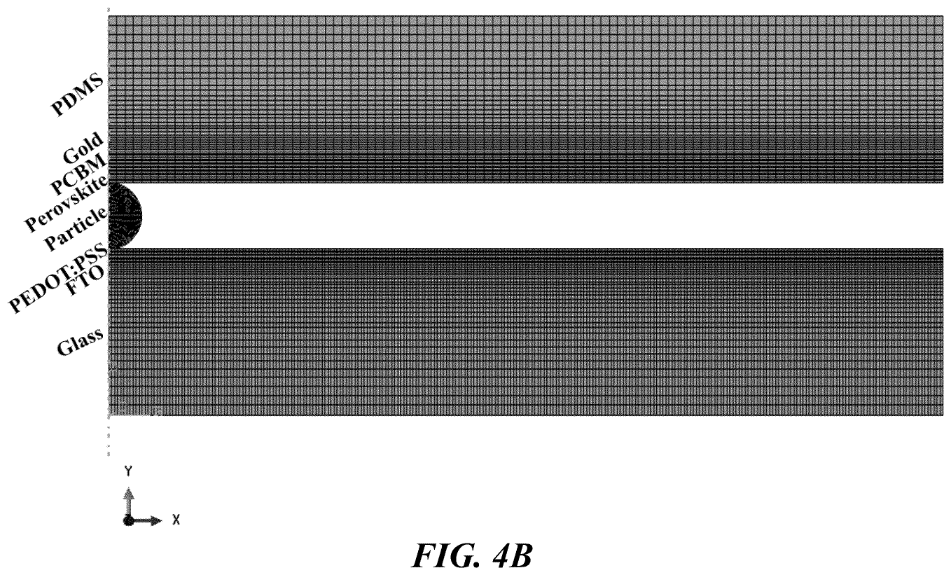

The finite element simulations of the effects of pressure treatment were carried out using the Abaqus software package. The effects of the clean room particles were considered in the simulations of contact between hole-transport layer (PEDOT:PSS) and the active layer (perovskite). The segments of the devices in the region of the embedded dust particles were analyzed in the simulations. FIGS. 4A and 4B depicts the axisymmetric geometries used. The part of the device that is farther from the dust particle would have no significant effect on the mechanics around the dust particle. Majority of the airborne particles in semiconductor clean room environment have a diameter of 1 μm, which is about four times of the thickness (250-300 nm) of the device active layer. Hence a diameter of 1 μm was chosen for the dust particle in the calculation. The mechanical properties of these particles are summarized in Table 1.

A four-node bilinear axisymmetric quadrilateral element was used in the mesh. The mesh was dense in the regions near the dust particle and the contact surfaces. Identical mesh sizes were also used in the regions near the surface contact regimes to assure convergence in contact simulation. All the materials were assumed to exhibit isotropic elastic behavior. Young's moduli of the materials were obtained from the nanoindentation experiments described prior studies. The Young's moduli and the Poisson's ratios of the materials used in the simulations are summarized in Table 2. The axisymmetric boundary condition was applied at the symmetry axis (as shown in FIGS. 4A and 4B). The bottom of the substrate was fixed to have no displacements and rotations. The outer edge of the model was also fixed to have no lateral movement for continuity, while a pressure was applied from the stamp onto the device.

TABLE 1
Materials properties of particles in a typical
semiconductor clean room environment.

| Particles | Young's modulus (GPa) | Poisson's ratio |
|---|---|---|
| Silicone | 0.001-0.02 | 0.3 |
| Photoresist | 1-8 | 0.3 |
| Aluminum | 70 | 0.3 |
| Quartz | 70-94 | 0.3 |
| Silicon | 75-200 | 0.3 |

TABLE 2
Material properties of layers used in the finite element simulations.

| | Young's modulus | | |
|---|---|---|---|
| Materials | (GPa) | Poisson's ratio | References |
| FTO | 206 | 0.32 | 26 |
| PEDOT:PSS | 1.42 | 0.3 | 16 |
| CH₃NH₃Pb₃₋ₓClₓ | 19.77 | 0.33 | 27 |
| PCBM | 8.8 | 0.3 | 28 |
| Au | 78 | 0.48 | 29 |
| PDMS | 0.003 | 0.3 | 21 |

### Results and Discussion

### Effect of Pressure on Interfacial/Surface Contact

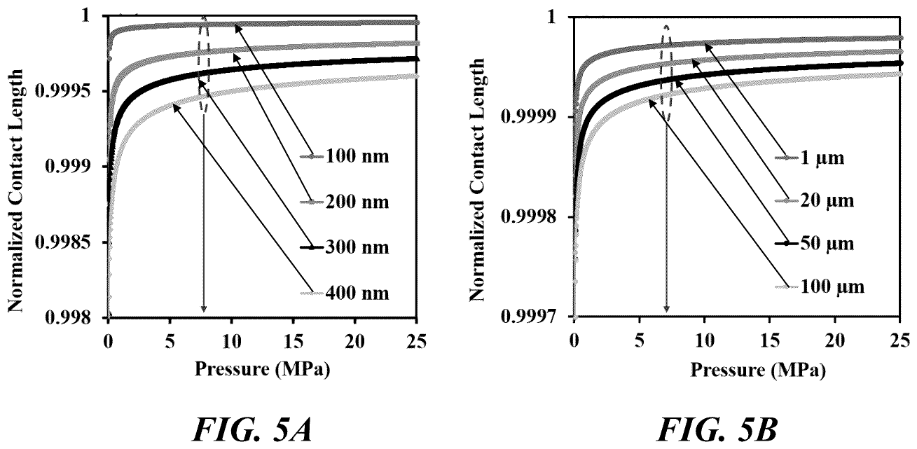

The results of the analytical modeling of the contact are presented in FIGS. 5A-5B. For different thicknesses of the perovskite films (FIG. 5B), the interfacial contact increases with increasing applied pressure. The thinner film requires less pressure to rap round the particle compared thicker film (as shown in FIG. 5B). For a typical perovskite film of 300 nm, applied pressures of ˜7-10 MPa optimize the interfacial/surface contact. In the case, where the particle sizes are different for several clean room conditions, obviously, the particle size decreases interfacial contact (FIG. 5B). Upon application of pressure the contact was improved. This implies that applications of pressure improve interfacial contact.

The results are also consistent with previous reports on organic solar cells and organic light emitting diodes. The analytical model results suggest that increased pressure caused increased in contact between the perovskite active layer and the adjacent layers, which improves transportation of charges and work function alignment across interfaces. Nevertheless, excessive pressure can lead to sink-in of dust particles, which can cause damage to the perovskite solar cell device. Therefore, for best results, moderate intermediate pressures are required for improved contact.

### Effects of Applied Pressure on Optical Properties

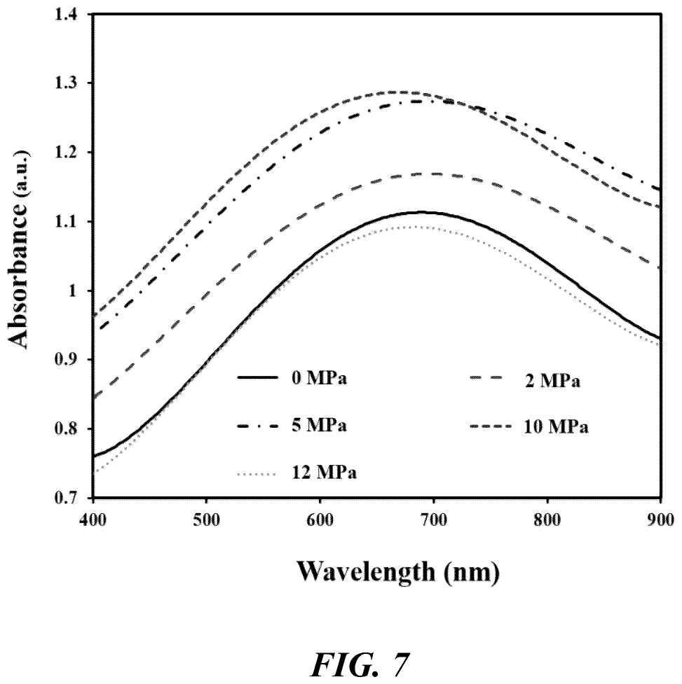

Effects of pressure of optical properties of the perovskite films are presented in FIG. 7. The effects show that the optical absorbance of the films increases when pressures are applied from 0 MPa to 10 MPa. The increase in the absorbance suggest the application of pressure compels the photoactive films to absorb light. Enhancement in the absorption of light of the perovskite solar cells increases generations of electron-hole pairs that improve the power conversion efficiencies. However, when pressure of above 10 MPa was applied on the films, the optical absorbance reduced drastically. It is important to note here that excessive application of pressure can lead to damage device cells.

### XRD Patterns and Microstructures of Photoactive Perovskite Film

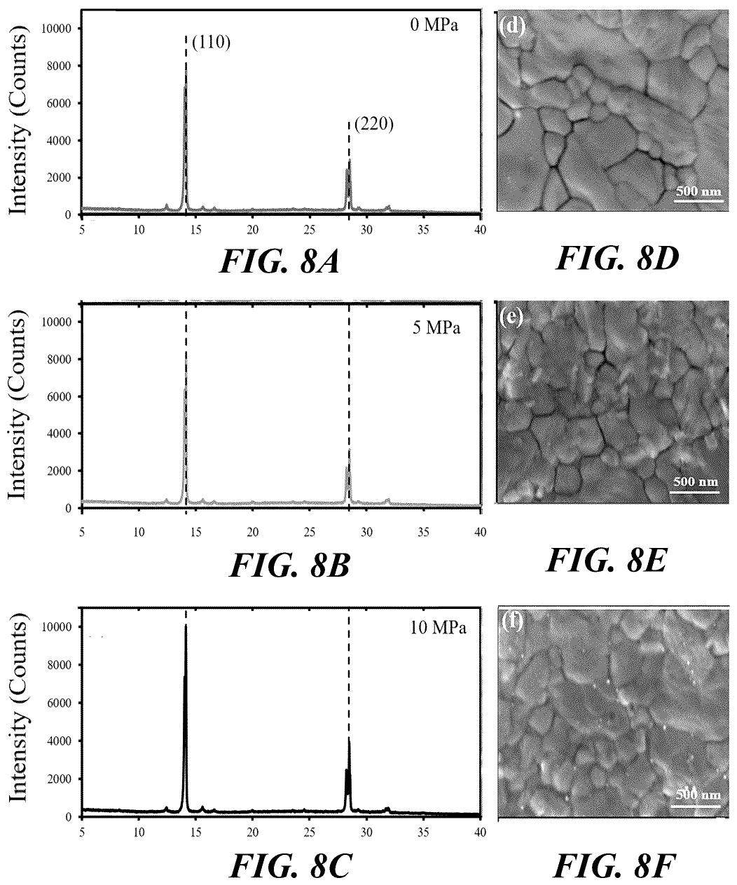

FIGS. 8A-8C present the XRD patterns of as-prepared perovskite films (FIG. 8A) and pressure-assisted films (FIGS. 8B and 8C). The intensities of the peaks increase with increasing applied pressure. This is an indication that the crystallization of the films was improved upon application of pressure. This is also an evidence of the improved absorbance of the pressure-assisted films. The microstructural images of the films are shown in FIGS. 8D-8F. Interlocking of grains increases with increasing applied pressure.

### Effects of Pressure on Current Density-Voltage Characteristics

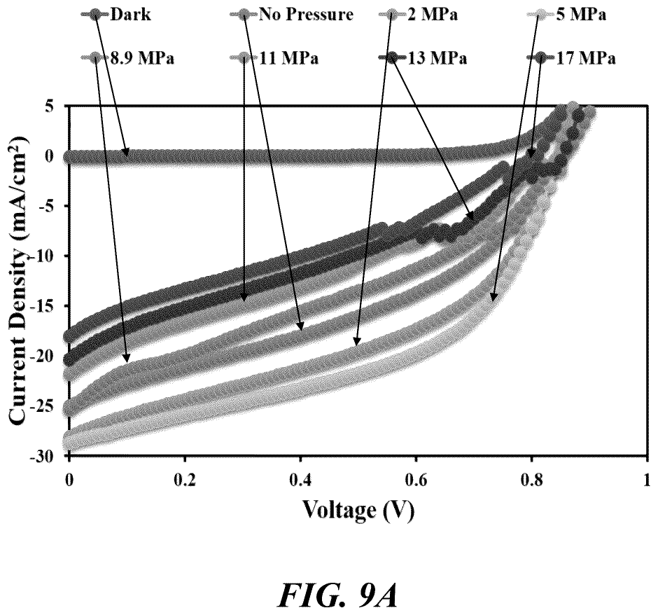

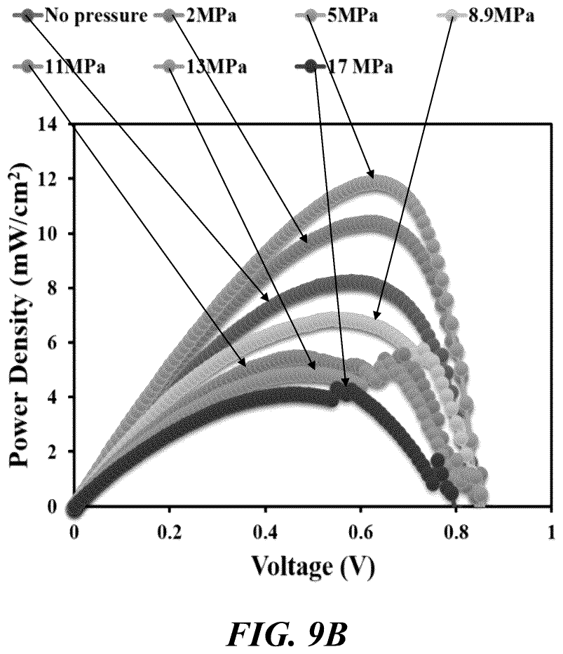

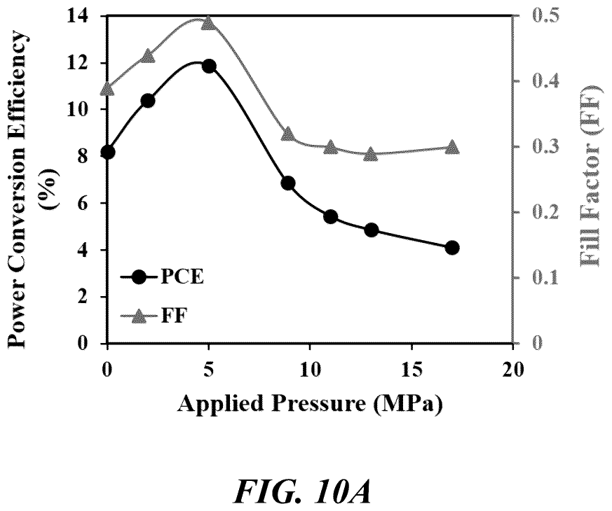

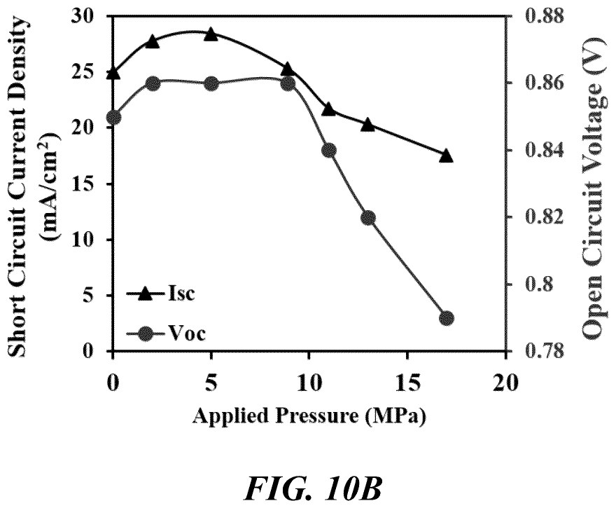

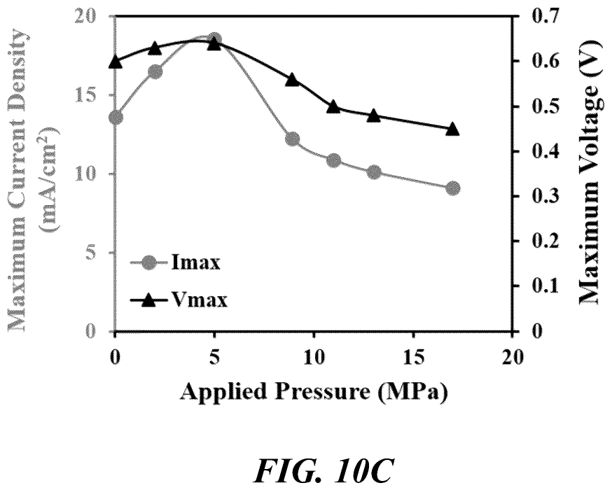

Typical current density-voltage characteristics obtained for the perovskite solar cells are presented in FIGS. 9A, while the corresponding power density-voltage curves are in FIG. 9B. Each of the curves is an average of the electrical characterization results for eight devices. The detailed device characteristic parameters are presented in FIGS. 10A-10C. In the case of the perovskite solar cell that was fabricated without the application of pressure, the Power Conversion Efficiency (PCE) and Fill Factor (FF) were 8.2% and 0.39, respectively. As shown in FIG. 10A, upon the application of pressure (up to 5 MPa), the PCE and FF increased up to 11.88% and 0.49, respectively. However, both PCE and FF decreased drastically to 4.1% and 0.3, respectively, for applied pressures between ˜5-17 MPa. These show that the performance of the devices increases with applied pressure but decreases at very high pressures. This trend in the power conversion efficiencies is related to the improved surface contacts (at lower pressures) and sink-in phenomena (at higher pressures).

The device short circuit current densities (J_{sc}) and open circuit voltage (V_{oc}) at different applied pressures are presented in FIG. 10B, while the maximum current-density and maximum voltage are in FIG. 10C. There is an increase in the device characteristic parameters between the applied pressure of 0-5 MPa, while there is a decrease when high pressures between 5 MPa and 17 MPa are applied.

### Implications

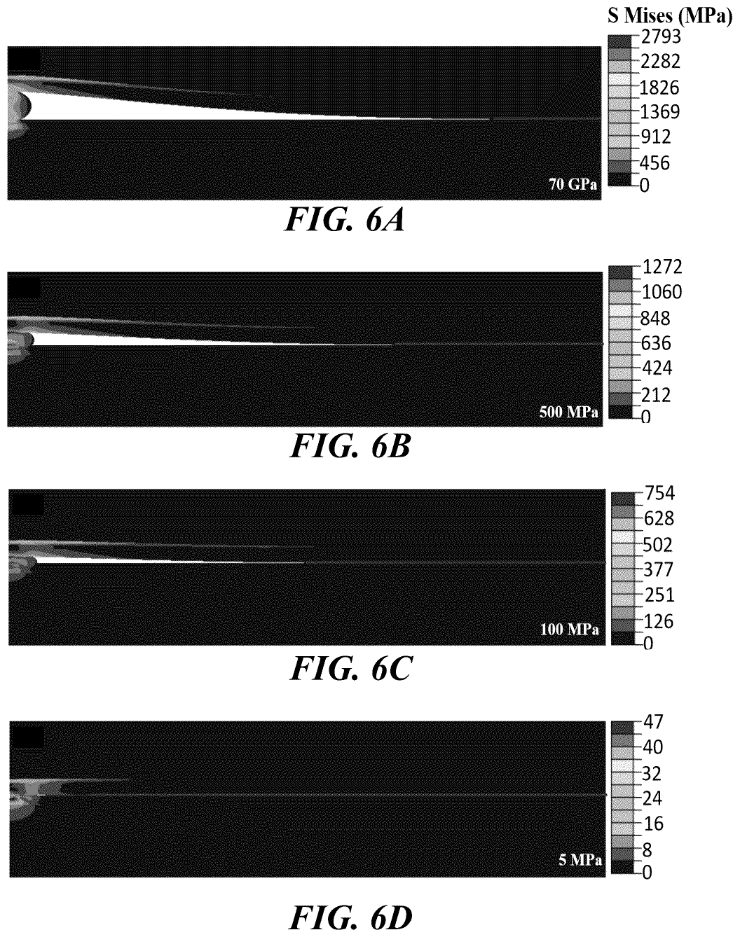

The study shows that the power conversion efficiencies of perovskite solar cells can be significantly improved by the application of pressure. The effects of pressure are credited to the closing of voids or the corresponding increase in the contact lengths. The contact lengths increase under pressure, while the void lengths decrease under pressure (as shown in FIGS. 6A-6D, resulting in increased contact area across the interfaces in the perovskite solar cell structures. For example, the interfacial contact increases as the Young's modulus of the particles decreases from 70 GPa (hard particle) to 5 MPa (soft particle). The stresses in the structure also decreases with decreasing Young's modulus of the dust particles. Hence, the improvement in the power conversion efficiency that was observed after the application of pressure is attributed largely to the increased contact areas due to the application of pressure.

Therefore, the performance of perovskite solar cell structures can be enhanced by the application of controlled levels of pressure during lamination and stamping processes. Such pressure may be applied after using the conventional spin-coating and thermal evaporation techniques to deposit the individual layers in the perovskite solar cell structures. In applying the pressure, caution must be taken to ensure that the applied pressure does not lead to sink-in which results to layer deformation and hence damage of the device. Improvements like this could promote the development of robust low-cost and roll-to-roll processes for the fabrication of perovskite solar cells with competitive power conversion efficiency.

### Conclusion

The results of Example 1 show that, increased pressure is associated with decreased void length or increased contact length. The power conversion efficiency also increased under the influence of pressure compared to the pressure-free device. The contacts associated with the interfaces between the active layer and the hole/electron injection layer improved by the application of pressure, resulting in higher PCE.

### Example 2—Pressure-Assisted Fabrication of Organo-Metallic Perovskite Light Emitting Devices

Example 2 shows that the interfacial surface contact lengths increase with increasing applied pressure. The current-voltage characteristics of the PLEDs are shown to reduce the turn-on voltages with increasing applied pressure (˜0-9 MPa). Increased applied pressure is also shown to result in a reduction of the band gaps (from 2.5-2.1 eV) of PLEDs, for pressures between 0 MPa and 9 MPa. The implications of the results are discussed for the pressure-assisted fabrication of perovskite light emitting devices. These results were derived from the Example 2 below.

### Processing of PLEDs

The architecture presented in FIG. 3A was used for the device fabrication. ITO-coated glass substrates (Sigma-Aldrich) were etched carefully using zinc powder and 2 M HCl, (Sigma-Aldrich). The etched surfaces were mechanically abraded with cotton swabs and washed with deionized water. Subsequently, the etched ITO-coated glass substrates were sequentially cleaned by sonification with Decon 90, DI water, acetone and isoproplyl alcohol (IPA) before blow-drying with Nitrogen gas. Further cleaning of the substrates was done in UV ozone cleaner (Name, Model, City, Country) for 20 minutes to remove any organic contaminants.

A hole-blocking and electron transport layer (ETL) of compact titanium oxide (c-TiO₂) was spin coated onto the cleaned substrates from a mixture of titanium (diisopropoxide) 75% in isopropanol (Sigma Aldrich) and a solution of 2 M HCl (Merck KGaA) in ethanol. The spin-coating of the c-TiO₂ was done for 30 s at 4000 rpm before it was sintered at 300° C. for 30 minutes. A mesoporous layer of Al₂O₃ nanoparticles, 20% wt % in isopropanol (Sigma Aldrich), was then spin-coated onto the sintered c-TiO₂ and annealed at 150° C. for 15 minutes.

Mixed halide perovskite, CH₃NH₃PbI₃₋ₓClₓ, was used as the emissive layer. The precursor was prepared by dissolving CH₃NH₃I and PbCl₂ (3:1 molar ratio) in anhydrous N,N-dimethylformamide (DMF) to give a concentration of 10 wt %. The mixture was then stirred at for 2 hours before it was filtered using 0.45 μm mesh. The filtered perovskite solution was spin-coated onto Al₂O₃/c-TiO₂/ITO-glass at 500 rpm for 30 s and 1500 rpm for 50 s. This was then annealed at 95° C. for 20 minutes to form a thin film of perovskite.

A composite of poly(3,4-ethylenedioxythiophene)-poly(styrenesulfonate) (PEDOT:PSS) and molybdenum (VI) oxide (MoO₃) was used as hole transport layer (HTL). was prepared by dissolving 5 mg of MoO₃ in 1 mL of IPA before blending with PEDOT:PSS in ratio 1:3. The solution was deposited on the emissive layer by spin coating at 4000 rpm for s, followed by annealing at 95° C. for 15 minutes to remove any residual solvent in the thin film. Finally, a 150 nm thick silver layer was thermally evaporated onto PEDOT:PSS/MoO₃ using an Edwards E306A thermal evaporator (Edwards, Sussex, UK), which was operated at a vacuum of 10⁻⁶ Torr. The device area of ˜0.09 cm² was defined using a shadow mask.

### Application of Pressure

First, a PDMS anvil was fabricated from a mixture of Sylgard 184 Silicone elastomer (Sylgard 184, Dow Corning) base and Sylgard 184 silicone elastomer curing agent in volume ratio 10:1, respectively. The mixture was poured into a glass mold of dimension mm×20 mm×5 mm and then degassed in a vacuum oven for 30 min to allow all bubbles to disappear at 25 kPa. The degassed PDMS was then cured for 2 hours at 80° C. Pressure was applied on the fabricated PLEDs using the 5848 MicroTester Instron. The configuration of the set is shown in FIG. 3B. The Instron was operated in compression mode, while its head was set to absolutely ramp at 1.0 mm/min and holds for 10 min at a pressure of 3 MPa. This procedure was repeated at different pressure between 0 MPa and 12 MPa. All measurements were taken under ambient temperature.

### Materials Characterization and J-V Curves Measurements

The current density-voltage (J-V) curves of the PLEDs were measured using Keithley Source Meter Unit (SMU) 2400. The source meter was connected to the devices while the voltage was sourced in sweep mode between 0 and 3 V. The I-V curves of the as-prepared devices were then measured. This procedure was repeated for other devices that were assisted with pressure. Optical transmittance of Al₂O₃/TiO₂/ITO-glass, as well as the optical absorbance of the spin-coated emitter was measured at different applied pressure using Avantes UV-VIS NIR spectrometer. The images of the spin-coated perovskite layers were obtained using an OMAX optical microscope (OMAX Microscope, Gyeonggi-do, South Korea) and scanning electron microscope (SEM). Also, the structures of the as-prepared and pressure-assisted perovskite layers were studied using PANalytical's X-ray diffractometer.

### Computational Modeling

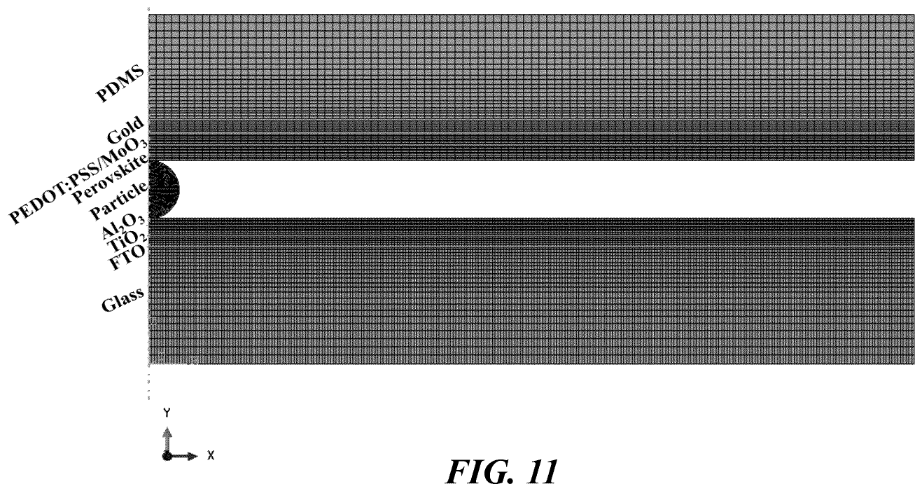

The finite element simulations of the effects of pressure treatment were carried out using the Abaqus software package. The effects of the clean room particles were considered in the simulations of contact between electron-transport layer and the active layer (perovskite). The segments of the devices in the region of the embedded dust particles were analyzed in the simulations. For simplicity, axisymmetric geometries were used as shown FIG. 11. It is assumed that the part of the device, which is farther from the dust particle, was have no significant effect on the mechanics around the dust particle. Majority of the airborne particles in semiconductor clean room environment have a diameter of 1 μm, which is about four times of the thickness (250-300 nm) of the device active layer. Hence a diameter of 1 μm was chosen for the dust particle in the calculation. The mechanical properties of these particles are summarized in Table 3.

A four-node bilinear axisymmetric quadrilateral element was used in the mesh. The mesh was dense in the regions near the dust particle and the contact surfaces. Identical mesh sizes were also used in the regions near the surface contact regimes to assure convergence in contact simulation. All the materials were assumed to exhibit isotropic elastic behavior. Young's moduli of the materials were obtained from the nanoindentation experiments described prior studies. The Young's moduli and the Poisson's ratios of the materials used in the simulations are summarized in Table 4. The axisymmetric boundary condition was applied at the symmetry axis (as shown in FIG. 3B). The bottom of the substrate was fixed to have no displacements and rotations. The outer edge of the model was also fixed to have no lateral movement for continuity, while a pressure was applied from the stamp onto the device.

TABLE 3
Materials properties of particles in a typical
semiconductor clean room environment

| Particles | Young's modulus (GPa) | Poisson's ratio |
|---|---|---|
| Silicone | 0.001-0.02 | 0.3 |
| Photoresist | 1-8 | 0.3 |
| Aluminum | 70 | 0.3 |
| Quartz | 70-94 | 0.3 |
| Silicon | 75-200 | 0.3 |

TABLE 4
Material properties of layers used in the finite element simulations.

| | | Poisson's |
|---|---|---|
| Materials | Young's modulus (GPa) | ratio |
| FTO | 206 | 0.32 |
| TiO₂ | 239 | 0.29 |
| CH₃NH₃Pb₃₋ₓClₓ | 19.77 | 0.33 |
| PEDOT:PSS/MoO₃ | 64.5 | 0.3 |
| Au | 78 | 0.48 |
| PDMS | 0.003 | 0.3 |

### Results and Discussion

### Interfacial Surface Contacts

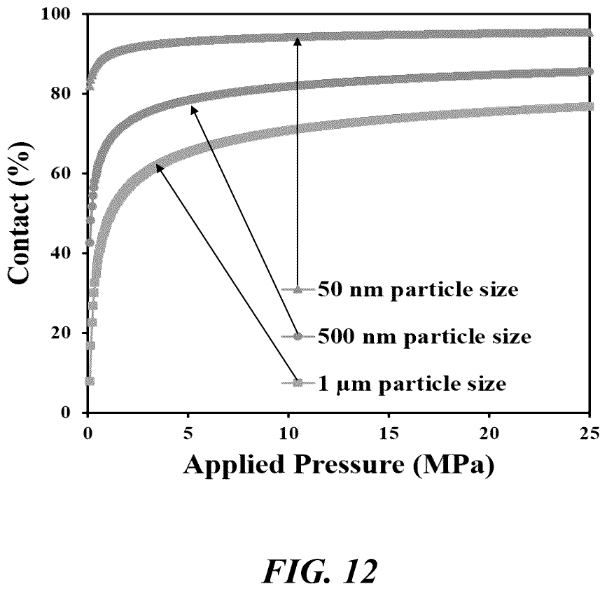

The results obtained for contact length as a function of the applied pressure for various particle sizes are presented in FIG. 12, which shows that the contact length is high for low size particles, even at 0 MPa. However, application of pressure increases the contact length significantly, especially for particles with higher sizes.

In other words, impurity with low particle size requires low pressure, while those with higher particle size require relatively higher pressure to achieve optimum interfacial contact. But attention must be paid to the optimum pressure that is needed for the adequate contacts which will not lead to sink-in in the adjacent layer that can damage the device.

### Optical Properties

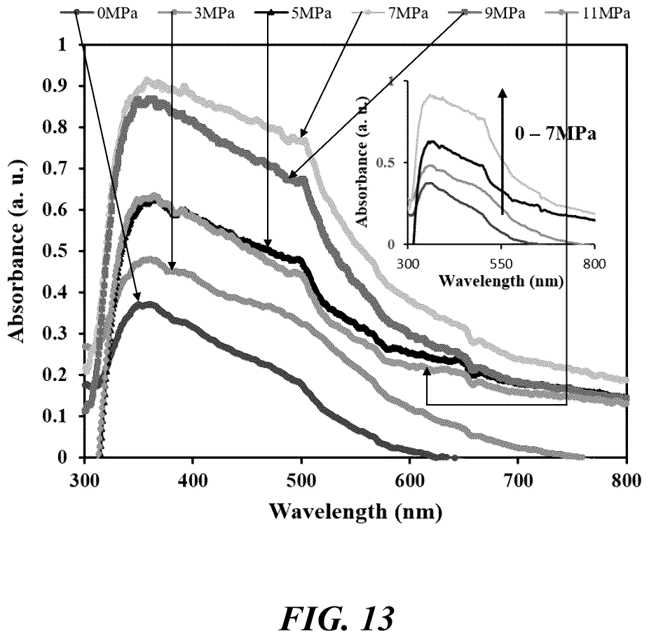

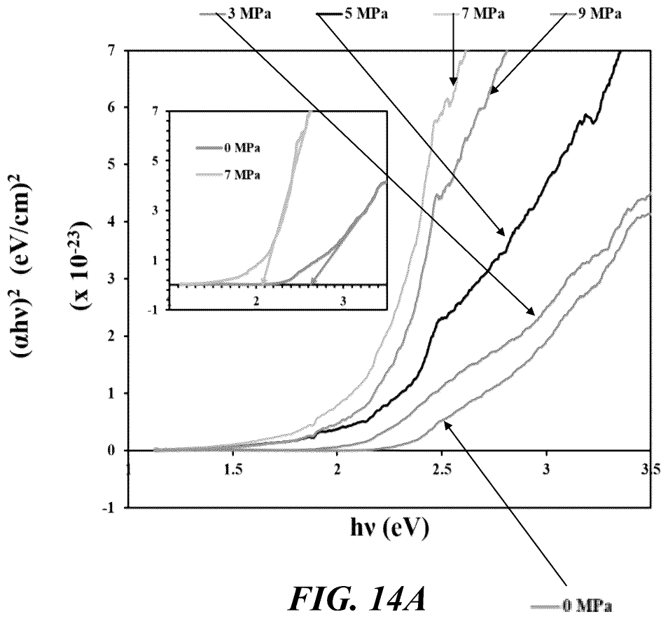

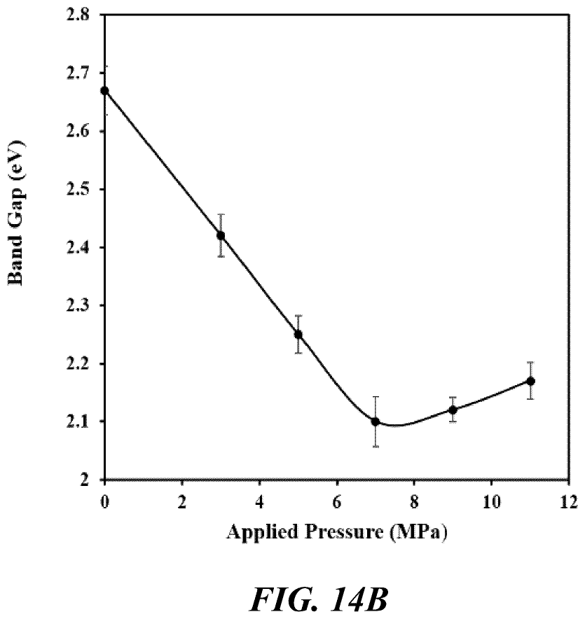

The optical absorbance of the mixed halide perovskite (CH₃NH₃PbI₃₋ₓClₓ) that was used as the emitter is presented in FIG. 13. The results showed an increase in the absorbance of the emissive material with increase in pressure. As the amount of pressure approaches the optimum value, the absorption tends to reduce. This is an indication that pressure application also agrees with the fact that application of pressure can improve hole-electron pair generation for improved performance of the device. The plot of (αhv)² as a function of photon energy (hv) for the emissive layer was obtained from the following equation: (αhv)²=hv−E_{g}, where a is absorbance, hv is the photon energy and E_{g} is the band gap energy. The was done by using the absorption spectra for the emissive layer. This is presented in FIG. 14A for different applied pressure. According to this equation, the bang gap (E_{g}) was estimated as the intercept of the curves along the photon energy. The estimated band gap is plotted as a function of applied pressure in FIG. 14B. The results show that the band gap reduces for the pressure applied between 0 MPa and 8 MPa.

### Effects of Pressure on XRD Patterns and Microstructure

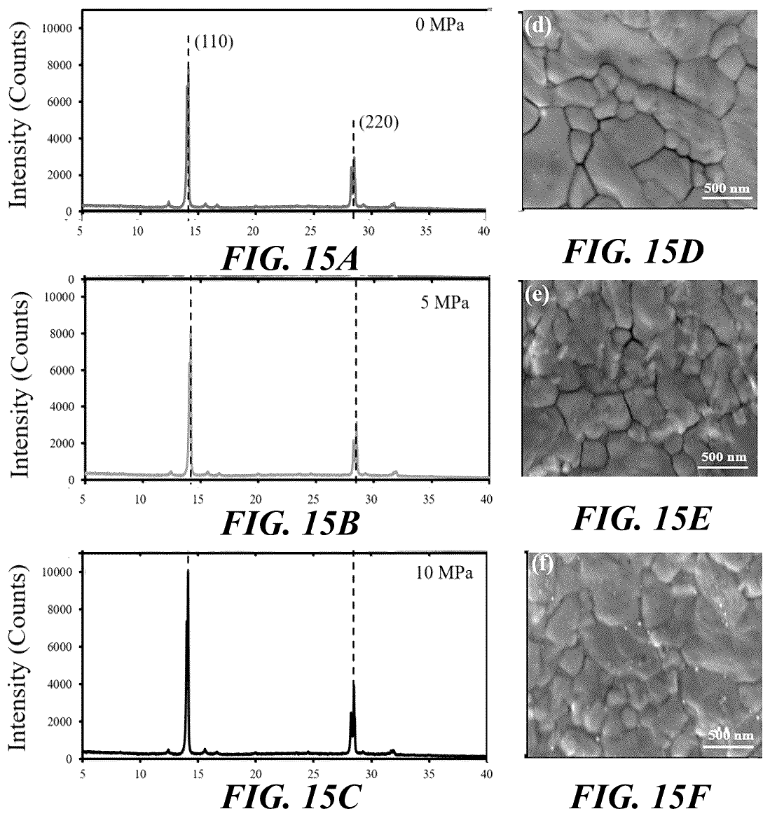

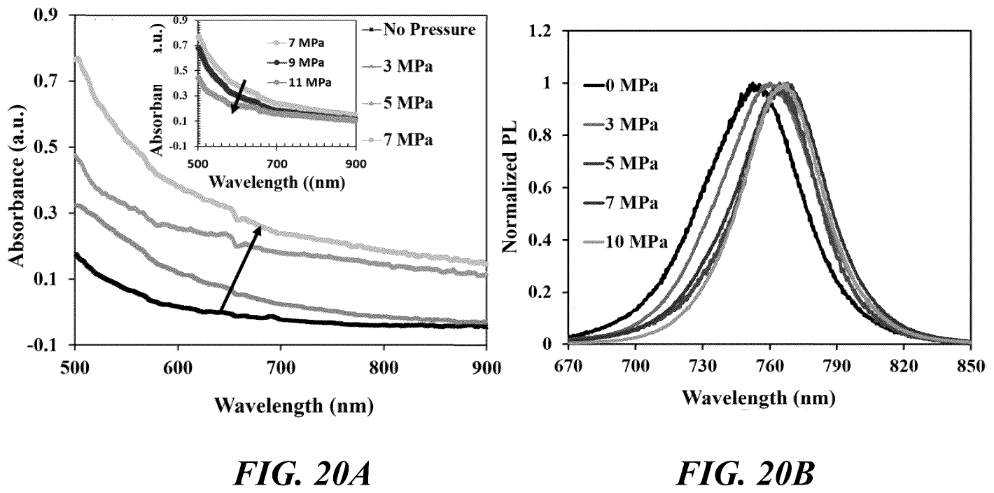

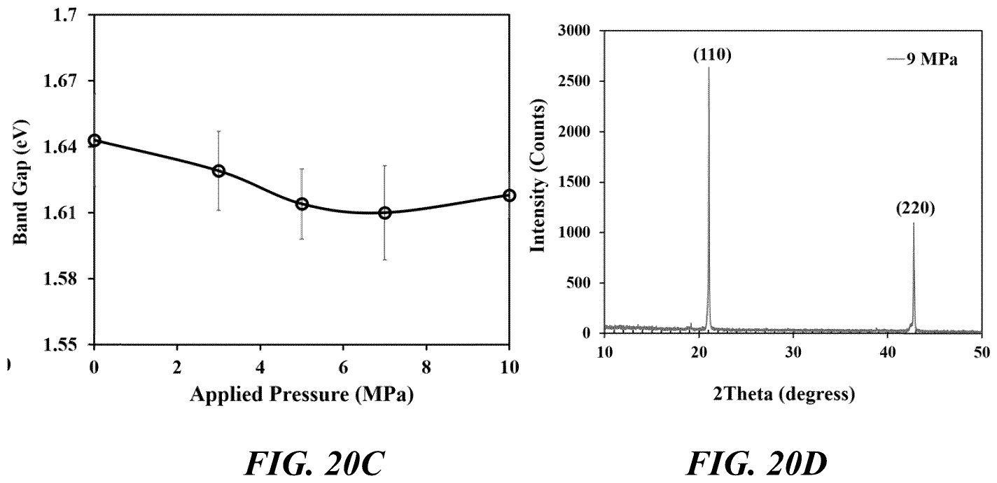

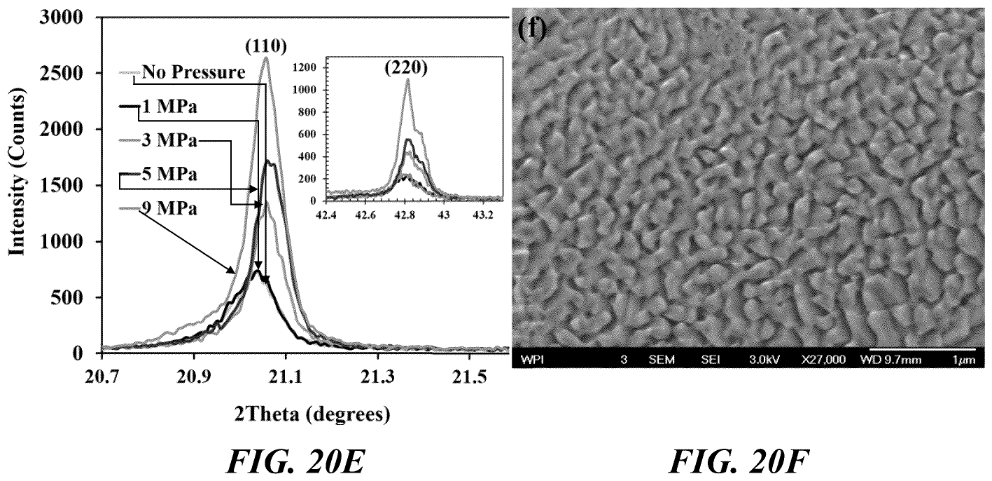

The X-Ray diffractometry patterns of mixed halide perovskite (CH₃NH₃PbI₃₋ₓClₓ) films are presented in FIGS. 15A-15F along with the Scanning Electron Microscopy (SEM) images at different applied pressure. The intensity of the peaks increased with increasing pressure (FIG. 15A-15C). It was observed that the sample patterns are in good accordance with the hexagonal structure and peaks at 14° and 28°. Also, they can be attributed to the crystal planes (110) (FIG. 20D) and (220) (FIG. 20E) respectively. The SEM images of the films in FIGS. 15D-15F showed that the integrity of the microstructures remain the same with well interlocked grains as the applied pressure increases. However, the patches of the pressure are evident at 10 MPa.

### Effects of Pressure on Performance

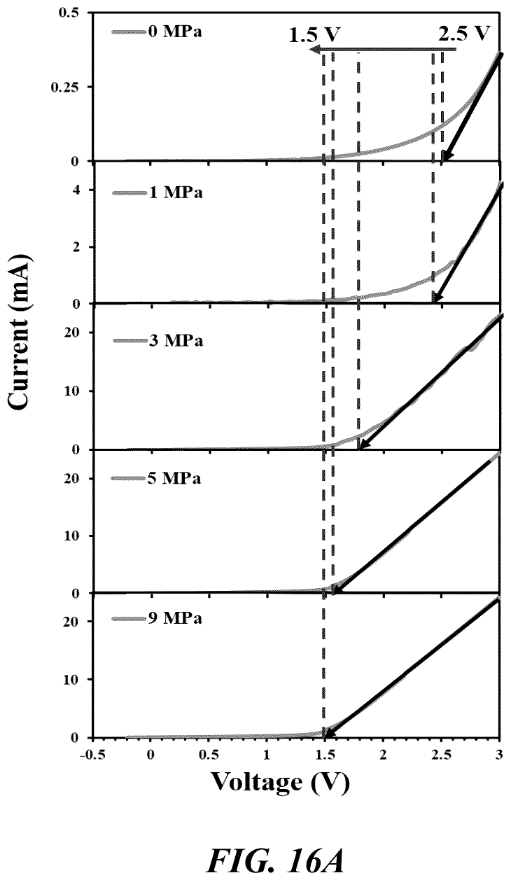

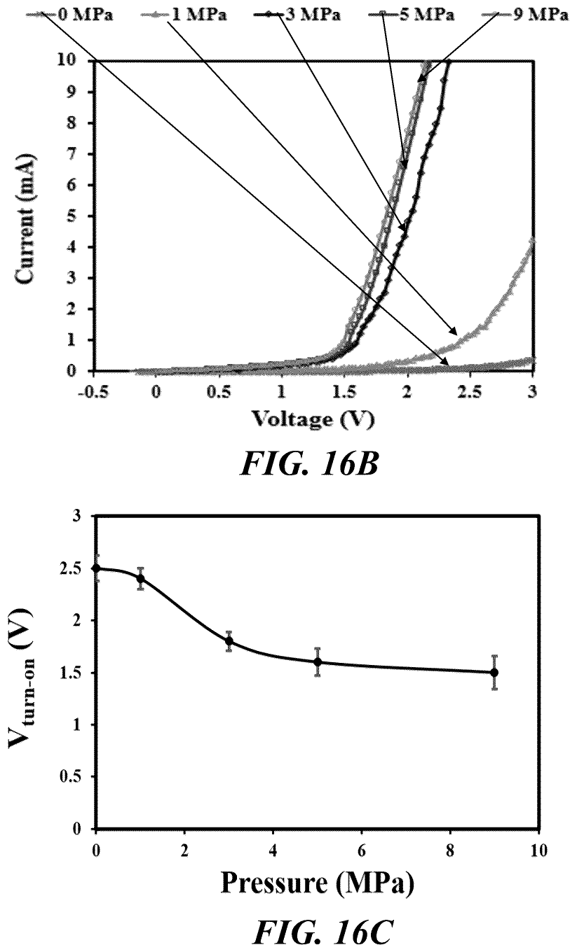

The results of the current-voltage (I-V) characteristics curves of the fabricated PLEDs are presented in FIGS. 16A-16C. These are for as fabricated and pressure assisted devices. FIG. 16A presents the I-V curves of the devices at different applied pressure, showing the estimation of the corresponding turn-on voltages. A combined I-V curves of the devices, at different applied pressure, is presented in FIG. 16B. Each curve represents the average of I-V curves of 5 different devices. FIG. 16C depicts the turn-on voltage as a function of pressure. It was observed that the turn-on voltage reduces from 2.5 V to 1.5 V for the pressures between 0 MPa to 9 MPa. These results can be attributed to the fact that pressure application on PLED structures improves interfacial contacts as shown in FIG. 10A-10C. Similar results have been shown for multilayer structures of organic solar cells and organic light emitting devices. The decrease in the interfacial void with applied pressure consequently increases the interfacial contact length, which in turn enhances work function alignment and charge transport. The increase in the transportation of charges increases recombination. This is evident in the increase in the optical absorbance (FIG. 13) of the emissive layer that suggests generation of hole-electron pairs. The reduction in the band gap (FIGS. 14A and 14B) is also an indication that electrons requires less energy to cross the band gap and recombine to emit photon light.

### Conclusion

The results of Example 2 show that, increased pressure is associated with decreased void length or increased contact length. The turn-on voltage reduced with increase in applied pressure. This is due to the improvement in interfacial surface contacts within the multilayer structure.

### Example 3—Pressure-Assisted Fabrication of Perovskite Light Emitting Devices

Example 3 shows the pressure-effects on performance characteristics of near-infra-red perovskite light emitting diodes (PeLEDs) using a combination of experimental and analytical/computational approaches. First, pressure-effects are studied using models that consider the deformation and contacts that occur around interfacial impurities and interlayer surface roughness in PeLEDs. The predictions from the model show that the sizes of the interfacial defects decrease with increasing applied pressure. The current-voltage characteristics of the fabricated devices are also presented. These show that the PeLEDs have reduced turn-on voltages (from 2.5 V to 1.5 V) with the application of pressure. The associated pressure-induced reductions in the defect density and the bandgaps of the perovskite layer can explain the improved performance characteristics of the PeLED devices. These results were derived from Example 3 below.

### Processing of PeLEDs

Indium tin oxide (ITO)-coated glass substrates (Sigma Aldrich) were etched carefully using zinc powder and 2M hydrochloric acid (HCl) (Sigma Aldrich). The etched surfaces were mechanically abraded with cotton swabs and washed with deionized water (DI). Subsequently, the etched ITO-coated glass substrates were sequentially cleaned by sonification with Decon 90, DI water, acetone, and isopropyl alcohol (IPA) before blow-drying with nitrogen gas. Further cleaning of the substrates was done in an ultraviolet (UV)-ozone cleaner (Novascan, Main Street Ames, IA, USA) for 20 min to remove any organic contaminants.

A compact titanium oxide (c-TiO2) was spin-coated onto the cleaned substrates from a 0.3M solution of titanium (diisopropoxide) (75% in isopropanol, Sigma Aldrich) in 1-butanol. The spin-coating of c-TiO2 was carried out for 30 s at 4000 rpm before annealing at 300 C for 30 min. A mesoporous layer of Al₂O₃ nanoparticles (20 wt. % in isopropanol, Sigma Aldrich) was then spin-coated onto c-TiO2 at 5000 rpm for 30 s and annealed at 150° C. for 15 min.

A mixed halide perovskite, CH₃NH₃PbI₃₋ₓClₓ, was used as the emissive layer. The precursor was prepared by dissolving CH₃NH₃I and PbCl₂ (3:1 M ratio) in anhydrous N,N-dimethylformamide (DMF) to give a concentration of 10 wt. %. 5 The mixture was then stirred at 60 C for 2 h, before it was filtered using a 0.45 μm mesh. The filtered perovskite solution was spin-coated onto Al2O3/c-TiO2/ITO-glass at 3000 rpm for 30 s. This was then annealed at 95 C for 20 min to form a thin film of perovskite.

A composite of poly(3,4-ethylenedioxythiophene)-poly(styrenesulfonate) (PEDOT:PSS) and molybdenum (VI) oxide (MoO3) was used as a hole transport layer (HTL). This was prepared by dissolving 5 mg of MoO3 in 1 ml of IPA before blending with PEDOT:PSS in ratio 1:3.50. The solution was deposited onto the emissive layer by spin coating at 4000 rpm for 40 s, followed by annealing at 95 C for 15 min to remove any residual solvent in the thin film. Finally, a 150 nm thick silver layer was thermally evaporated onto PEDOT:PSS-MoO3/CH3NH3PbI3-xClx/Al2O3/c-TiO2/ITO-glass using an Edwards E306A thermal evaporator (Edwards, Sussex, UK), which was operated at a vacuum of 10 6 Torr. The device area of 0.1 cm2 was defined using a shadow mask.

To identify the effects of pressure on the mobility of carrier and the density of trap states caused by the presence of defects in the perovskite film, a single carrier (hole-only) device was fabricated using the structure, ITO/PEDOT:PSS-MoO3/perovskite/spiro-OMeTAD/Ag. Spiro-OMeTAD was prepared by mixing 72 mg of spiro-OMeTAD, 17.5 μl of lithium bis(trifluoromethylsulfonyl)imide (Li-FTSI) (Sigma Aldrich) (500 mg in 1 ml of acetonitrile), and 28.2 μl of 4-tert-butylpyridine (tBP) (Sigma Aldrich) in 1 ml of chlorobenzene. This was then spin-coated onto the perovskite layer at 5000 rpm for 40 s, while other layers were deposited following the above procedures.

### Pressure Experiments

First, a PDMS anvil was fabricated from a mixture of Sylgard 184 silicone elastomer (Sylgard 184, Dow Corning) base and Sylgard 184 silicone elastomer curing agent in a volume ratio of 10:1. The mixture was poured into a glass mold of dimension 20 mm 20 mm 5 mm and then degassed in a vacuum oven for 30 min. This was done to allow all bubbles to disappear at 25 kPa. The degassed PDMS was then cured for 2 h at 60° C.

Pressure was then applied on the fabricated PeLEDs using 5848 MicroTester Instron (Instron, Norwood, MA, USA). The configuration of the set is shown in FIG. 3D. Instron was operated in the compression mode, while its head was set to absolutely ramp at 1.0 mm/min and holds on the devices for 10 min at a pressure of 1 MPa. This procedure was repeated at different pressures between 0 MPa and 12 MPa. All the measurements were obtained under ambient conditions (25° C.).

### Characterization

Both as-prepared and pressure-assisted spin-coated perovskite emitters were characterized. The optical absorbance of the films was measured for the different applied pressures. This was done using an Avantes UV-VIS NIR spectrometer (Avantes, BV, USA), while the microstructures of the films and the cross sections of devices were obtained using a Scanning Electron Microscope (SEM) (JEOL 7000F, JEOL, Inc., MA, USA). The x-ray diffraction patterns of the films were obtained using an x-ray diffractometer (Empyrean, PANalytical, USA) under the Cu Kα radiation source with a beta nickel filter at 40 KV and 40 mA. Photoluminescence (PL) spectrum measurements were obtained using the Horiba MicOS microscope optical spectrometer system that consists of a Horiba iHR550 spectrometer, a luminescence microscope with a 50 Edmund Optics Plan Apo NIR Mitutoyo objective, and a Horiba Synapse EM CCD camera. The PL spectrum measurements were then obtained using a single photon counter module (SPD-OEM-VIS, Aurea Technology) and an acquisition software interface.

The current-voltage (I-V) curves of the PeLEDs were measured using Keithley Source Meter Unit (SMU) 2400 (Keithley, Tektronix, Newark, NJ, USA). The source meter was operated using the Kickstart software by sweeping voltages between 0 V and 3 V to measure current in the dark. The I-V curves of the as-prepared devices were then measured. This procedure was repeated for other devices that were assisted with pressures between 0 MPa and 12 MPa.

### Computational Modeling

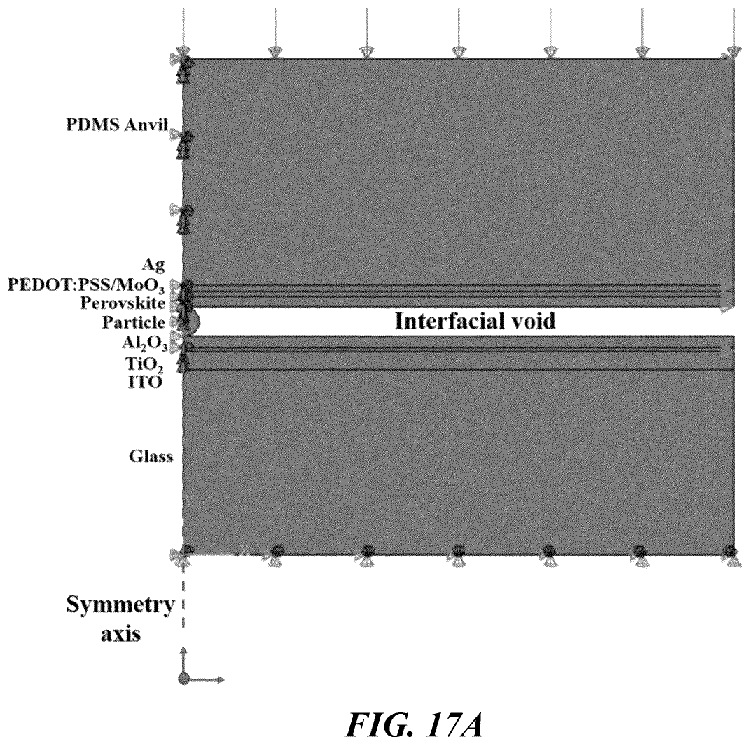

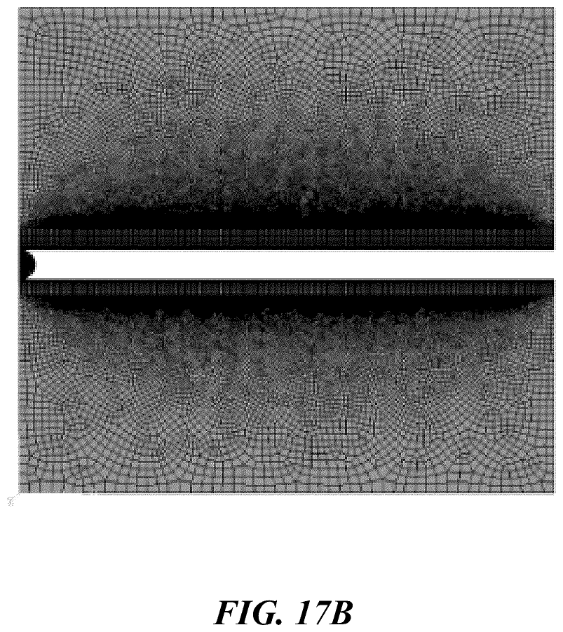

The finite element simulations of the effects of pressure on multilayered PeLED structures were carried out using the Abaqus software package (Dassault Systèmes Simulia Corporation, Providence, RI, USA). The segments of the devices in which the region of the embedded particles between electron transporting and photoactive perovskite layers was analyzed in the simulations. For simplicity, axisymmetric geometries were used as shown in FIGS. 17A and 17B. It is assumed that the part of the device, which is farther from the dust particle, has no significant effect on the mechanics around the dust particle.

A four-node bilinear axisymmetric quadrilateral element was used in the mesh. The mesh was dense in the regions near the particle and the contact surfaces. Identical mesh sizes were also used in the regions near the surface contact regimes to ensure convergence in contact simulation. All the materials were assumed to exhibit an isotropic elastic behavior. Young's moduli and Poisson's ratios of the materials for different layers of the PeLEDs are summarized in Table 5. The bottom of the substrate was fixed to have no displacements and rotations. The outer edge of the model was also fixed to avoid lateral movement for continuity, while pressures were applied from the stamp onto the device as depicted by FIG. 17A. The mesh density of the model is depicted in FIG. 17B.

TABLE 5
Mechanical properties of materials for
different layers and dust particles.

| | Young's | |
|---|---|---|
| | modulus | Poisson's |
| Materials | (GPa) | ratio |
| ITO | 116 | 0.35 |
| TiO₂ | 202 | 0.31 |
| Al₂O₃ | 385 | 0.3 |
| CH₃NH₃PbI₃₋ₓClₓ | 19.77 | 0.33 |
| PEDOT:P | 1.42 | 0.3 |
| SS | | |
| Ag | 76 | 0.48 |
| PDMS | 0.0036 | 0.48 |
| Particle | 70 | 0.3 |

### Results and Discussion

### Interfacial Surface Contacts

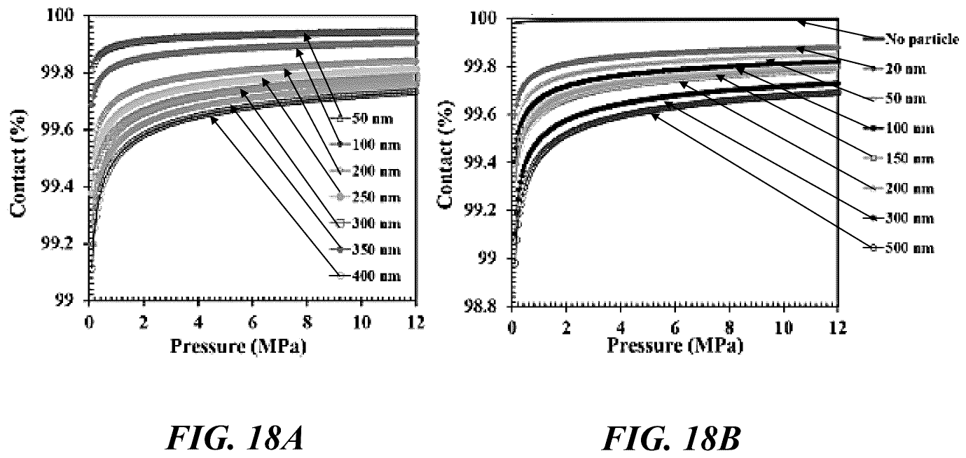

The surface contact lengths between the perovskite layer and the adjacent layers were estimated from equation 1 for different applied pressures between 0 MPa and 12 MPa. FIGS. 18A and 18B present the effects of pressure on the estimated surface contact lengths. The results show that the surface contacts increase with increasing applied pressure.

FIG. 18A presents the surface contacts for different thicknesses of the perovskite films. The surface contact increases as the thickness of the film decreases with increasing applied pressure. FIG. 18B presents the effects of pressure on the perovskite film for different sizes of the particle. The results show that, for small particle sizes, perovskite films require less pressure for surface contact with the adjacent layer compared to big particle sizes.

It is important to note that perovskite films with small particle size require low pressure, while those with big particle size require relatively higher pressure to achieve an optimum interfacial surface contact. An optimum pressure for the adequate surface contacts can avoid the sink-in of particles into adjacent layers, which can damage the device.

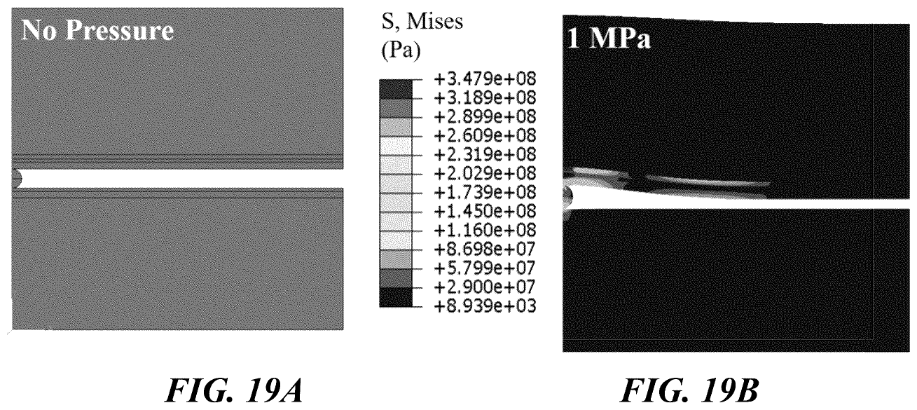

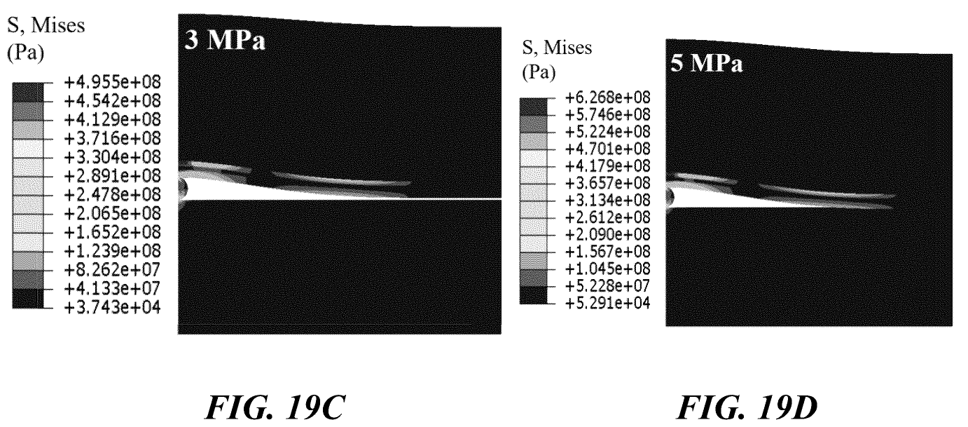

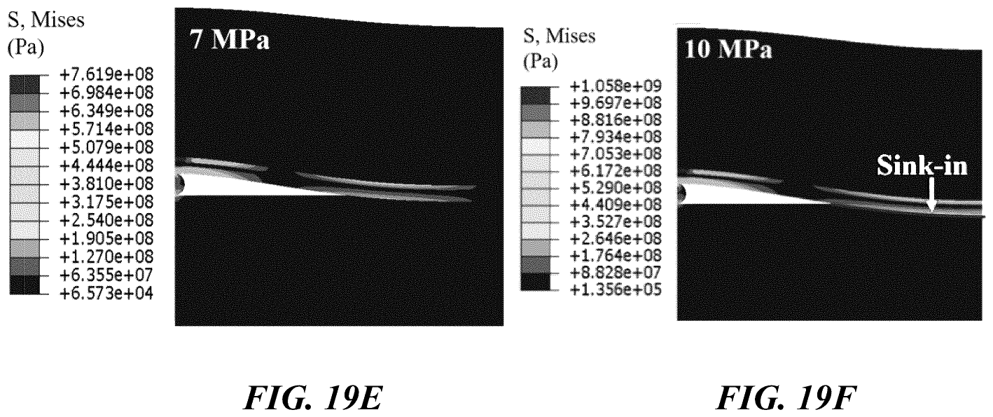

To study the interfacial stress due to the applied pressure on the multilayered PeLED structures, FIGS. 19A-19F present the results of finite element simulations of the device interface between the photoactive perovskite and electron transporting layers before and after pressure application. FIG. 19A depict the von Mises stresses within layers and interfaces before pressure application. FIGS. 19B-19D depict pressure-assisted devices at 1 MPa (FIG. 19B), 3 MPa (FIG. 19C), 5 MPa (FIG. 19D), 7 MPa (FIG. 19E), and 10 MPa (FIG. 19F). The results show that the interfacial surface contacts increased with increasing pressure between 0 MPa and 12 MPa.

There is an increase in the distribution of von Mises stress within layers and around the interfacial defects as the applied pressure increases. However, there is evidence of sink-in of the top layer to the bottom at higher pressure FIG. 19F. The PDMS anvil and top layers of the device deformed accordingly and curl round the particle as the surface contact improves. It is important to note that, by comparing the level of von Mises stress to the remotely applied pressures (which are in mega scale), the von Mises stresses in the layers are larger to induce crystallization.

### Optical Properties

The optical absorbance of the mixed halide perovskite (CH₃NH₃PbI₃₋ₓClₓ) emitter is presented in FIG. 20A. The results showed an increase in the absorbance of the emissive material with an increase in pressure from 0 MPa to 7 MPa within visible spectrum. As the amount of pressure approaches the optimum value, the absorption tends to decrease. This increase in the absorbance can be attributed to increased crystallization and improved film quality. The results of the PL spectra are presented in FIG. 20B. The increase in crystallization is evident in the PL results, as the peaks of the spectra shift slightly toward higher wavelengths with increasing applied pressure from 0 MPa to 7 MPa. The bandgaps that were estimated from the PL spectra are presented in FIG. 20C for films that were assisted with pressures between 0 MPa and 10 MPa. The bandgap reduces with increasing pressure from 0 MPa to 7 MPa. The reduction in the bandgap can be associated with increased crystallization of the perovskite films. However, the bandgap seems to increase when 10 MPa pressure is applied, which can be attributed to film damage. In PeLEDs, the low bandgap emitter implies lower energy for turn-on voltage, while the high bandgap emitter requires high energy for PeLEDs' turn-on. The bandgap energy is essentially used up during recombination of electrons and holes.

The XRD patterns of the perovskite emissive layer are depicted in FIGS. 20D and 20E, while FIG. 20F depicts the SEM image of the perovskite layers. FIG. 20F depicts that the films were uniformly spin-coated with nicely arranged grains. FIG. 20D presents the dominant peak (110) that appeared at 21°, while FIG. 20E (inset) has the peak (220) at 42.8° for the as-prepared and all the pressure-assisted films. The results show a significant increase in the (110) and (220) peaks for applied pressures between 0 MPa and 9 MPa. The increase in the peak intensity can be attributed to pressure-induced crystallization.

### Effects of Pressure on Performance

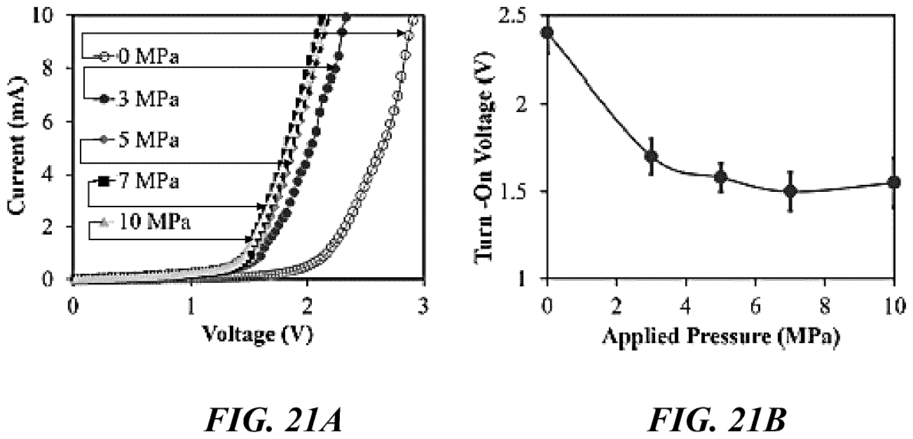

FIG. 21A depicts the results of the current-voltage (I-V) characteristic curves of the fabricated PeLEDs. FIG. 21B depicts the I-V curves showing that there is a decrease in the turn-on voltage with increasing applied pressure. The turn-on voltage is reduced from 2.5 V to 1.5 V for the pressures between 0 MPa and 7 MPa. These results can be attributed to improved interfacial surface contacts and crystallization of the films as depicted in FIG. 20E. Similar results have been shown for multilayer structures of organic solar cells and organic light emitting devices. The increase in the interfacial surface contacts with applied pressure consequently decreases interfacial voids, which in turn enhances the work function alignment and charge transport. FIG. 21B depicts the reduction in the bandgap as the increase in the transportation of charges increases recombination.

### Mobility and Defect Density

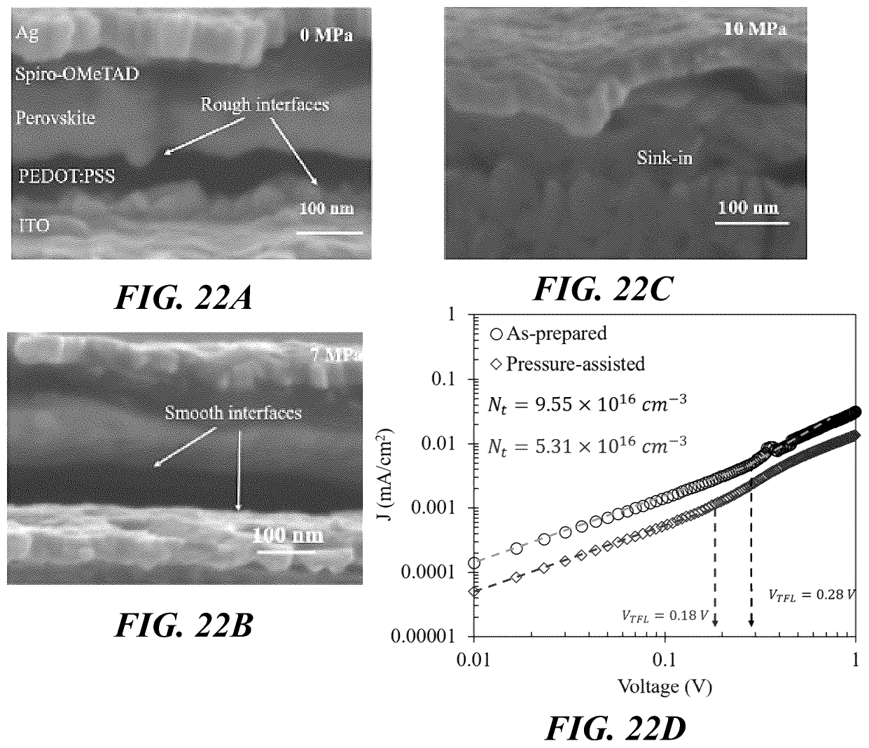

The space charge limited conduction (SCLC) technique was used to provide insights into carrier mobility and defect trap density. The cross-sectional SEM images are presented in FIGS. 22A-22C for hole-only devices that were assisted with pressures from 0 MPa to 10 MPa. FIG. 22B depicts results that show improved interfaces with an applied pressure of 7 MPa. FIG. 22C depict higher pressures that result in the sink-in of layers. To compare the defect density of the as-prepared and optimum pressure-assisted devices, the current density-voltage (J-V) curves of the single carrier devices are incorporated into the Mott-Gurney relation, which relates the defect trap density (Nt) to the bias trap filled voltage (VTFL). This results in the following equation:

$${V}_{TFL} = \frac{2 {εε}_{0} {N}_{t}}{{qL}^{2}}$$

where ε, ε0, q, and L are the relative permittivity of the perovskite layer, permittivity of free space, electronic charge, and thickness of the perovskite, respectively.

FIG. 22D presents the J-V curves of the as-prepared and pressure-assisted (at 7 MPa) hole-only devices in a log-log scale. The result shows a decrease in the trap filled voltage from 0.28 V to 0.18 V for as-prepared and pressure-assisted devices, respectively. The trap density also decreased from 9.55×1016 cm-3, while the hole mobility increased from 41.1×10=6 cm2/Vs to 43.3×10-6 cm2/Vs.

### Conclusion

The results of example 3 show a combination of analytical, computational, and experimental methods for studying the effects of pressure on the performance characteristics of perovskite light emitting devices.

The application of pressure increases the interfacial surface contacts between adjacent layers in multilayered PeLED structures. The surface contacts are also shown to increase with reduced film thicknesses and particle sizes. The increased interfacial surface contact improves the work function alignment of layers, which enhances the transportation and recombination of generated holes and electrons.

The optical properties of the perovskite films increase with increasing applied pressure. The results show that the optical absorbance of the films increases with pressures between 0 MPa and 7 MPa. The increase in the absorbance of the perovskite film is associated with the reductions in the bandgap. The XRD patterns of the as-prepared and pressure-assisted perovskite films are compared. The results show a significant increase in the intensities of the (110) (FIG. 20D) and (220) (FIG. 20E) peaks with increasing applied pressure. This is due to an increase in crystallinity.

The decrease in the energy bandgap and crystallization at high pressure is evident in the device performance characteristics. The turn-on voltages of the PeLEDs were significantly reduced from 2.5 V to 1.5 V for applied pressures between 0 MPa and 7 MPa due to the reduction in the defect trap density. This reduction in the turn-on voltage is also attributed to the improvements in interfacial surface contacts within the multilayered structures of PeLEDs.

### Example 4—Pressure-Assisted Fabrication of Perovskite Solar Cells

Example 4 shows the results of a combined experimental and analytical/computational study of the effects of pressure on photoconversion efficiencies of perovskite solar cells (PSCs). First, an analytical model is used to predict the effects of pressure on interfacial contact in the multilayered structures of PSCs. The PSCs are then fabricated before applying a range of pressures to the devices to improve their interfacial surface contacts. The results show that the photoconversion efficiencies of PSCs increase by ˜40%, for applied pressures between 0 and ˜7 MPa.

Example 4 depicts a combined computational/analytical and experimental approach to study the effects of pressure on the photoconversion efficiencies of multilayered perovskite solar cells. First, use computational finite element simulations and analytical models to simulate the effects of pressure on interfacial surface contacts in the layered mixed halide PSCs. The models and simulations, which incorporates the mechanical properties of the layers in the perovskite solar cells, show that contact between the layers increases with increasing applied pressure. The results reveal that increase pressure results in the densification of the mesoporous layers and the infiltration of the mesoporous layers with the perovskite layers.

The resulting perovskite solar cells have photoconversion efficiencies that increase from ˜9.84 (9.40±0.70) to 13.67 (13.10±0.70) %, for pressure values between 0 and 7 MPa. The photoconversion efficiencies decrease with increasing pressure beyond 7 MPa. The increasing initial trends in the photoconversion efficiencies (p<7 MPa) are attributed to the improved surface contacts and the initial densification and infiltration of the mesoporous layer that are associated with increasing applied pressure. The subsequent decrease in photoconversion efficiencies at higher pressures (p>7 MPa) are associated with the fragmentation of the perovskite grains, and the sink-in of the perovskite layers into the mesoporous TiO₂ layer, which can cause device damage.

### Processing of Perovskite Solar Cells

FTO-coated glass (Sigma Aldrich) was cleaned successively in an ultrasonic bath (for 15 minutes each) in deionized water, acetone (Sigma Aldrich) and IPA (Sigma Aldrich). The cleaned glass was then blow-dried in nitrogen gas, prior to UV-Ozone cleaning (Novascan, Main Street Ames, IA, USA) for 20 minutes to remove organic residuals. Subsequently, an electron transport layer (ETL) (that comprises compact and mesoporous layers of titanium oxide) was deposited onto the FTO-coated glass. First, a compact titanium oxide (c-TiO2) was spin-coated onto the cleaned FTO-coated glass from a solution of titanium diisopropoxide bis (acetylacetone) (0.15 M in 1-butanol) at 2000 rpm for 30 s. This was followed by 5 minutes of annealing at 150° C. before spin coating another layer of titanium diisopropoxide bis (acetylacetone) (0.3 M in 1-butanol) at 2000 rpm for 30 s. The deposited c-TiO₂ was then annealed in a furnace (Lindberg Blue M, Thermo Fisher Scientific) at 500° C. for 30 minutes. The sample was then allowed to cool down to room-temperature (˜25° C.). A mesoporous titanium oxide (mp-TiO₂) was spin coated from a solution of titanium oxide paste (20% in ethanol) at 5000 rpm for 30 s before sintering at 500° C. for 30 mins in a furnace (Lindberg Blue M, Thermo Fisher Scientific). This was then transferred into a nitrogen filled glove box, where the photoactive perovskite and the hole transport layers were deposited.

A mixed halide perovskite solution was prepared from a mixture of 222.5 mg of lead (II) iodide (PbI2) (>98.9% purity, Sigma Aldrich) and 381.5 mg of methylammonium chloride (MACl) (>99% purity, Sigma Aldrich) in 1 ml of dimethylformamide (DMF) (Fisher Scientific). This was then stirred at 60° C. for 6 hours in the nitrogen filled glove box. The solution was filtered using a 0.2 μm mesh filter before spin-coating onto mp-TiO2 at 2000 rpm for 50 s. After 30 s of the spin coating of the perovskite layer, 300 μl of chlorobenzene was then dispensed onto the film. The perovskite film was then crystallized by annealing at 90° C. for 30 minutes to crystalize. Finally, a solution of 2, 2′, 7, 7′-tetrakis (N,N-di-p-methoxyphenylamine)-9, 9′-spirobifluorene (Spiro-OMeTAD) (>99% purity, Sigma Aldrich) was spin coated at 5000 rpm for 30 s.

The Spiro-OMeTAD solution was prepared from a mixture of 72 mg of Spiro-OMeTAD in 1 ml of chlorobenzene, 17.5 μl of lithium bis (trifluoromethylsulphony) imide (Li-FTSI) (Sigma Aldrich) (500 mg in 1 ml of acetonitrile), 29 μl of tris(2-(1H-pyrazol-1-yl)-4-ter-butylpyridine)-cobalt (III) tris(bis(trifluoromethylsulfonyl) imide) (FK209) (Sigma Aldrich) (100 mg in 1 ml of acetonitrile) and 28.2 μl of 4-tert-butylpyridine (tBP) (Sigma Aldrich). The above film was kept overnight in a desiccator before thermally evaporating a 80.0 nm thick gold (Au) layer onto the Spiro-OMeTAD from an Edward E306A evaporation system (Edward E306A, Easton PA, USA). The evaporation was carried out under a vacuum pressure of <1.0×10⁻⁵ Torr at a rate of 0.15 nm s⁻¹. Shadow masks were used to define both small and large device active areas of 0.10 cm² and 1.1 cm² respectively. FIG. 3E depicts the resulting device architecture.

### Pressure Experiments

FIGS. 3F and 3G depict a range of pressures (0-10 MPa) was applied to the fabricated perovskite solar cells. This was done using a model 5848 MicroTester Instron electrochemical testing machine (Instron, Norwood, MA, USA) with a PDMS anvil placed on the device. First, the PDMS anvil was fabricated from a mixture of Sylgard 184 silicone elastomer base and Sylgard 184 silicone elastomer curing agent (Dow Corning Corporation, Midland, M I) in a ratio 10:1 by weight. The mixture was degassed and cured (at 65° C. for 2 hours) in a mold with shining silicon base. The PDMS anvil was then cut out into the dimensions of the device glass substrate.

FIG. 3F summarize the pressure experiments and FIG. 3G depicts information on the Instron MicroTester set-up. The Instron was set to ramp in compression at a displacement rate of 1.0 mm·min⁻¹, followed by a hold at 2 MPa for 10 minutes. Unloading was then carried out at a displacement rate of ˜−1.0 mm·min⁻¹. This cycle was then repeated to different peak pressures (from 2 MPa to 10 MPa) on the perovskite solar cells and perovskite layers.

### Characterization of Current Density-Voltage Behavior

Plots of current density against voltage (J-V) were obtained for the fabricated perovskite solar cells. These were measured (before and after the pressure treatment) using a Keithley SMU2400 system (Keithley, Tektronix, Newark, NJ, USA) that was connected to an Oriel simulator (Oriel, Newport Corporation, Irvine, CA, USA) under AM1.5 G illumination of 100 mW cm⁻². The J-V curves of devices (with zero pressure) were first measured before subsequent J-V measurements of the devices that were subjected to applied pressures of 0-10 MPa.

The optical absorbances of the as-prepared and pressure-assisted perovskite layers were measured using an Avantes UV-Vis spectrophotometer (AvaSpec-2048, Avantes, BV, USA). The X-ray diffraction patterns of as-prepared and pressure-assisted perovskite layers were also obtained using an X-ray diffractometer (Malvern PANalytical, Westborough, MA, USA). The microstructural changes of the as-prepared and pressure-assisted perovskite layers were also observed using field emission scanning electron microscope (SEM) (JEOL JSM-700F, Hollingsworth & Vose, MA, USA).

### Results and Discussion

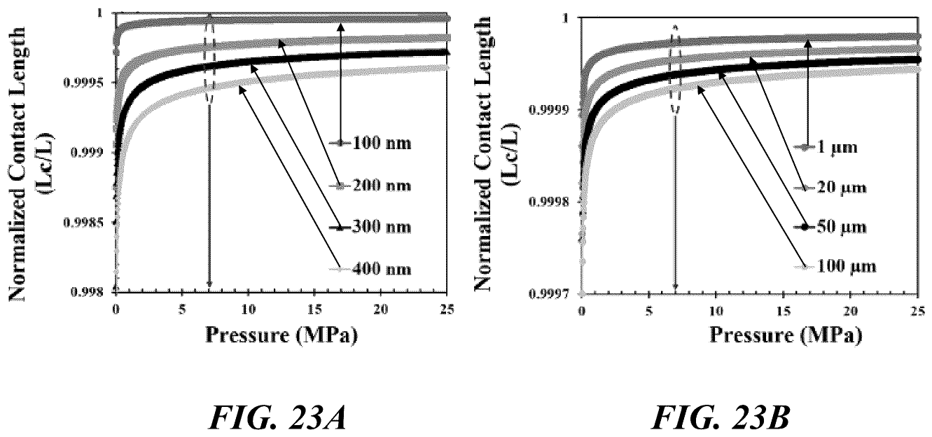

The contact length ratios, L_{C}/L, associated with the effects of applied pressures were obtained by the substitution of appropriate parameters into Eq. 1. Example 4 considers the effects of varying the thickness of the perovskite layer (100-400 nm) and the interlayer particle sizes. FIGS. 23A and 23B depicts the results of the analytical modeling of surface contact. FIG. 23A depicts that for different thicknesses of the perovskite films, the interfacial surface contact length ratio L_{C}/L increases with increasing applied pressure. The thinner films also require less pressure to wrap round the particles. This results in higher interfacial surface contacts around interlayer particles between thinner layers. FIG. 23B depicts that in the case where the particle sizes vary under different clean room conditions, decreasing particle sizes results in increasing interfacial surface contact.

Upon the application of pressure, the contact length ratios L_{C}/L increases with increasing applied pressure. The analytical model results suggest that increased pressure caused increased in contact between the perovskite active layer and the adjacent layers, which improves transportation of charges and work function alignment across interfaces. Excessive pressure can lead to sink-in of the particles, which can cause damage to the adjacent layers in perovskite solar cells. The perovskite layers can also sink into the adjacent mesoporous layers, leading ultimately to short circuiting.

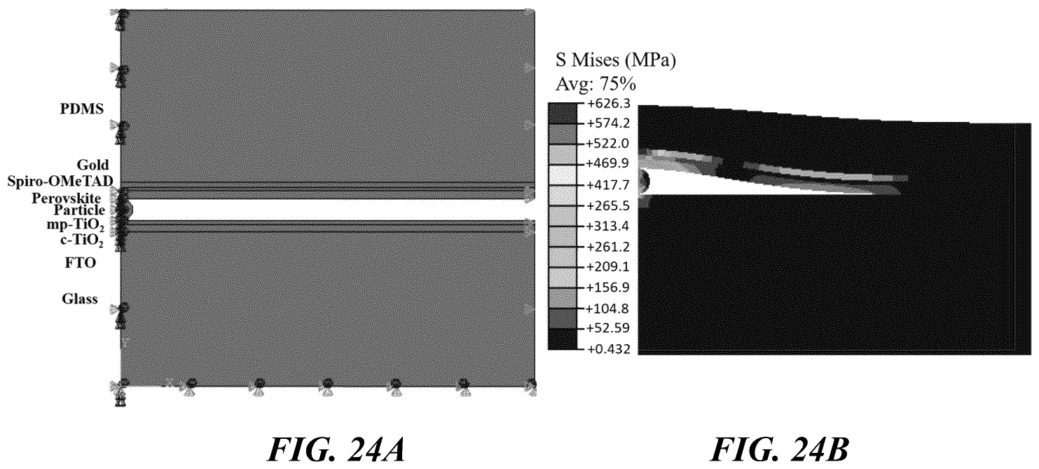

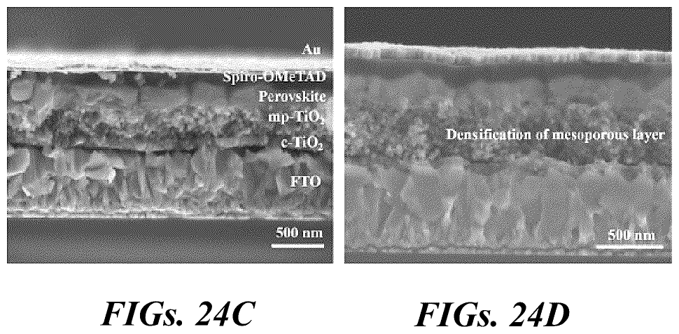

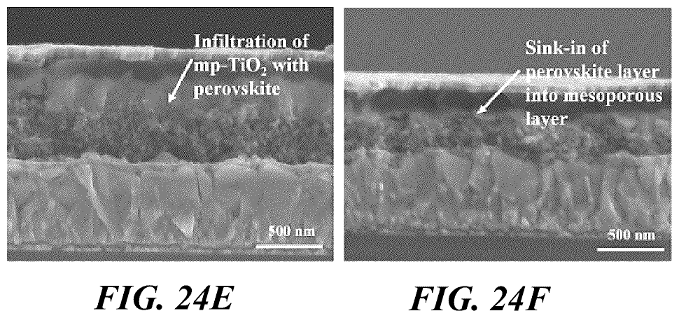

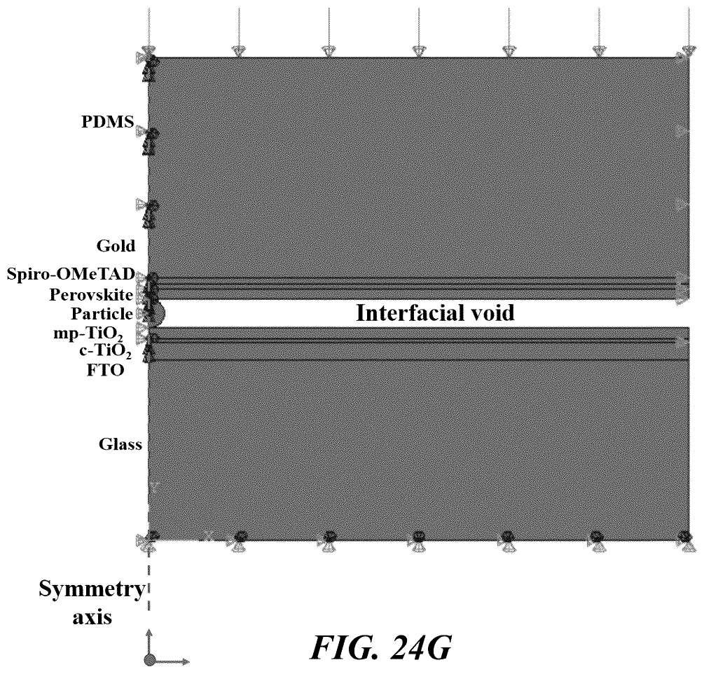

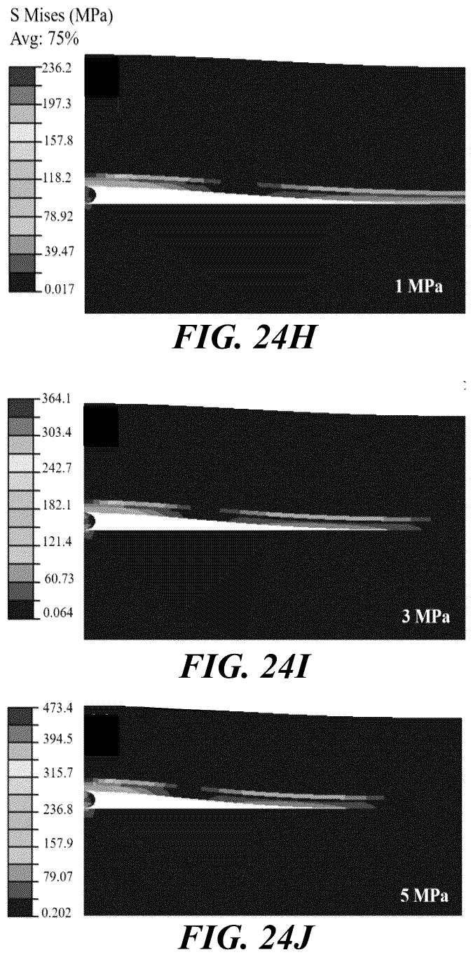

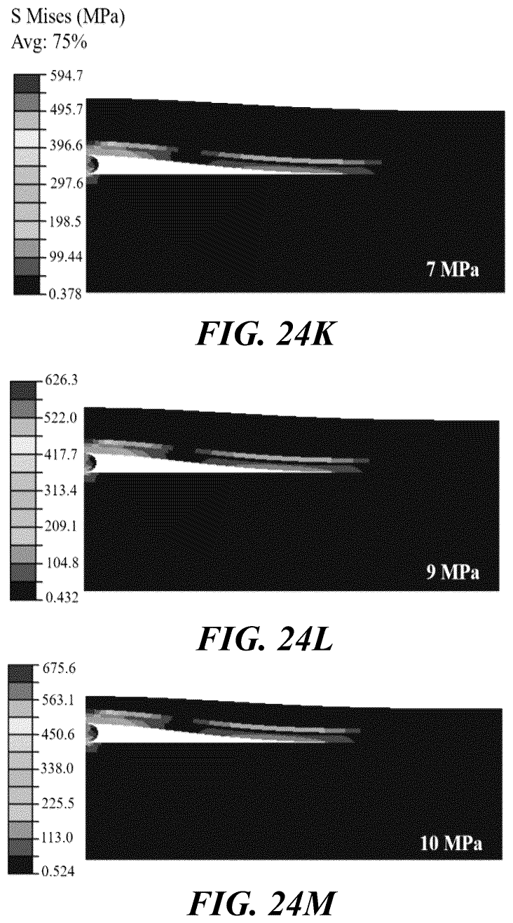

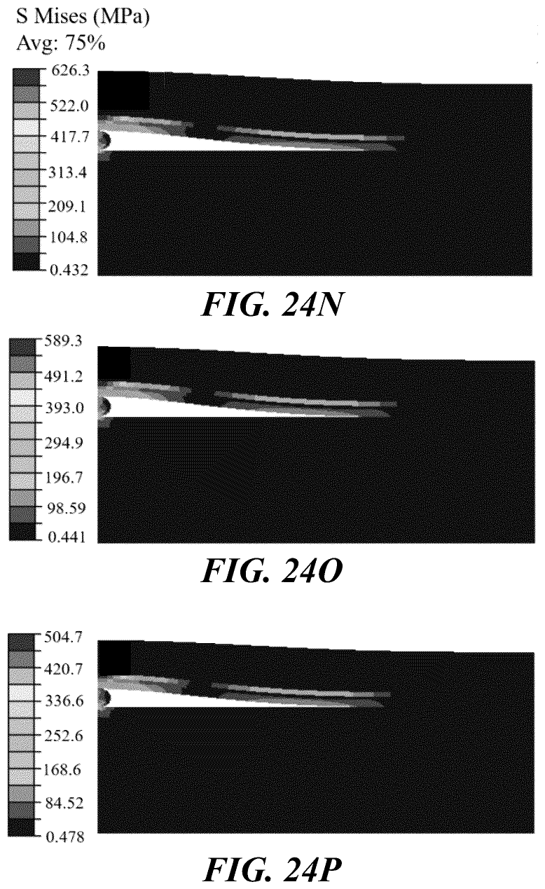

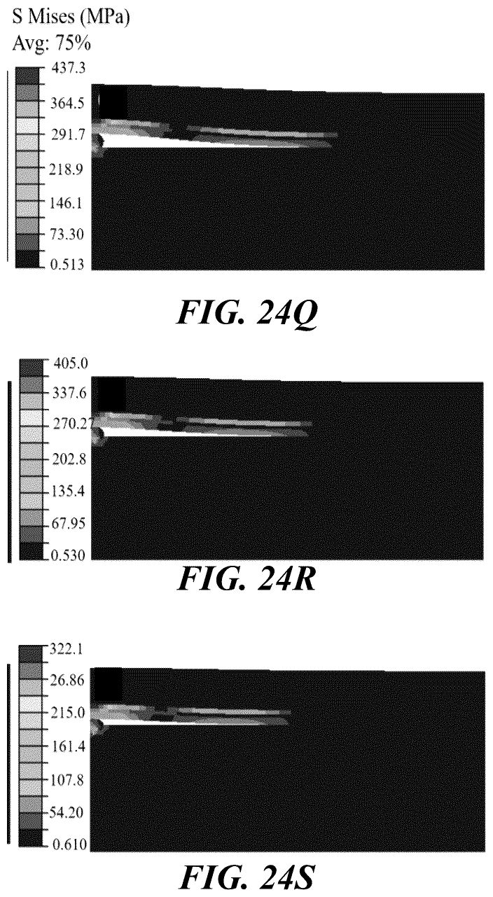

Finite element modeling was also used to explore the effects of pressure on the surface contact length ratios L_{C}/L, and interlayer/impurity particle sink-in. Table 6A depicts previously obtained materials properties incorporated into the finite element modeling, which was carried out using the ABAQUS software package (ABAQUS Dassault Systemes Simulia Corporation, Providence, RI, USA). The models utilized axisymmetric geometries of the device architecture. They were simplified by considering a sandwiched particle between two layers, along one of the interfaces of the device structure. The axisymmetric boundary condition was applied along the symmetry axis shown in FIG. 24G. The bottom of the substrate was also fixed to have no displacements or rotations. For continuity, the outer edge of the model was also fixed to have no lateral motion, while a pressure was applied from a stamp. The details of the finite element simulations are presented in the support information.

TABLE 6A
Mechanical properties of materials used in the analytical modeling
and finite element simulations. The clean room particles that
can constitute interfacial surface void are classified along
with the mechanical properties of device materials.

| | | Young's Modulus | Poisson |
|---|---|---|---|
| Class | Materials | (GPa) | Ratio |
| Clean room | Silicone | 0.001-0.02 | 0.3 |
| particles | Photoresist | 1-8 | 0.3 |
| | Aluminum | 70 | 0.3 |
| Device Materials | FTO | 206 | 0.32 |
| | TiO₂ | 210 | 0.3 |
| | Perovskite | 19.77 | 0.33 |
| | Spiro-OMeTAD | 15 | 0.36 |
| | Au | 78 | 0.48 |
| | PDMS | 0.003 | 0.3 |

FIGS. 24A-24D depict interfacial surface contacts in perovskite solar cells before and after pressure applications. FIG. 24A and FIG. 24B depict the results of the finite element simulations (before and after pressure application, respectively), for the interfacial surface contact between perovskite layer and mesoporous TiO₂ layer. FIG. 24A depicts stress distributions before contact. FIG. 24B depicts stress distributions after contact. FIG. 24C and FIG. 24D depict improvements in pressure-induced contacts at other interfaces in the device structure. FIGS. 24H-M depict the interfacial surface contacts increased with increasing pressure (1 MPa-10 MPa). FIG. 24H depicts the stress distribution in perovskite solar cells during pressure application at 1 MPa. FIG. 24I depicts the stress distribution in perovskite solar cells during pressure application at 3 MPa. FIG. 24J depicts the stress distribution in perovskite solar cells during pressure application at 5 MPa. FIG. 24K depicts the stress distribution in perovskite solar cells during pressure application at 7 MPa. FIG. 24L depicts the stress distribution in perovskite solar cells during pressure application at 9 MPa. FIG. 24M depicts the stress distribution in perovskite solar cells during pressure application at 10 MPa. The interfacial surface contact of the increases with increased pressure, while the interfacial void decreases. FIG. 24C depicts cross section of interfacial void before pressure application. FIG. 24D depicts densification of mesoporous layer after contact.

The finite element simulations of the effects of pressure treatment were carried out using the Abaqus software package (Dassault Systemes Simulia Corporation, Providence, RI, USA). The effects of the clean room particles were considered in the simulations of contact between transport layer (TiO₂) and the photoactive active layer (perovskite). The segments of the devices in the region of the embedded particles were analyzed in the simulations. For simplicity, axisymmetric geometries were used as shown FIG. 24E. It is assumed that the part of the device, which is farther from the dust particle, would have no significant effect on the mechanics around the dust particle. Majority of the airborne particles in semiconductor clean room environment have a diameter of 1 μm, which is about four times of the thickness (250-400 nm) of the device active layer. In the simulation, a diameter of 1 μm was chosen for the dust particle. The mechanical properties of these particles are summarized in Table 6B.

TABLE 6B
Mechanical properties of materials used in the modeling and
finite element simulations. The clean room particles that
can constitute interfacial surface void are classified along
with the mechanical properties of device materials.

| | | Young's Modulus | |
|---|---|---|---|
| Class | Materials | (GPa) | Poisson Ratio |
| Clean room | Silicone | 0.001-0.02 | 0.3 |
| particles | Photoresist | 1-8 | 0.3 |
| | Aluminum | 70 | 0.3 |
| Device | FTO | 206 | 0.32 |
| Materials | TiO₂ | 210 | 0.3 |
| | Perovskite | 19.77 | 0.33 |
| | Spiro-OMeTAD | 15 | 0.36 |
| | Au | 78 | 0.48 |
| | PDMS | 0.003 | 0.3 |

A four-node bilinear axisymmetric quadrilateral element was used in the mesh. The mesh was dense in the regions near the dust particle and the contact surfaces. Identical mesh sizes were also used in the regions near the surface contact regimes to assure convergence in contact simulation. All the materials were assumed to exhibit isotropic elastic behavior. Young's moduli of the materials were obtained from the nanoindentation experiments as described in prior studies. The Young's moduli and the Poisson's ratios of the materials used in the simulations are summarized in Table 6B. The axisymmetric boundary condition was applied at the symmetry axis as shown in FIG. 24E. The bottom of the substrate was fixed to have no displacements and rotations. The outer edge of the model was also fixed to have no lateral movement for continuity, while a pressure was applied from the stamp onto the device.

FIGS. 24N-24S depict the effects of pressure and the material properties of the interlayer particles on the surface contact, such as the stress distribution in perovskite solar cells during pressure application, showing effects of particles materials properties. FIG. 24N depicts that for pressure of 9 MPa, the interfacial void reduces for particles with material properties of 70 MPa. FIG. 24N depicts that for pressure of 9 MPa, the interfacial void reduces for particles with material properties of 20 GPa. FIG. 24O depicts that for pressure of 9 MPa, the interfacial void reduces for particles with material properties of 500 MPa. FIG. 24P depicts that for pressure of 9 MPa, the interfacial void reduces for particles with material properties of 500 MPa. FIG. 24Q depicts that for pressure of 9 MPa, the interfacial void reduces for particles with material properties of 300 MPa. FIG. 24R depicts that for pressure of 9 MPa, the interfacial void reduces for particles with material properties of 250 MPa. FIG. 24S depicts that for pressure of 9 MPa, the interfacial void reduces for particles with material properties of 170 MPa. FIGS. 24N-24S show that the interfacial void lengths (between adjacent layers) are greatly reduced with decreasing interlayer particle moduli between 70 GPa-0.17 GPa (for the same pressure of MPa). This range of Young's moduli corresponds to the material properties of particles that are found in clean room environment as shown in Table 6A.

The analytical and computational results are consistent with microstructural observations of the device cross sections (before and after the application of pressure), as shown in FIGS. 24C-24F. FIG. 24C shows the significant interfacial voids between the layers of the perovskite solar cells before the application of pressure. FIG. 24D depicts the reduction in the interfacial void lengths and the mesoporous layers being compacted after the application of a pressure of 7 MPa, which resulted in the infiltration of the mesoporous TiO2 layers with perovskite as shown in FIG. 24E. FIG. 24F depicts the sink-in of the perovskite (into the adjacent mesoporous layer) at a pressure of 10 MPa. This sink-in can be the compaction and damage phenomena associated with the compressive deformation of porous materials.

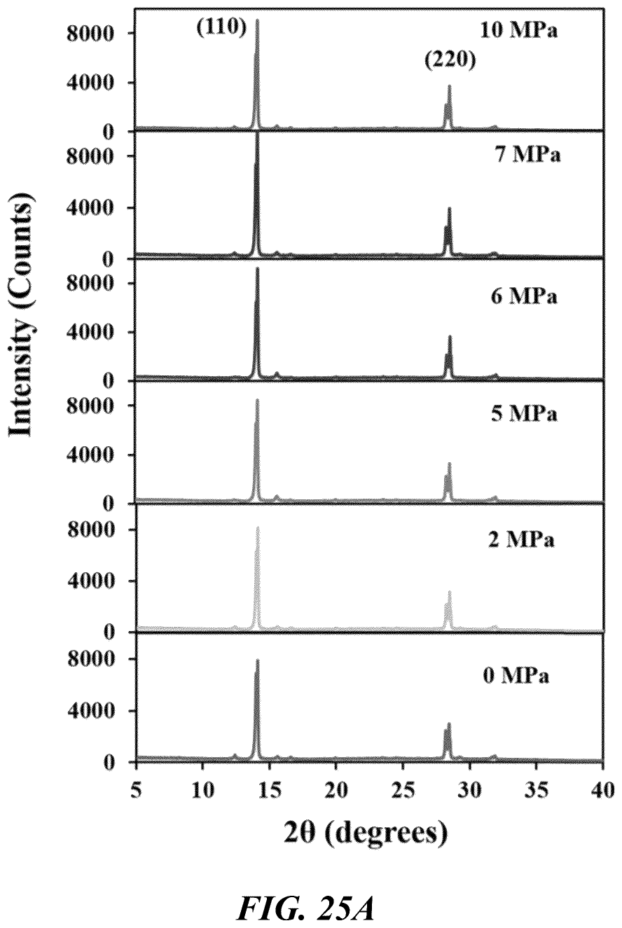

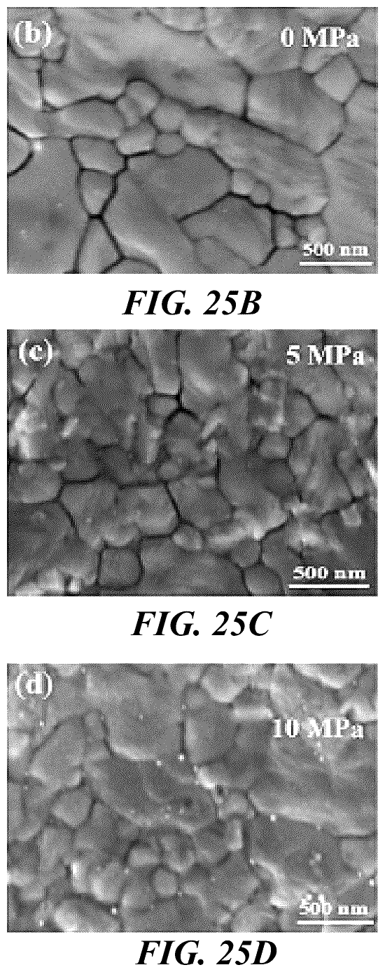

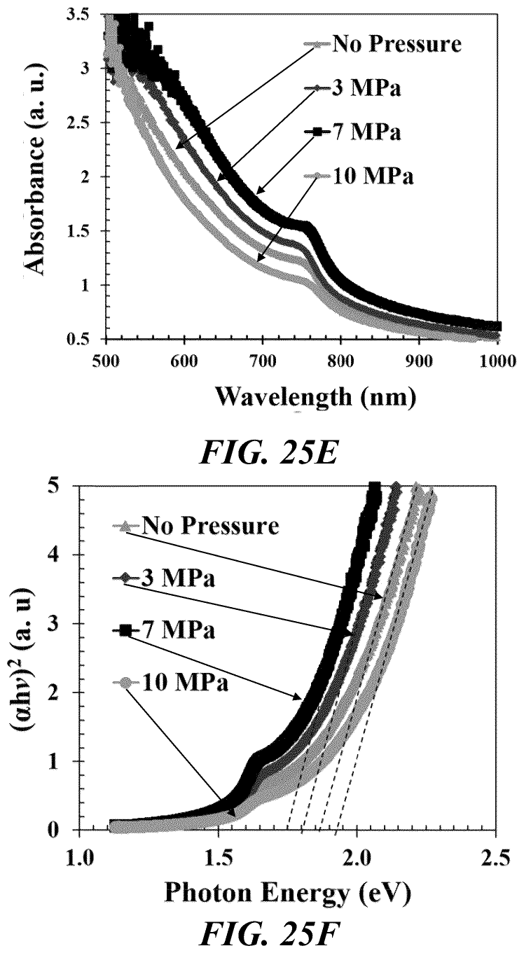

The effects of pressure are also evident in the structural and optical properties of the perovskite solar cells. FIG. 25A depicts the XRD patterns of the as-prepared perovskite films and those produced via pressure-assisted fabrication. The (110) (FIG. 20D) and (220) (FIG. 20E) peaks increase with increasing pressure between 0 MPa and 7 MPa. However, the peaks decrease with further increase in pressure (above 7 MPa). FIGS. 25B-25D depict the SEM images of the perovskite films with the pressure-induced crystallization. The increase to crystallization phenomena can occur due to small bond lengths that occur with increase initial pressure. Such reduction in bond lengths is also associated with stress-induced phase transformations that increase the percentage of crystalline perovskite phases with (110) (FIG. 20D) and (220) (FIG. 20E) orientations. However, for pressure above 7 MPa, the 110 and 220 peaks were observed to decrease with increasing pressure. The decrease is attributed to the potential onset stress-induced amorphization that can occur due to cracking and damage phenomena. Such localized amorphization can reduce the overall crystallinity.

FIG. 25E depicts optical absorbance of perovskite film. The optical properties of the perovskite films increased with increasing applied pressure. The optical absorbance of the films increases with pressures between 0 MPa and 7 MPa due to the decrease in bond lengths. FIG. 25F depicts a plot of (αhv)² versus photon energy. The increase in the absorbance of the perovskite film can be due to increased pressures in the reduction bandgaps between 0 MPa and 7 MPa. For pressures above 7 MPa, the bandgaps were observed to increase with increasing pressure. This can also be attributed to local stress-induced phase changes or amorphization phenomena that can occur due to pressure application.

The bandgaps can be estimated by incorporating the absorption spectra into an empirical formula: (αhv)²=hv−Eg, where h, v, Eg and α are plank constant, frequency, optical energy bandgap and absorption coefficient, respectively. The decrease in the bandgap exhibits a red shift in the absorption edge that corresponds to an increase in the capacity to generate electron-hole pairs that can travel to the electrodes before recombination, which improves power conversion efficiencies. For applied pressures of 10 MPa and above, the optical absorbance can decrease significantly with increasing applied pressure. High pressures can cause damage, which can lead to light scattering and unexpected blue shifts in the absorption edge.

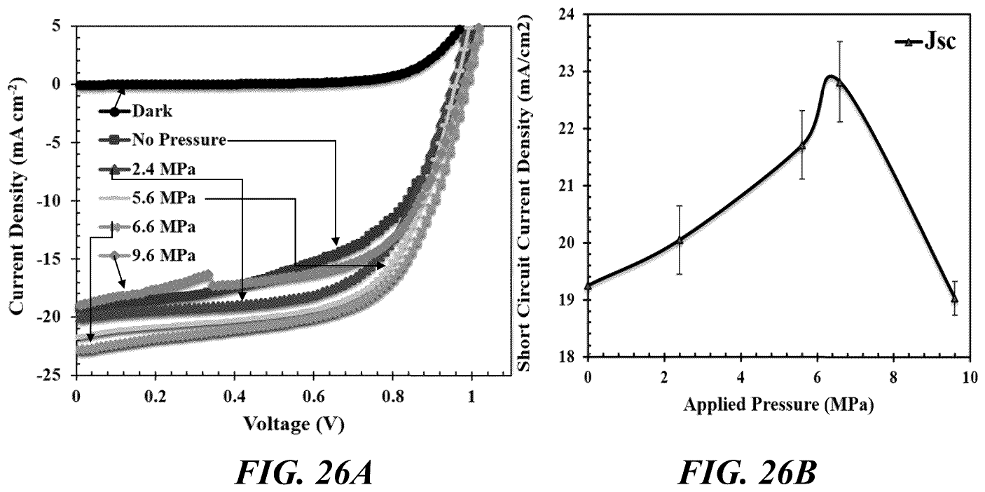

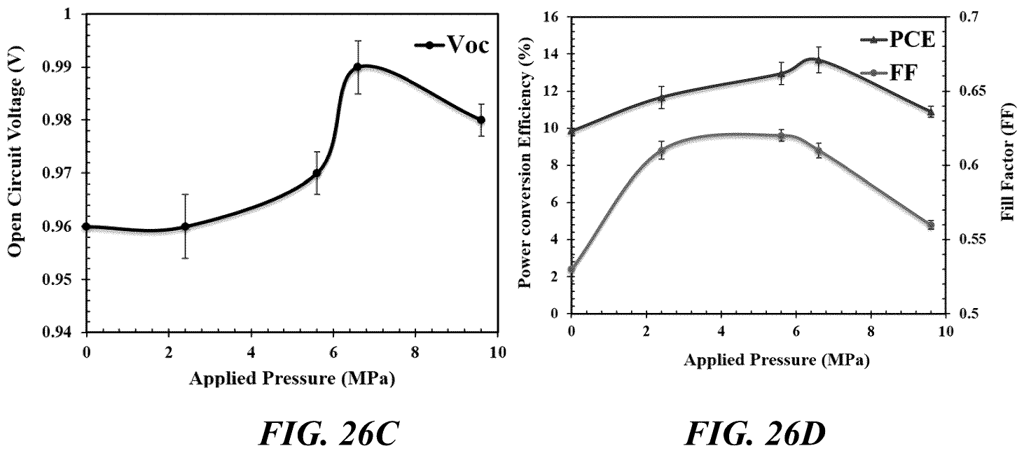

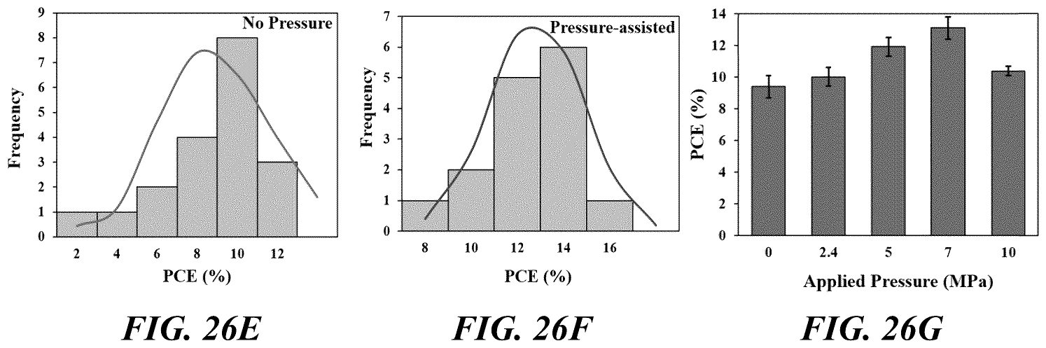

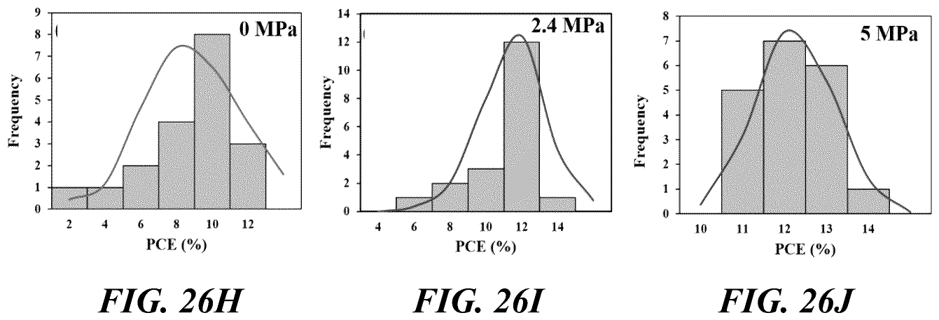

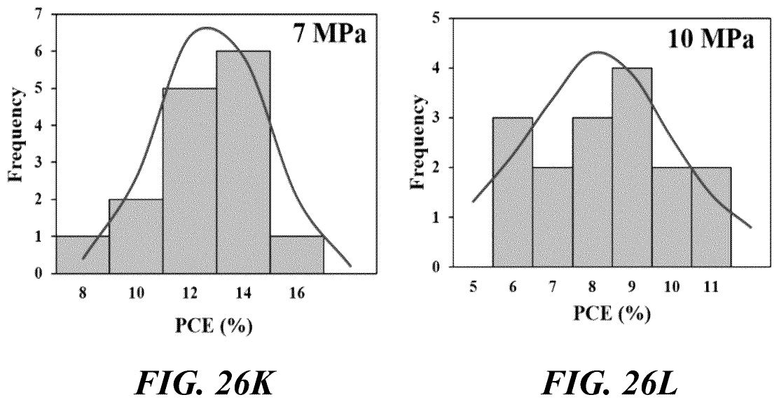

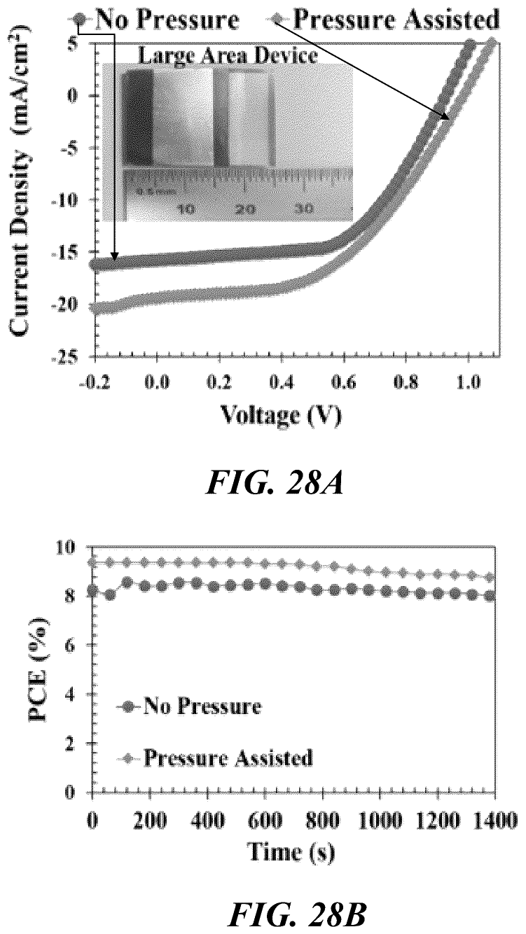

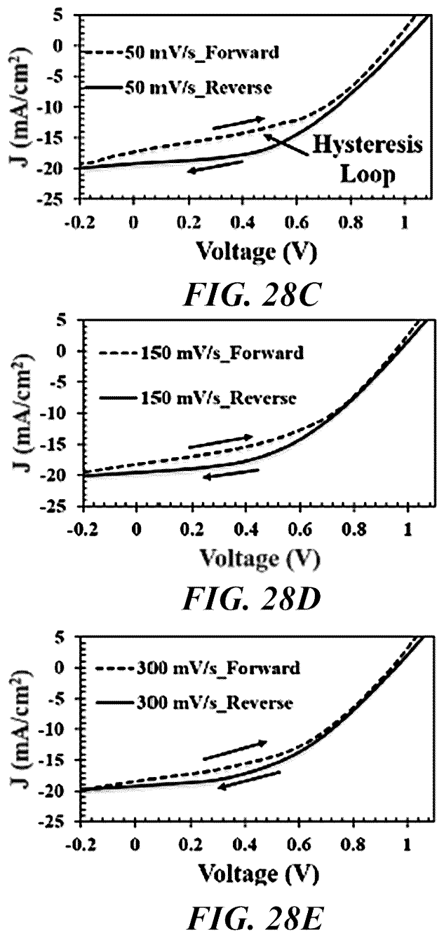

FIGS. 26A-26G depict device parameters before and after application of pressure to depict the effects of pressure on performance parameters of perovskite solar cells. FIG. 26A depicts a set of current density-voltage (J-V) curves obtained for the perovskite solar cells. The areas under the curves increased with increasing pressure. FIG. 26A depicts current density-voltage curves of average of J-V curves obtained from the devices. FIGS. 26B-26D depict the effects of applied pressure on short circuit current density (J_{SC}), open circuit voltage (V_{OC}), power conversion efficiency (PCE), and fill factor (FF). FIG. 26B depicts short-circuit current density. FIG. 26C depicts open circuit voltage. FIG. 28D depicts power conversion efficiency (PCE) and fill factor for different applied pressures. Table 7A includes the device characteristics and Table 7B includes overall device parameters obtained for other sets of devices.

TABLE 7A
Device characteristic parameters for pressure-assisted perovskite
solar cells indicating the average of the PCEs.

| Pressure | | J_{SC} | | PCE (PCE_{average}) | |
|---|---|---|---|---|---|
| (MPa) | V_{oc} (V) | (mAcm⁻²) | FF | (%) | |
| 0.0 | 0.96 ± 0.0078 | 19.25 ± 1.20 | 0.53 ± 0.008 | 9.84 | (9.40 ± 0.70) |
| 2.4 | 0.96 ± 0.0056 | 20.05 ± 0.60 | 0.61 ± 0.007 | 11.66 | (10.01 ± 0.60) |
| 5.0 | 0.97 ± 0.0038 | 21.71 ± 0.06 | 0.62 ± 0.004 | 12.94 | (11.92 ± 0.60) |
| 7.0 | 0.99 ± 0.0045 | 22.82 ± 0.70 | 0.61 ± 0.005 | 13.67 | (13.10 ± 0.70) |
| 10.0 | 0.98 ± 0.0027 | 19.03 ± 0.30 | 0.56 ± 0.003 | 10.89 | (10.02 ± 0.30) |

TABLE 7B
Detailed device parameters for perovskite solar cells

| | Pressure | Voc | Jsc | | PCE (PCE_{avg}) | |
|---|---|---|---|---|---|---|
| Devices | (MPa) | (V) | (mAcm⁻²) | FF | (%) | |
| Set 1a) | 0 | 0.82 | 20.88 | 0.46 | 7.91 | (6.60 ± 0.90) |
| | 2.4 | 0.92 | 21.38 | 0.54 | 10.43 | (8.13 ± 0.84) |
| | 5.6 | 0.92 | 21.44 | 0.56 | 11.58 | (10.61 ± 0.74) |
| Set 2b) | 0 | 0.83 | 26.64 | 0.41 | 9.22 | (8.52 ± 0.61) |
| | 2.4 | 0.83 | 27.64 | 0.40 | 9.22 | (8.66 ± 0.40) |
| | 5.6 | 0.84 | 31.85 | 0.50 | 13.22 | (12.87 ± 0.48) |
| | 7 | 0.84 | 31.72 | 0.45 | 11.65 | (10.10 ± 0.49) |
| | 10 | 0.83 | 23.87 | 0.31 | 6.22 | (5.67 ± 0.52) |
| Set 3c) | 0 | 0.92 | 17.51 | 0.54 | 8.72 | (8.74 ± 0.40) |
| | 2.4 | 0.92 | 19.42 | 0.61 | 10.87 | (10.39 ± 0.50) |
| | 5.6 | 0.91 | 20.14 | 0.61 | 11.23 | (10.39 ± 0.90) |
| | 7 | 0.9 | 20.11 | 0.62 | 11.12 | (10.63 ± 0.50) |
| | 10 | 0.92 | 16.92 | 0.47 | 7.13 | (6.61 ± 0.80) |
| Set 4d) | 0 | 0.96 | 19.25 | 0.53 | 9.84 | (9.40 ± 0.70) |
| | 2.4 | 0.96 | 20.05 | 0.61 | 11.66 | (10.01 ± 0.60) |
| | 5 | 0.97 | 21.71 | 0.62 | 12.94 | (11.92 ± 0.60) |
| | 7 | 0.99 | 22.82 | 0.61 | 13.67 | (13.10 ± 0.70) |
| | 10 | 0.98 | 19.03 | 0.56 | 10.89 | (10.02 ± 0.30) |

a)15 devices, 5 for each applied pressure;
b)20 devices, 4 for each applied pressure;
c)25 devices, 5 for each applied pressure;
d)25 devices, 5 for each applied pressure;
avg(average)

In the case of the perovskite solar cells that were fabricated without pressure application, the PCE and FF were 9.84 (9.40±0.70) % and 0.53±0.008, respectively. The application of pressure (up to 7 MPa) advantageously increases the PCE and FF up to 13.67 (13.10±0.70) % and 0.61±0.005%, respectively. For a higher applied pressure of 10 MPa, the PCE and FF both decreased slightly to 10.89 (10.02±0.30) % and 0.56±0.003, respectively.

Referring to FIG. 26B, the device short circuit current density (J_{SC}) and open circuit voltage (VOC) values (obtained at different applied pressures) increased with the applied pressures between 0-7 MPa. FIGS. 26B-26D and FIG. 26F depict that for higher applied pressures (p>7 MPa), the performance parameters of the solar cells (J_{SC}, V_{OC}, FF and PCE) generally decreased.

Referring to FIGS. 26E and 26F, the histograms and the normal distributions summarize the PCEs obtained for devices fabricated with and without pressure. FIG. 26E depicts a histogram and normal distribution of the PCEs of unpressurized devices. FIG. 26F depicts a histogram and normal distribution of the PCEs of devices subjected to pressure of 2-10 MPa. FIGS. 26H-26L depict histogram and normal distribution curves of the power conversion efficiencies of perovskite solar cells at different applied pressures. FIG. 26H depicts no pressure (0 MPa), FIG. 26I depicts a pressure of 2.4 MPa. FIG. 26J depicts a pressure of 5 MPa. FIG. 26K depicts a pressure of 7 MPa. FIG. 26L depicts a pressure of 10 MPa.

FIG. 26G depicts a bar chart of a summary of the effects of pressure on PCEs of fabricated devices. The results shows that the power conversion efficiencies increased with improved surface contacts at moderate pressures. FIG. 26D depicts that the occurrence of interlayer particle sink-in and the compaction and damage of the mesoporous layer reduces the overall device efficiencies at higher applied pressures. Similar trends have been observed in organic solar cells. However, these do not include the compaction of the mesoporous layers, which were present only in the perovskite solar cells.

There are at least two explanations for how relatively low applied pressures can result in high local stresses within the layered structures of perovskite solar cells. In the first scenario, which is illustrated in FIG. 24B, one can consider the role of interfacial impurities that can give rise to interfacial stress concentration due to elastic or elastic-plastic contact. An idealized example of this is elastic contact between spherical shapes that is often idealized by Hertzian contact theory.

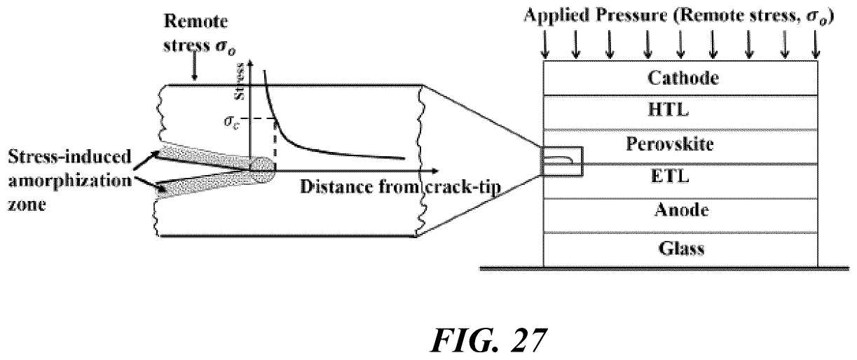

Another explanation is interfacial or layer crack/notch subjected to remote stress, σ₀. FIG. 27 depicts a schematic of a localized stress in an interfacial layer crack/notch within the multilayered structure of a perovskite solar cell subjected to remote pressure/stress. Effective high stresses at the crack or notch tips can induce amorphization. Even under compressive loading, the induced local notch/crack stresses can be much greater than the remote stresses. Even under compressive loading, there can be induced local tensile stresses at the crack or notch tips. Such stresses may be sufficient to cause stress-induced phase changes or amorphization phenomena. It is possible to have local effects in the vicinity of such notch or crack tips that can induce phase changes/amorphization under conditions in which relatively low remote stresses are applied to a notched or cracked geometry. The stress-induced phenomena can occur due to stress concentrations that are associated with elastic contacts around impurities and/or stress concentrations around interfacial notches or cracks.

FIGS. 28A-28E depict the pressure-assisted fabrication technique for devices with a large active area. For example, a large active area of 1.1 cm² for pressure of 7 MPa. FIG. 28A depicts the J-V curves of pressure-assisted fabricated devices. FIG. 28B depicts the steady-state PCEs of the large area devices under 1 sun illumination. The results show that pressure application enhances the PCE of the large active area devices from 8.26±0.21% to 9.38±0.26%. The hysteretic behavior of these devices can be studied at different scanning rates between 50 mV/s and 300 mV/s. FIGS. 28C-28E depict the J-V curves for both forward and reverse scanning directions at different scanning rates. FIG. 28C depicts the hysteretic behavior of J-V curves of the devices with large active areas at a scanning rate of 50 mV/s. FIG. 28D depicts the hysteretic behavior of J-V curves of the devices with large active areas at a scanning rate of 150 mV/s. FIG. 28E depicts the hysteretic behavior of J-V curves of the devices with large active areas at a scanning rate of 300 mV/s.

The results showed that hysteresis loop decreases with increasing scanning rates. The dependence of hysteresis on the scanning rates and direction of the J-V curves are associated with charge carrier collection efficiencies that strongly depend on built-in potential.

The results show that the power conversion efficiencies of perovskite solar cells can be significantly improved by the application of pressure. The pressure results in the closing up of voids, and the corresponding increase in the interfacial surface contact lengths, which increases with increasing pressure. The improvement in the power conversion efficiencies that was observed with increased pressure (between 0 and 7 MPa) is attributed largely to the effects of increased surface contact and the compaction and infiltration of the TiO2 layers with perovskite during the application of pressure.

The results are significant for the design of pressure-assisted process that can be used for the fabrication of perovskite solar cells. First, the significant effects of pressure suggest that pressure-assisted processes such as lamination, cold welding, and rolling/roll-to-roll processing can be used to fabricated perovskite solar cells with improved performance characteristics (photoconversion efficiencies, fill factors, short circuit currents and open circuit voltages). However, the applied pressures should be ˜7 MPa or less, to ensure that the applied pressures do not induce layer damage and the excessive sink-in of perovskite layer (between layers). Hence, the combined effects of interlayer contact, mesoporous layer compaction and infiltration and the potential for layer damage at higher pressures must be considered in the optimized design of pressure-assisted processes for the fabrication of perovskite solar cells.

### Modeling of Interfacial Surface Contacts Due to Pressure Effect.

The interfacial contact between the layers of perovskite solar cells is important for the effective transportation of charges and for work function alignment. The integrity of the interfaces in the resulting multilayered structure also depends on the surface roughness of the adjacent layers and as well as the cleanliness of the environments that are used for device fabrication. There are impurities/interlayer particles that can be embedded between layers in clean rooms. These impurities include particles of silicone, silicon, silica, textile polymer and organic materials with diameters ranging from ˜0.1 to 20 μm.

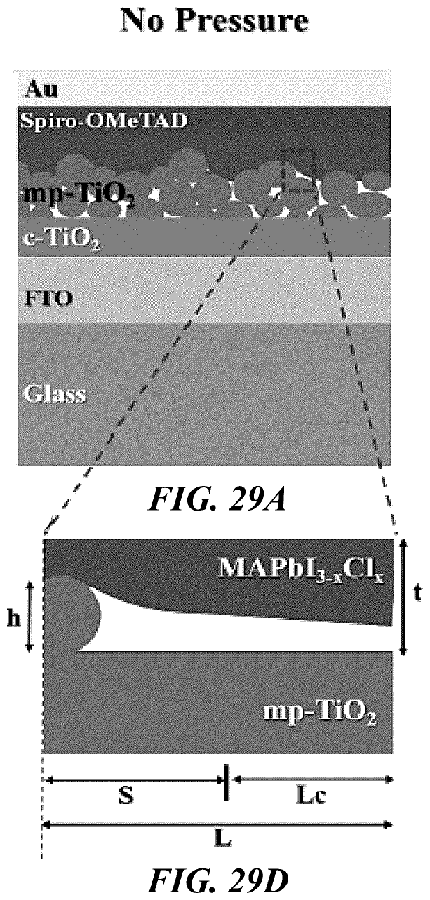

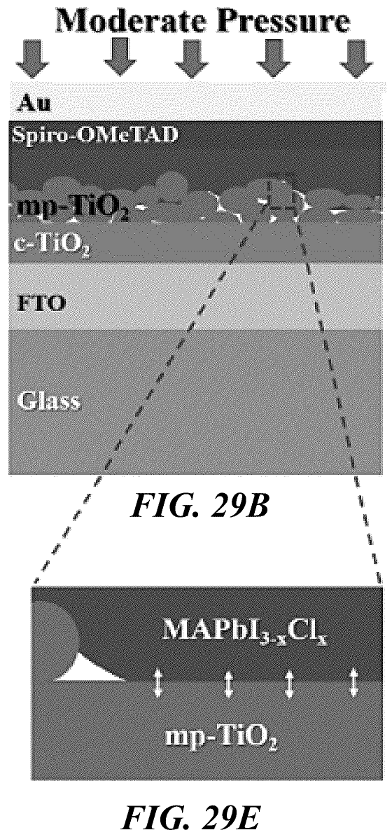

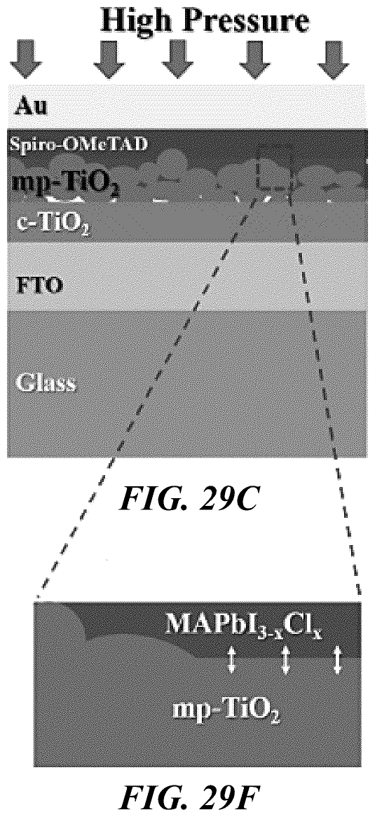

FIGS. 29A-29C depict schematics of the interfacial surface contact. FIG. 29A depicts no pressure and that the presence of these particles can reduce the effective contact areas of the bi-material pairs that are relevant to the PSCs. FIG. 29B depicts moderate pressure and that the application of moderate pressure (to PSCs) can improve the interfacial contacts between layers that sandwich the particles. FIG. 29C depicts that at higher pressures, the sink in of the trapped impurities/particles can induce damage in surrounding layers in ways that can result in reduced solar cell photoconversion efficiencies.

FIG. 29D-29F depict an axisymmetric model of interfacial surface contact. FIG. 29D depicts the model for no pressure case. FIG. 29E depicts the model for moderate pressure. FIG. 29F depicts the model for high pressure. Example 4 depicts an analytical model for the prediction of surface contacts between layers that are relevant to PSCs. The deformation of thin films (due to applied pressure) was idealized by modeling the deformation of a cantilever beam around the particles. The modeling is based on:

$$\frac{{L}_{c}}{L} = 1 - {[ \frac{3 ( \frac{E}{1 - {v}^{2}} ) {t}^{3} h}{2 {PL}^{4}} ]}^{1 / 4} ,$$

h is the height of the impurity particle, t is the thickness of the top layer (cantilever) that deforms upon pressure application, S is the void length, Lc is the contact length, L is the length of the cantilever beam, E is the Young's modulus, v is the Poisson ratio and P is the applied pressure. Using the materials properties of the films and particles summarized in Table 6A, the interfacial surface contact lengths can be estimated for the range of pressures and film thickness and roughness that are relevant to the different bi-layer configurations in the multilayered perovskite solar cells structures.

### Conclusion

Example 4 depicts the results of a combined analytical, computational, and experimental study of the effects of pressure on the performance of perovskite solar cells. The results show that the application of pressure results in improved interlayer surface contact, the compaction of mesoporous TiO2 layers, and the infiltration of the mesoporous layers with perovskite for pressure up to 7 MPa that also result in in improved photoconversion efficiencies. However, at higher pressures (p>7 MPa), the damage due to sink-in of the perovskite layers into the adjacent mesoporous layers results in reductions in the photoconversion efficiencies of perovskite solar cells.

### Example 5—Pressure and Thermal Annealing Effects on the Photoconversion Efficiency of Polymer Solar Cells

Example 5 presents the results of experimental and theoretical studies of the effects of pressure and thermal annealing on the photo-conversion efficiencies (PCEs) of polymer solar cells with active layers that consist of a mixture of poly(3-hexylthiophene-2,5-diyl) and fullerene derivative (6,6)-phenyl-C₆₁-butyric acid methyl ester. The PCEs of the solar cells increased from ˜2.3% (for the unannealed devices) to ˜3.7% for devices annealed at ˜150 C. A further increase in thermal annealing temperatures (beyond 150 C) resulted in lower PCEs. Further improvements in the PCEs (from 3.7% to 5.4%) were observed with pressure application between 0 and 8 MPa. However, a decrease in PCEs was observed for pressure application beyond 8 MPa. The improved performance associated with thermal annealing is attributed to changes in the active layer microstructure and texture, which also enhance the optical absorption, mobility, and lifetime of the optically excited charge carriers. The beneficial effects of applied pressure are attributed to the decreased interfacial surface contacts that are associated with pressure application. The implications of the results are then discussed for the design and fabrication of organic solar cells with improved PCEs.

### Methods

Poly(3-hexylthiophene) (P3HT) consisting of 20 000 and 85 000 average Mw, fullerene derivative (6,6)-phenyl-C₆₁-butyric acid methyl ester (PCBM), poly(3,4-ethylenedioxythiophene)-poly(styrenesulfonate) (PEDOT:PSS), anhydrous chlorobenzene, and indium tin oxide (ITO)-coated glass were all purchased from Sigma-Aldrich (Natick, MA, USA). All of the materials were used in their as received conditions. The ITO-coated glasses were patterned by etching with zinc powder and 2M hydrochloric acid. They were then washed in deionized (DI) water, before sonicating (each for 15 min) in decon-90, DI water, acetone, and isopropyl alcohol. The glass slides were blow dried using nitrogen gas. They were then treated with a UV/ozone cleaner (Novascan, Main Street Ames, IA, USA) to remove organic residuals.

Subsequently, PEDOT: PSS was filtered with a 0.45 μm mesh filter before spin-coating with a spin coater (Laurell Technologies Corporation, North Wales, PA, USA) onto the cleaned ITO-coated glass slides at 3000 rpm for 30 s. The resulting films were annealed for min at 120° C. in air before transferring them into a dry nitrogen filled glove box. A solution of 30 mg/ml P3HT: PCBM (1:1 w/w) was then prepared by mixing 7.5 mg of 20 000 Mw of P3HT and 7.5 mg of 80 000 Mw of P3HT with 15 mg of PCBM in 1 ml of chlorobenzene. The solution was stirred for 2 h before filtering through a 0.2 μm mesh filter. The solution of P3HT:PCBM blend was then spin-coated onto the PEDOT:PSS-coated ITO-glass surface at 800 rpm for 120 s. The spin-coated structure was then annealed in a dry nitrogen-filled glove box at 50° C. for 20 min. The spin coating procedures were repeated for other PEDOT:PSS/ITO-coated glasses before annealing them at different temperatures (RT=25, 100, 150, 200, and 250 C).

For the thermally annealed P3HT: PCBM/PEDOT:PSS/ITO coated glass structures, a 150 nm thick aluminum layer was thermally evaporated onto P3HT:PCBM using an Edward E306A evaporation system (Edward E306A, Easton PA, USA). The evaporation was carried out at a vacuum pressure of ˜1×10-6 Torr at a deposition rate of 0.2 nm/s. A shadow mask was used to define a device area of 0.1 cm².

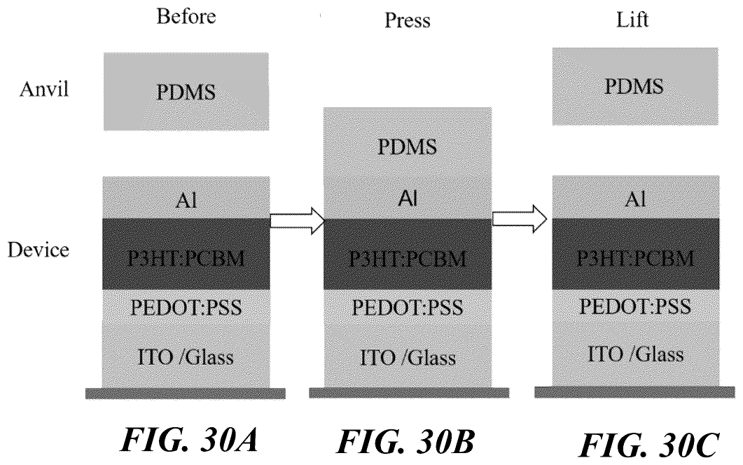

FIGS. 30A-30C depicts Schematics of the pressure assisted testing setup: FIG. before pressure application, FIG. 30B during press, and FIG. 30C during lifting up of the anvil. In selected cases, a controlled mechanical pressure was applied to both the device and the P3HT:PCBM-coated glass structures using an electromechanical Instron 5848 MicroTester (Instron, 5848 MicroTester, Norwood, MA, USA) with a poly-di-methyl siloxane (PDMS) anvil, as shown in the schematics FIGS. 30A-30C. First, the PDMS anvil was fabricated from a mixture of Sylgard 184 silicone elastomer base and Sylgard 184 silicone elastomer curing agent (Dow Corning Corporation, Midland, MI) in a ratio of 10:1 by weight. The mixture was then degassed and cured at 65° C. for 2 h in a mold with a polished silicon base. The PDMS anvil was then cut out into the dimensions of the glass substrates. Instron was used to apply compressive loading at a displacement rate of 1 mm/min up to a peak stress of 2 MPa. The peak stress was held constant for 10 min, before ramping down to zero stress at a displacement rate of 1 mm/min. A similar procedure was used to study the effects of ramping to peak pressures between 2 and 10 MPa.

The current density-voltage (J-V) characteristics of the fabricated devices were measured before and after the pressure treatment. This was done under AM1.5G illumination of 100 mW cm⁻² using a Keithley 2400 source meter unit (Keithley, Tektronix, Newark, NJ, USA) that was connected to an Oriel solar simulator (Oriel, Newport Corporation, Irvine, CA, USA). The solar simulator was calibrated using an optical power detector (918D-SL-OD2R, Newport Corporation, Irvine, CA, USA). The initial J-V curves of as-prepared devices were also obtained before measuring the J-V characteristics of solar cells that were subjected to pressures of 0-10 MPa. The optical absorbances of the P3HT:PCBM blend (produced with and without pressure application) were measured using an Avantes UV-VIS spectrophotometer (Avantes, Louisville, CO, USA), before and after thermal annealing. The resulting microstructures were then observed using a field emission gun Scanning Electron Microscope (SEM) (JSM 7000F, JOEL, Ltd., Tokyo, Japan) and an Atomic Force Microscope (AFM) (Naio-AFM, Nanosurf instruments, Woburn, MA, USA).

The XRD patterns of the P3HT:PCBM-coated structures were obtained from 150 nm thick active layers (P3HT:PCBM) deposited on clean glass substrates. These were obtained using an X-Ray Diffraction (XRD) system (Malvern PANalytical, Westborough, MA, USA). XRD patterns of the P3HT:PCBM thin films were obtained (for as-prepared films at different thermal annealing conditions and those that were pressure-assisted) using a CuKα radiation source with a beta nickel filter at 40 KV and 40 mA.

The influence of thermal annealing temperature and applied pressure on polymer chain alignment and crystallinity of the P3HT:PCBM films was also investigated using grazing incidence wide-angle x-ray scattering (GIWAXS) technique as previously reported. The experiments were carried out using an x-ray beam of 13.5 KeV and a wavelength of 9.18 nm at the 11-BM beamline (NSLS, Brookhaven National Laboratory, USA). The films were aligned such that the incident x-ray beam impinges on the samples at various shallow angles of ˜0.05°-0.15°, generating diffuse scattering from a large sample volume. The GIWAXS patterns were taken from a grazing incidence of 0.12, which is above the critical angle of the P3HT:PCBM blend.

Time-resolved terahertz spectroscopy (TRTS) measurements were carried out on P3HT:PCBM films that were spin-coated onto fused quartz substrates at 500 rpm for 60 s. The films were thermally annealed and assisted by mechanical pressure. The Tera-Hertz (THz) spectroscopy measurements were carried out as described previously. In brief, 400 nm (or 3.1 eV), 100 fs pulses with an energy fluence of 800 μJ/cm2 were used to photoexcite the films with an optical penetration depth of P3HT:PCBM at 400 nm. These were reported as ˜260 nm, substantially smaller than the film thickness, with excitation pulses that were almost fully absorbed in all the studied films. The resulting excitation induced changes in the complex conductivity were detected using a time-delayed THz probe pulse. THz pulses with bandwidths of 0.25⁻² THz (1-10 meV) were generated with an optical rectification of 100 fs and 800 nm pulse in a 1 mm thick [110] ZnTe crystal. The pulse was focused onto the P3HT:PCBM films using off-axis parabolic mirrors, and the transmitted THz pulses were detected using free-space electro-optic sampling in a second 1 mm thick [110] ZnTe crystal.

### Analytical and Computational Methods

Since excellent interfacial surface contacts are essential for the enhancement of work function alignment among the constituted layers of multilayered organic solar cells, the interfacial surface contacts between the layers in the OSCs can be enhanced by application of pressure (compression treatment). The structure and properties of thin films (subjected to mechanical pressure) also determine the deformation of the film. Interfacial defects can also occur due to environmental or undissolved/unfiltered particles that are sandwiched between layers as shown in FIGS. 3I-3L.

FIGS. 3I-3L depict analytical modeling of interfacial surface contact. FIG. 3I depicts an idealized particle without no pressure. FIG. 3J depicts with an idealized surface roughness without pressure. FIG. 3K and FIG. 3L depicts after application of pressure. Interfacial and layer defects in organic solar cells can be associated with settled particles between layers (FIG. 3I) or surface roughness due to undissolved particles (FIG. 3J). The improvement of interfacial surface contact as well as defects in photoactive material is, therefore, important for highly efficient devices. Various analytical models were used in studying the contact profiles of the interfaces in thin films prior to the application of pressure. When pressure is applied, the top films curl round the particles to improve interfacial contact (FIG. 3K). A relationship between the adhesion energy and the contact profile is:

$$γ = \frac{2 {Et}^{3} {h}^{2}}{3 ( 1 - {v}^{2} ) {r}^{4}} ,$$

where E, t, and h are the Young's modulus, thickness of the membrane and height of the trapped particle respectively; v is the Poisson's ratio of the membrane material, and γ is the adhesion energy.

The model can be simplified by a simple bi-layered structure (FIG. 3L) with the particle sandwiched between layers. The relationship between void length (S) and the contact ratio (L_{c}/L) can be written as:

$$s = {( \frac{3 {Et}^{3} {h}^{2}}{2 γ} )}^{\frac{1}{4}} and \frac{{L}_{c}}{L} = 1 - \frac{1}{L} {( \frac{3}{2} \frac{{Et}^{3} {h}^{2}}{2 γ} )}^{\frac{1}{4}}$$

The contact length can also be written as a function of the applied pressure as follows:

$$\frac{{L}_{c}}{L} = 1 - {[ \frac{3 ( \frac{E}{1 - {v}^{2}} ) {t}^{3} h}{2 {PL}^{4}} ]}^{\frac{1}{4}}$$

where L_{c} is the contact length and P is the applied pressure. The equation above has been verified using experimental studies of adhesion in cold-welded Au—Ag interfaces. Hence, since the material and geometric properties of the thin film layers are known, the contact length, the void length and the adhesion energy between the various interfaces that make up the OSCs can be determined with the aid of force microscopy or interfacial fracture mechanics methods, by obtaining the value of the Young's modulus from nano-indentation.

Defects can also initiate in the photoactive layer due to surface roughness and processing conditions. Usually, the types of trapped particles vary from hard to soft/compliant materials, depending on their Young's moduli. These films are deformed and wrapped round the particles when pressure is applied to improve the interfacial surface contact. The deformation of a thin film around interfacial particles can be idealized by the displacement of a cantilever beam. When the film deflects, the cantilever is brought into contact with the adjacent (bottom) layer. Consequently, the cantilever deflection and the interfacial surface contacts between adjacent layers provide insights into the formation of interlayer contacts between the adjacent layers of OSC structures.

However, when the trapped particles between layers are stiff (ITO, TiO₂, quartz, etc.), it is difficult to achieve interfacial layer contacts since the void length depends on the modulus and height of the trapped particle. Essentially, the rigid particles can sink-in into the compliant adjacent layers, which can ultimately lead to damage of the device structures. The relationship between the interfacial surface contact (Lc/L) and the applied pressure (P) can be expressed as

$$\frac{{L}_{c}}{L} = 1 - {[ \frac{3 ( \frac{E}{1 - {v}^{2}} ) {t}^{3} h}{2 {PL}^{4}} ]}^{1 / 4} ,$$

where Lc is the interfacial surface contact length, E is Young's modulus, v is the Poisson ratio, t is the film thickness, h is the height of the particle or film surface roughness, L is the length of the device structure, and P is the applied pressure. The relationship between the interfacial surface contact length and the defect/void dimension (S) can be expressed as

$$\frac{S}{L} = 1 - \frac{{L}_{c}}{L} .$$

The materials properties of layers were incorporated into the two equations to estimate the interfacial surface contact length and the defect/void sizes as a function of the applied pressure that can assist multilayered structures of OSCs.

The interfacial surface contacts in the multilayered OSC structures were also simulated using particles of different elastic properties. The simulations utilized materials properties that have been previously reported. The materials properties were incorporated into finite element modeling that was carried out using the ABAQUS software package (ABAQUS, Dassault Systemes Simulia Corporation, Providence, RI, USA).

The finite element simulations of the effects of pressure on interfacial surface contacts were carried out using the ABAQUS software package (Dassault Systemes Simulia Corporation, Providence, RI, USA). The effects of the properties of the particles were considered in the simulations of contact between the active layer and hole transport layer (Figure S1c). The segments of the devices in the region of the embedded particles were analyzed in the simulations. It is assumed that the part of the device, which is farther from the particle, has no significant effect on the mechanics around the particle.

A four-node bilinear axisymmetric quadrilateral element in the mesh was used. The mesh was dense in the regions near the dust particle and the contact surfaces. Identical mesh sizes were also used in the regions near the surface contact regimes to assure convergence in contact simulation. All the materials were assumed to exhibit isotropic elastic behavior. The Young's moduli and the Poisson's ratios of the materials that were used in the simulations are summarized in Table 7C. The bottom of the substrate was fixed to have no displacements and rotations. The outer edge of the model was also fixed to have no lateral movement for continuity, while a pressure was applied from the stamp onto the device.

TABLE 7C
Mechanical properties of materials for OSCs structure

| | Young's modulus |
|---|---|
| Material | (GPa) |
| Glass | 70 |
| ITO | 116 |
| PEDOT:PSS | 1.56 |
| P3HT:PCBM | 6.02 |
| Al | 69 |
| Particle | 70 |

### Results and Discussion

### Microstructures of Active Layers

The microstructures of as cast and annealed photoactive layers were observed using Atomic Force Microscopy (AFM) and Scanning Electron Microscopy (SEM). It has been shown that annealing of P3HT:PCBM above the glass transition temperature of P3HT drives the diffusion of PCBM into the polymer matrix and promotes polymer self-organization and crystallization. The glass transition temperature of P3HT has been reported to be in the range between and 110° C. As the films are annealed in this temperature regime and above, the microstructures of the P3HT:PCBM films evolve with increasing annealing temperature.

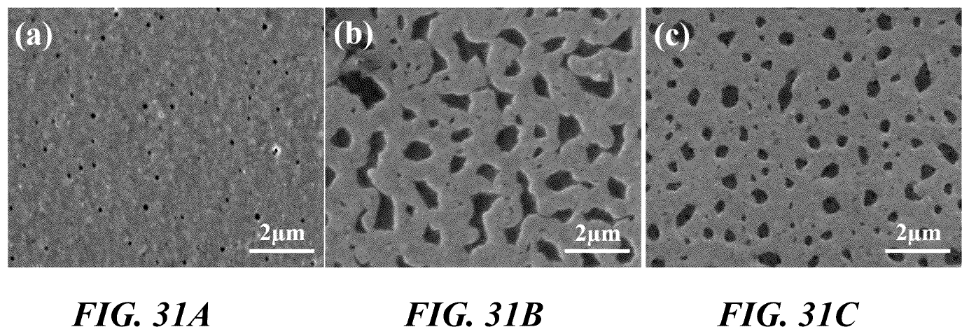

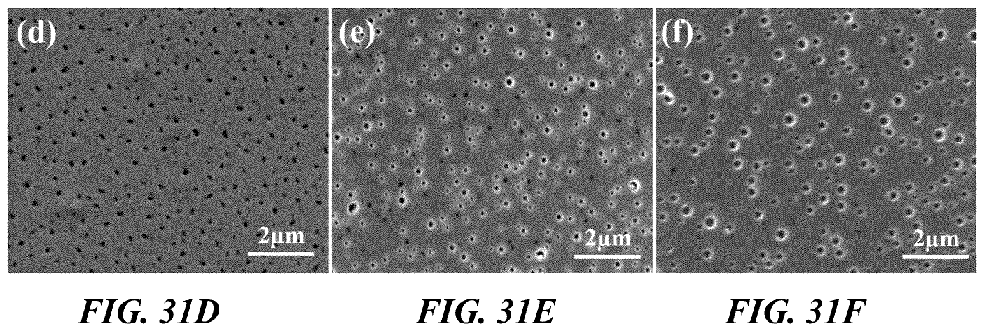

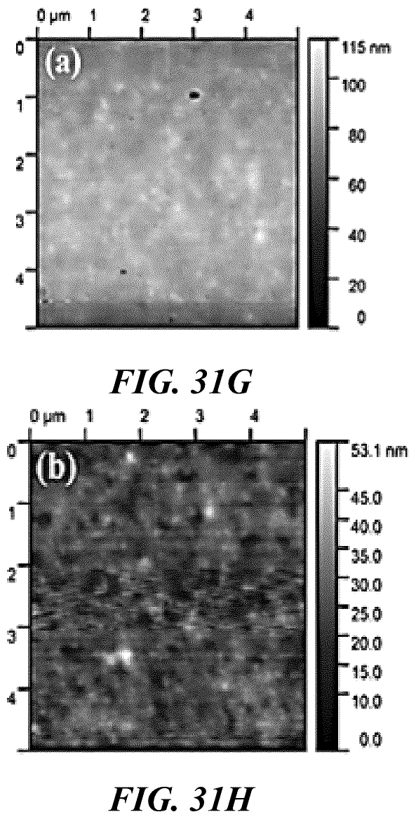

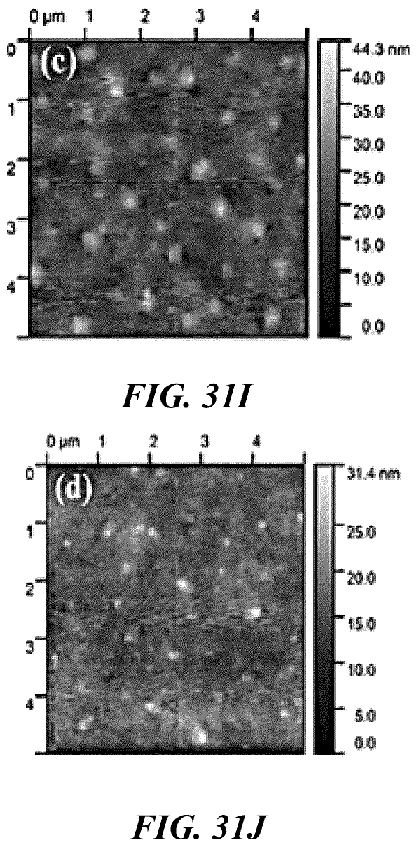

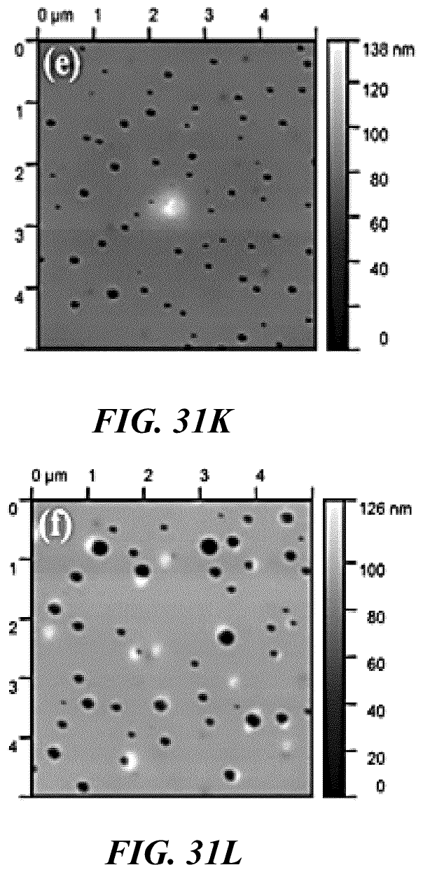

FIGS. 31A-31F depict SEM images of P3HT:PCBM films annealed at room temperature (RT) (FIG. 31A), 50 C (FIG. 31B), 100 C (FIG. 31C), 150 C (FIG. 31D), 200 C (FIG. 31E), and 250 C (FIG. 31F). FIGS. 31A-31F depict the SEM images of the evolving microstructures of the annealed P3HT:PCBM films (on PEDOT:PSS/ITO-coated glasses). In the un-annealed film depicted in FIG. 31A, sporadic PCBM phases were observed within the blend. Phase separation was also observed at room temperature (RT=˜22-25° C.). This resulted in the nucleation and growth of PCBM-rich regions in a matrix of P3HT. For annealing temperatures of 50 and 100° C. [FIGS. 31B and 31C], phase separated domains of P3HT and PCBM were observed with micron-scale agglomeration of PCBM. However, for annealing temperatures between 100 and 250° C., sub-micron PCBM-rich domains were observed within the continuous P3HT matrix. The PCBM-rich domains also continued to grow by agglomeration, as the annealing temperature increased FIGS. 31D-31F. This resulted in a larger area of P3HT-rich regions.

The above results show that increasing annealing temperatures (from 50 to 150° C.) enhances phase separation, yielding more finely dispersed donor and acceptor phases as depicted in FIGS. 31B-31D. This can improve transport of charges by creating percolation pathways for both donor and acceptor materials. It is important to note that the P3HT:PCBM constituents attain an equilibrium morphology at 150° C., which is driven by the thermodynamically drive re-organization of the P3HT polymer chains and PCBM molecules. Based on the P3HT:PCBM phase diagram, P3HT:PCBM mixtures should form a liquid phase at higher annealing temperatures of 200-250° C. as depicted in FIGS. 31E and 31F, for P3HT: PCBM ratios of 1:1 wt. %. This can lead to evaporation and the formation of pinholes at such temperatures.

The AFM images of the P3HT:PCBM films annealed at different temperatures are presented in FIGS. 31G-31L, which depict AFM images of P3HT:PCBM films annealed at: RT (FIG. 31G); 50° C. (FIG. 31H); 100° C. (FIG. 31I); 150° C. (FIG. 31J); 200° C. (FIG. 31K), and 250° C. (FIG. 31L). The surface roughness values of the films are summarized in Table 7D.

TABLE 7D
Surface roughness values of the films
at different annealing temperatures

| Temperature | |
|---|---|
| (° C.) | RMS (nm) |
| RT | 2.84 ± 1.07 |
| 50 | 3.12 ± 0.65 |
| 100 | 2.75 ± 0.42 |
| 150 | 1.65 ± 0.31 |
| 200 | 2.74 ± 1.89 |
| 250 | 3.88 ± 2.19 |

The film roughness values were obtained from small areas (5×5 μm2) of the film surface. The roughness of the films decreases with increasing annealing temperature, for annealing temperatures between 50 and 150° C. This is attributed to the effects of phase separation and the re-organization of PCBM in the P3HT matrix. However, annealing at temperatures between 200 and 250° C. results in increasing surface roughness, which can be associated with possible pinholes that were formed at high temperatures.

### Film Crystallinity

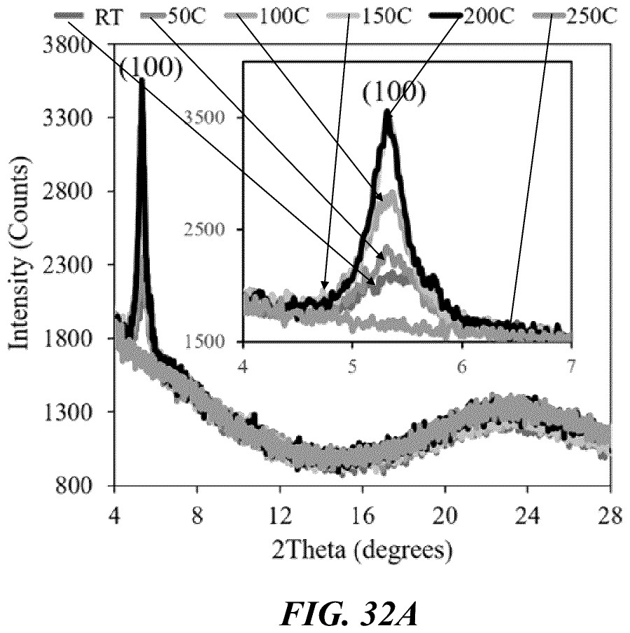

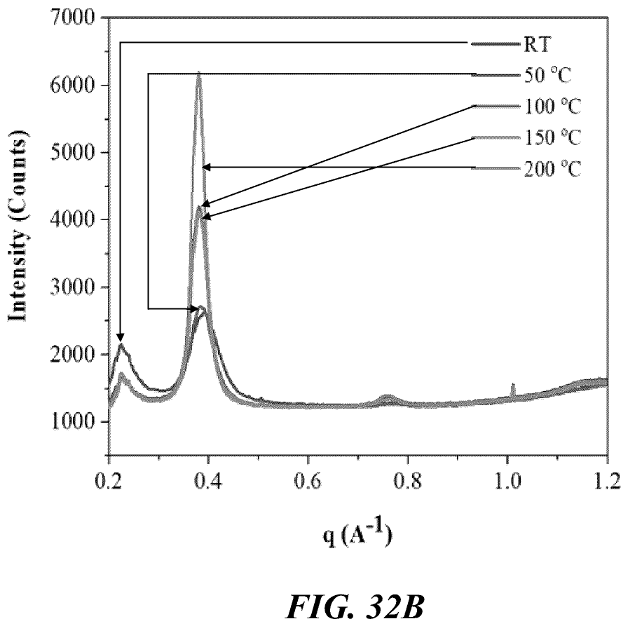

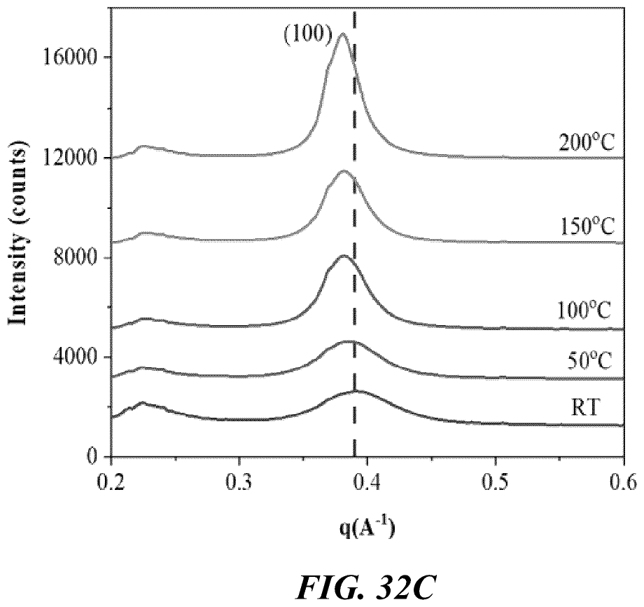

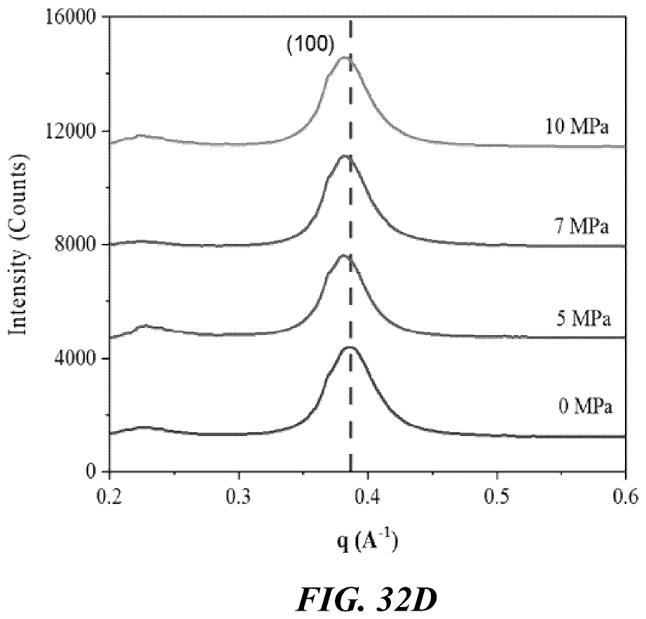

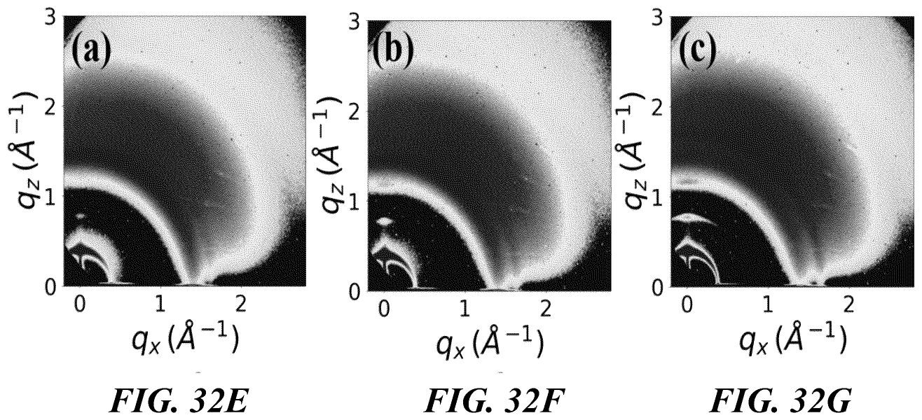

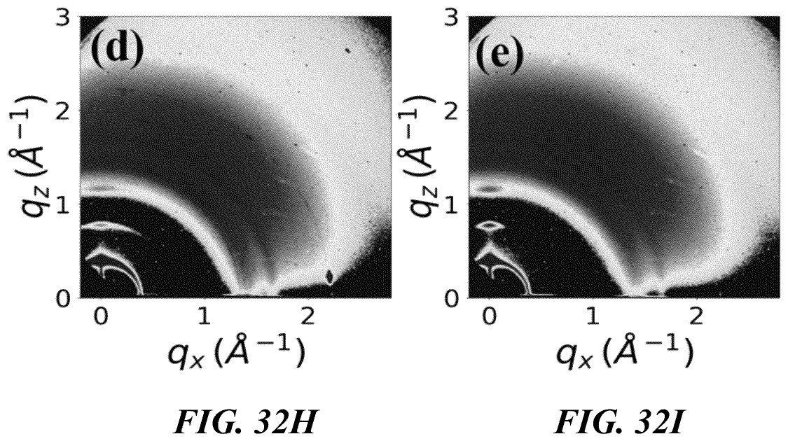

FIGS. 32A-32D depict crystallinity of the P3HT:PCBM films. FIG. 32A depicts XRD patterns at different annealing temperatures. FIGS. 32B and 32C depict GIWAXS patterns at different annealing temperatures. FIG. 32D depicts GIWAXS patterns of the pressure-assisted films. A combination of X-Ray Diffractometry (XRD) and grazing incidence wide-angle x-ray scattering (GIWAXS) synchrotron radiation was used to study the effects of mechanical pressure and thermal annealing on the P3HT:PCBM blends. FIG. 32A depicts the XRD patterns of the films at different annealing temperatures. The intensity of the strongest peak (that corresponds to plane 100) increases with increasing temperature up to 200° C. Further increase in annealing temperature to 250° C. revealed no peaks were observed due to the loss of crystallinity above the melting point. The differences in the (100) peaks of the films are clearer in the inset of FIG. 32A. Therefore, there were no GIWAXS pattern measurements for the films that were annealed at 250° C. as the XRD patterns already revealed that there were no peaks. The strongest peaks (at 285.3°) correspond to the inter-chain spacing of P3HT, which is associated with the interdigitated alkyl chains. Hence, using the (100) peak, the full-width-half-maximum (FWHM) of the fill was calculated using the Scherer equation. The FWHM values of the (100) peak decrease as the crystallite size increases with increasing annealing temperature up to 200° C. Table 7E presents the estimated FWHM of the films with respect to the annealing temperature.

TABLE 7E
Full-Width-Half-Maximum (FWHM) values of the
P3HT:PCBM annealed at different temperatures

| Temperature (° C.) | FWHM (nm) |
|---|---|
| Unannealed (RT) | 7.66 ± 0.078 |
| 50 | 8.92 ± 1.151 |
| 100 | 8.35 ± 1.033 |
| 150 | 8.08 ± 0.961 |
| 200 | 7.65 ± 0.946 |
| 250 | No peak |

GIWAXS patterns of the films at different annealing temperature between 50 and 200° C. are shown in FIG. 32B and FIG. 32C along with the GIWAXS patterns of the films that were assisted by mechanical pressures between 0 and 10 MPa in FIG. 32D. There was a left shift in the peaks FIG. 32B due to increasing annealing temperature. This is associated with an increase in the quality of crystal of the films and strain relaxation between the films and the substrates. A further slight left shift in the peaks obtained for the pressure-assisted films depicted in FIG. 32D. This slight shift can also be an indication of induced-crystallization and reduction in the defects within the films.

The two-dimensional GIWAXS images (FIGS. 32E-32I) of the films show evidence of π-π stacking in the direction parallel to the substrate, that is, (100) peak along qz and (010) being in-plane along qₓ, as shown by the weak in-plane scattering at ˜1.65 A⁻¹. FIGS. 32E-32I depict 2-D GIWAXS images of P3HT:PCBM films at different annealing temperature RT (FIG. 32E); 50° C. (FIG. 32F); 100° C. (FIG. 32G); 150° C. (FIG. 32H), and 200° C. (FIG. 32I). There is evidence of slight π-π stacking in the direction that is perpendicular to the substrate, as the lamellar stacking is in-plane. In the annealed films, the π-π stacking is predominantly parallel to the substrate. Annealing drives the system toward a lower free energy state by the self-organization of the P3HT lamellar and the π-π stacking direction parallel to the substrate, thereby attaining an edge-on configuration. The decrease in the FWHM values (Table 7E) of the out-of-plane peak suggests that the P3HT lamellae/crystallites grew in a direction that was parallel to the substrate.

### Optical Properties

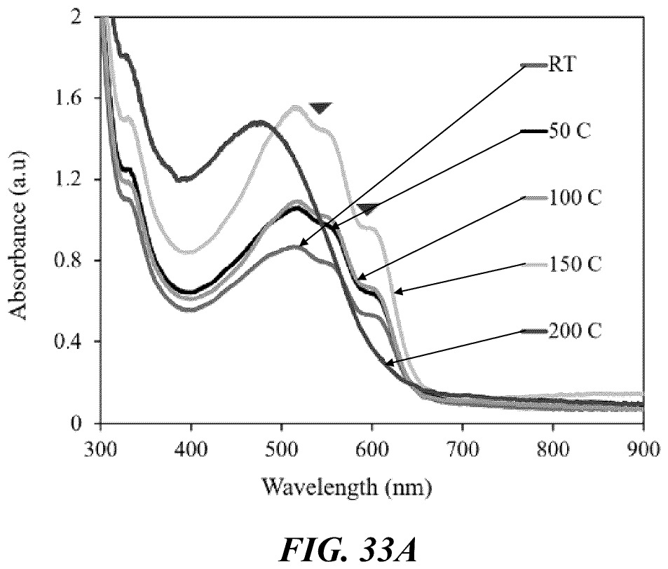

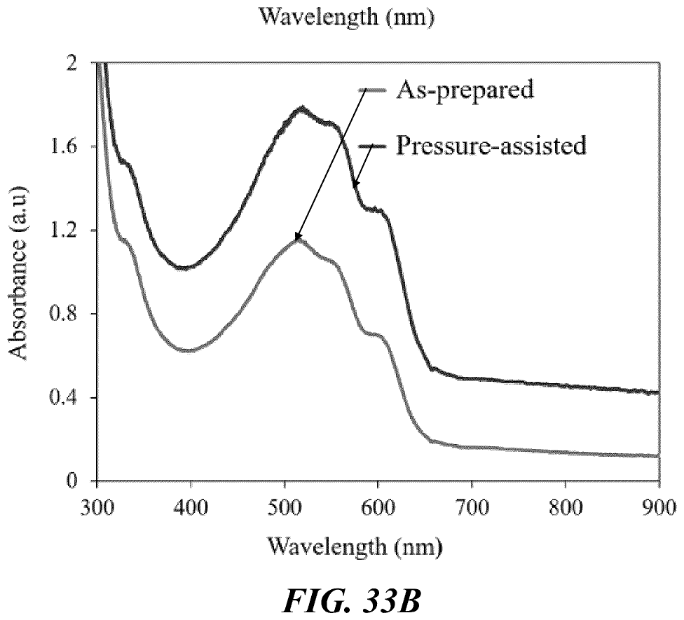

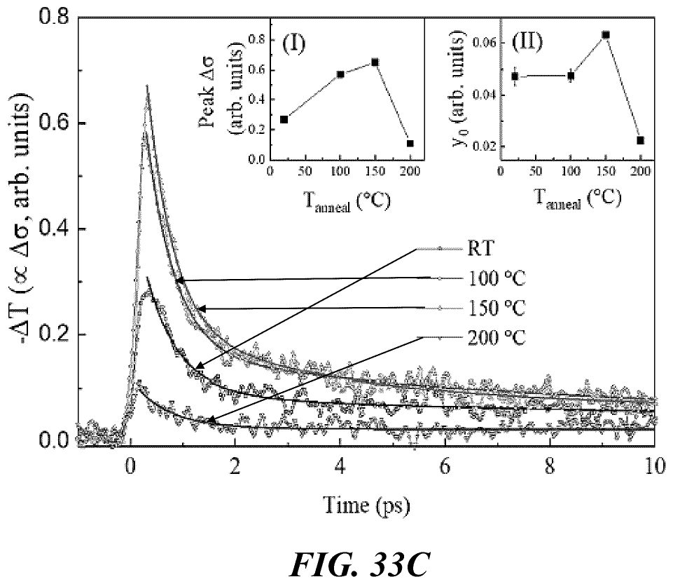

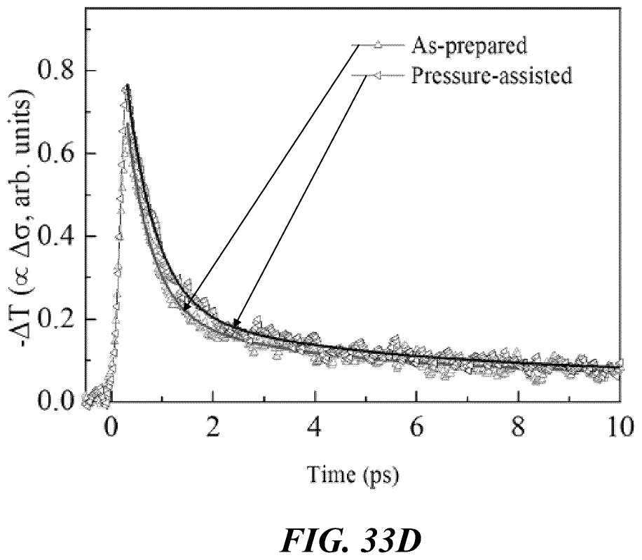

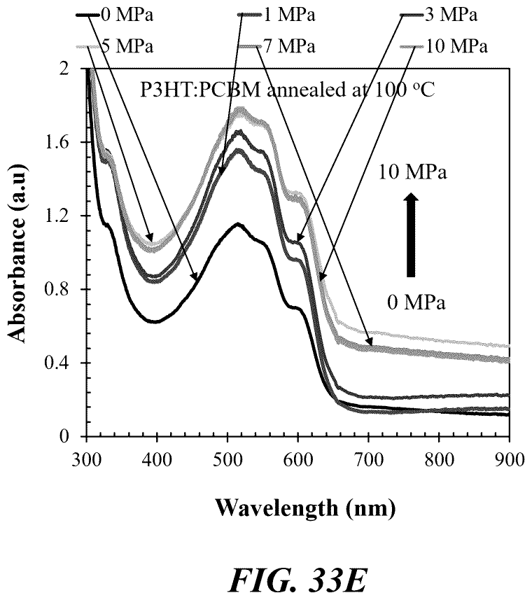

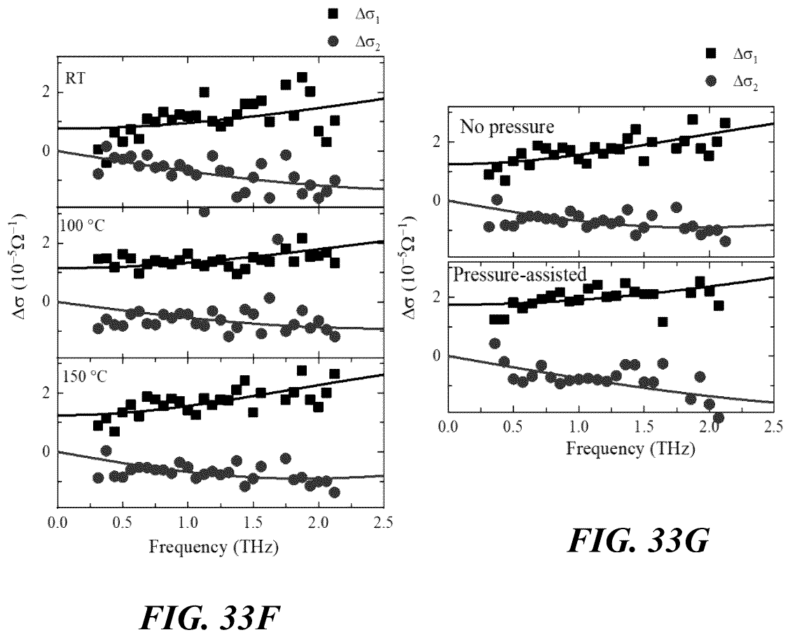

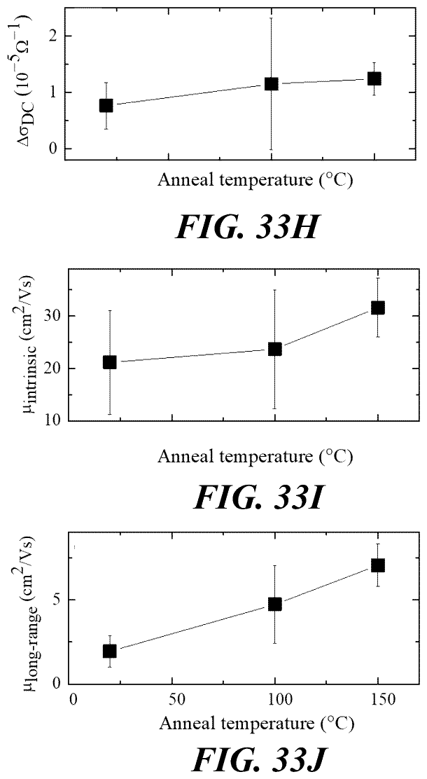

FIGS. 33A-33D depict optical absorbance spectra and transient photoconductivity of P3HT:PCBM films. FIG. 33A depicts optical absorbance at different annealing temperatures (the triangles indicate the positions of two vibronic shoulders at around 550 nm and 600 nm). FIG. 33B depicts optical absorbance of pressure-assisted films that were thermally annealed at 100 C. FIG. 33C depicts transient photoconductivity (−ΔT∝Δσ) following excitation with 400 nm, 100 fs pulses with ˜800 μJ/cm2 fluence for films prepared with different annealing temperature (insets I and II show the peak photoconductivity and the long-lived photoconductivity component as a function of the annealing temperature, respectively). FIG. 33D depicts transient photoconductivity for pressure-assisted films annealed at 150 C.

The optical properties of the P3HT:PCBM films are depicted in FIGS. 33A and 33B. There was a significant increase in magnitude and a slight red shift of the absorbance peaks within the visible spectrum (450-650 nm) with increasing annealing temperatures between room temperature (RT) and 200° C. in 33A. This increase in absorption is associated with an increase in the packing of the P3HT chains. In the case of the films that were annealed between RT and 150° C., two vibronic shoulders [triangles in FIG. 33A were observed at 550 and 600 nm wavelengths. These are attributed to higher levels of crystallization as depicted in FIGS. 32A-32C by intra-chain stacking in conducting polymers. There was pronounced blue shift of the peaks in the films annealed above 150° C. The disappearance of the vibronic shoulders at 200° C. annealing temperature FIG. 33A is attributed to a low level of intrachain stacking in the films. In the case of pressure-assisted films, there is also a significant increase in absorption of light depicted in FIG. 33B and FIG. 33E. This can be associated with healing of defects within films and along the film/substrate interface. There is tendency for the film to strain horizontally as the mechanical pressure is being applied to the surface of the films, leading to closing of existing voids/defects and induced-phase separation.

### Photoexcitation of Charge Carrier Generation and Transport

Time-resolved terahertz spectroscopy (TRTS) can be used to study the effects of microstructural changes due to mechanical pressure and thermal annealing. These reveal the intricate interplay of processes involved in the photoexcitation of P3HT:PCBM films. As the low energy THz pulses are sensitive to free, mobile charge carriers, TRTS enables contact-free, all-optical measurements of microscopic photoconductivity and dynamics of photoexcited charge carriers. These include free carriers and charged species, such as polarons, in the case of conjugated polymers and organic semiconductors.

Monitoring the excitation-induced changes (in the THz absorption regime) as a function of the optical pump-THz probe delay provides information about the carrier lifetime and photoconductivity dynamics. In the limit of small photoinduced changes, the negative change in the transmission of the THz probe pulse peak is proportional to photoconductivity, as −ΔT(t)/T∝Δσ(t).

FIGS. 33C and 33D summarize the transient photoconductivity dynamics in a series of films annealed at different temperatures as depicted in FIG. 33C and in a series of films annealed at 150° C. that have been assisted by pressure as depicted by FIG. 33D. The overall dynamics of the films agree with previously reported results on P3HT:PCBM films: a rapid increase in photoconductivity over timescales that are comparable to or shorter than our experimental time resolution of ˜200 fs is followed by a multi-exponential decrease that in the experimental time window is well-described by a biexponential decay function Δσ(t)=A_{1E}^{-t/t1}+A_{2E}^{-t/t2}+y₀. In this function, A₁, A₂ represent amplitudes of the two constituent decay components and y₀ is a constant offset that represents a longer-lived component that decays over the timescales that are longer than 20 ps. The fastest, t₁=0.5±0.1 ps, decay component is consistent with exciton formation time, while a slower, t₂=4±1 ps, component likely accounts for trapping of free carriers at defects and grain boundaries. A fraction of charge carriers remains free and mobile for considerably longer times and is represented by the constant offset yₒ.

While the fast and slow decay times are essentially unchanged by thermal annealing or pressure, the overall magnitude of photoconductivity is sensitive to both. With the same film thicknesses in both series and the same excitation conditions, this change in overall peak photoconductivity can be explained by differences in the density of free carriers that is present in the films at times longer than an experimental time resolution of ˜200 fs and, to a lesser extent, by annealing-induced and pressure-induced changes in carrier mobility, discussed in more detail below. Insets I and II in FIG. 33C show the dependence of peak photoconductivity and long-lived photoconductivity (yₒ) on annealing temperature. Both parameters increase in films with increasing annealing temperatures up to ˜150° C., where microstructure changes observed in SEM depicted in FIGS. 31A-31F and AFM images depicted in FIGS. 31G-31L demonstrate improvements of crystallinity, reduction of surface roughness, and formation of percolative pathways for both electrons (in continuous PCBM domains) and holes (in the P3HT matrix). Improvement in peak photoconductivity can likely be attributed to suppressed trapping and self-localization of the free carriers over short (<200 fs) timescales at defect sites. However, when annealing temperature is increased to 200° C., both peak and long-lived photoconductivity drop, consistent with the reduction of light absorption depicted in FIG. 33A due to the formation of pin holes depicted in FIG. 33E at high annealing temperatures. Applying mechanical pressure to the films annealed at 150° C. further improved photoconductivity.

For more insight into microscopic conductivity of films and influence of thermal annealing and mechanical pressure on carrier mobility, recordings were made of complex frequency-resolved photoconductivity spectra at 2-3 ps after photoexcitation (FIGS. 33F and 33G). Complex photoconductivity spectra were calculated by analyzing the photoexcitation-induced changes in the amplitude and the phase of the THz pulse waveform transmitted through the sample. Then model complex photoconductivity of P3HT:PCBM films with a phenomenological Drude-Smith model, a modification of the free carrier Drude conductivity that accounts for localization of the mobile carriers on the length scales commensurate with their mean free path and has been extensively applied to describe photoconductivity in conjugated polymers and other disordered systems. Results from the analysis of the Drude-Smith analysis are presented in FIGS. 33F and 33G for both thermally annealed as depicted in FIG. 33F and pressure-assisted films depicted in FIG. 33G. The long-range conductivity (σDS) of the polymeric films is also depicted in FIG. 33H.

FIGS. 33F and 33G depict photoinduced change in complex THz photoconductivity at 3 ps after photoexcitation with ˜800 μJ/cm², 100 fs, 400 nm pulses for different annealing temperature (FIG. 33F) and pressure (FIG. 33G). Black squares and red circles show real and imaginary conductivity components, respectively. Lines are fits of experimental data to Drude-Smith model. FIGS. 33H-33J depict effects of thermal annealing on long-range conductivity (σ_{DS}) and carrier mobility of films: (FIG. 33H) Long-range conductivity; (FIG. 33I) short-range carrier mobility (μ_{short-range}), and (FIG. 33J) long-range carrier mobility (μ_{long-range}).

Complex photoconductivity of P3HT:PCBM films are modeled with a phenomenological Drude-Smith model, a modification of the free carrier Drude conductivity that accounts for localization of the mobile carriers on the length scales commensurate with their mean free path, and has been extensively applied to describe photoconductivity in conjugated polymers and other disordered systems. Complex frequency-resolved conductivity is given as

$$Δ σ ( ω ) = \frac{{σ}_{0}}{1 - i ω {τ}_{DS}} ( 1 + \frac{c}{1 - i ω {τ}_{DS}} ) ,$$

where τ_{DS} is a carrier relaxation time,

$${σ}_{0} = \frac{{Ne}^{2} {τ}_{DS}}{{m}^{*}} ,$$

N is the intrinsic charge carrier density and m* is the carrier effective mass. In this formalism, the DC conductivity is given by a σ_{DC}=σ₀(1+c), where c is a phenomenological parameter that represents the effect of disorder on carrier transport. When c=0, the Drude model is recovered and carriers move throughout the sample unimpeded, while c=−1 yields the fully suppressed σ_{DC} as the free carriers are mobile only over short distances. While the bandwidth of our THz source does not extend below ˜0.25 THz, σ_{DC} can be estimated by extrapolating the fit of the real component of the photoconductivity to 0 THz. As it can be seen in FIGS. 33F-33J, which plots some of the results of the Drude-Smith analysis, long-range conductivity, σ_{DC}, shows a slight but detectable improvement in response to the thermal anneal at temperatures up to 150° C., as well as in response to applied pressure.

Furthermore, using the Drude-Smith momentum relaxation time τ_{DS} (an experimental fitting parameter) and an effective mass m*=1.7mₑ, calculated both short-range mobility of carriers within the homogeneous crystalline regions as

$${μ}_{short - range} = \frac{e {τ}_{DS}}{{m}^{*}} ,$$

and the long-range mobility over macroscopic length scales is then given as μ_{long-range}=μ_{short-range}(1+c). Dependence of both parameters on annealing temperature and pressure are also shown in FIGS. 33H-33J. We find that short range mobility is in good agreement with a theoretical prediction of 31 cm²/Vs for crystalline P3HT. Long range mobility of the free carriers is significantly lower, limited by the size of the crystalline regions and transport of carriers through the grain boundaries. We find that both short- and long-range mobility increase slightly in response to the thermal annealing, which improves crystallinity and grows percolative pathways. Also, we conclude that an increase in the overall conductivity of the films is due to increase in the lifetime of photoinduced free carriers that is associated with improved interface quality and reduced defects (due to pressure application).

### Performance Characteristics of Devices

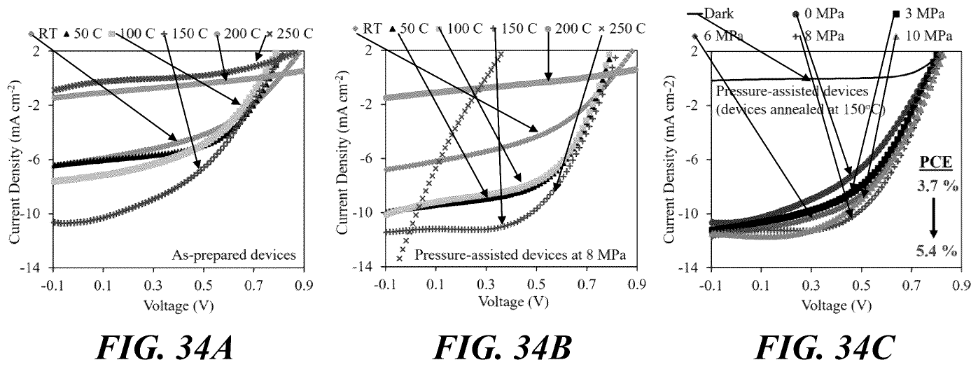

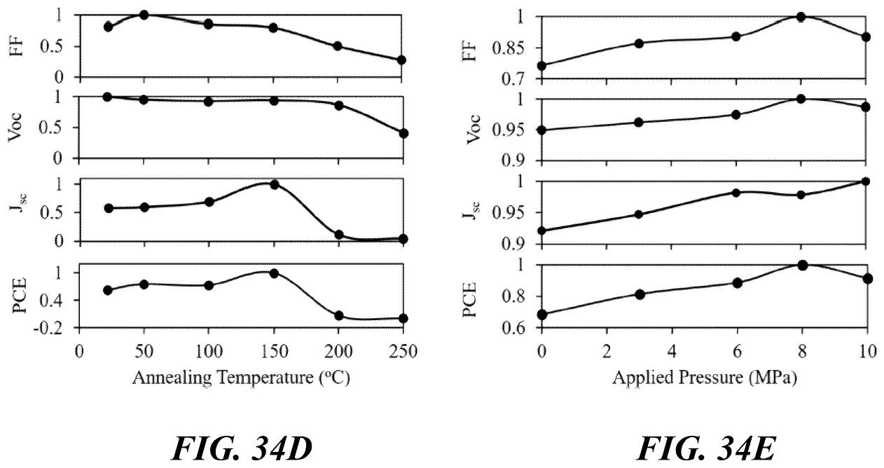

FIGS. 34A-34E depict characteristics performance of OSCs at different applied pressures and thermal annealing temperatures. FIG. 34A depicts current density-voltage curves of as-prepared devices at different thermal annealing temperatures. FIG. 34B depicts current density-voltage curves of pressure-assisted devices (for 8 MPa applied pressure) at different thermal annealing temperatures. FIG. 34C depicts effects of pressure on the current density-voltage curves of devices at 150 C annealing temperature. FIG. 34D depicts normalized device characteristic parameters vs annealing temperature. FIG. 34E depicts normalized device characteristic parameters vs applied pressure.

The current density-voltage (J-V) curves are depicted in FIG. 34A for as-prepared P3HT:PCBM devices that were annealed at different temperatures (RT-250° C.). The device parameters (fill factors, FFs; short-circuit current densities, J_{sc}; open circuit voltages, V_{oc}; and PCE) are summarized in Table 8.

TABLE 8
Summary of device parameters: short-circuit current density
(J_{SC}), open circuit voltages (V_{oc}), fill factors (FFs), and photo-
conversion efficiencies (PCEs) at different annealing temperatures.

| Temperature (° C.) | Jsc (mA cm⁻²) | Voc (V) | FF | PCE^{a} (%) |
|---|---|---|---|---|
| RT | 6.16 | 0.8 | 0.42 | 2.32 |
| 50 | 6.37 | 0.76 | 0.52 | 2.52 |
| 100 | 7.37 | 0.74 | 0.44 | 2.70 |
| 150 | 10.62 | 0.75 | 0.42 | 3.70 |
| 200 | 1.26 | 0.69 | 0.26 | 0.25 |
| 250 | 0.50 | 0.33 | 0.15 | 0.03 |

² Average values of PCEs from five to eight devices.

The results show increased PCEs with increasing temperatures between RT and 150° C. However, annealing at higher temperatures (200 and 250° C.) leads to reduced OSC performance characteristics. The J-V curves of the pressure-assisted devices are also depicted in FIGS. 34B and 34C, while a summary of the pressure effects on device parameters is presented in Table 9.

TABLE 9
Summary of device parameters at different applied pressures.

| Pressure (MPa) | Jsc (mA cm⁻²) | Voc (V) | FF | PCE^{a} (%) |
|---|---|---|---|---|
| 0 | 10.62 | 0.75 | 0.42 | 3.70 |
| 2 | 10.92 | 0.76 | 0.48 | 4.41 |
| 5 | 11.32 | 0.77 | 0.50 | 4.80 |
| 8 | 11.28 | 0.79 | 0.55 | 5.41 |
| 10 | 11.53 | 0.78 | 0.50 | 4.95 |

² Average values of PCEs from four to six devices.

The results show an increased PCE with increasing applied pressure between 0 and 8 MPa for all devices annealed at different temperatures depicted in FIG. 34B. However, the application of pressure to devices that were prepared at higher temperatures (above 150° C.) resulted in almost linear J-V curves depicted in FIG. 34B.

In the case of devices that were thermally annealed at 150° C., pressure application significantly increased PCEs by ˜46% as depicted in FIG. 34C. The normalized device parameters are presented in FIGS. 34D and 34E for different annealing temperatures [FIG. 34D] and applied pressures [FIG. 34E]. Both the PCEs and short circuit current densities (Jsc) of devices increased with increasing annealing temperature between RT and 150° C., while there were no significant improvements in the open circuit voltage (Voc) and fill factor (FF) [FIG. 34D] with increasing annealing temperature. For the devices annealed at 150° C., the normalized device parameters (PCE, Jsc, Voc, and FF) increased with increasing applied pressure between 0 and 8 MPa [FIG. 34E)].

The above trends in the device performance characteristics are attributed to the combined effects of improved crystallinity, enhanced photoconductivity, and reduced defects in layers and along interfaces of multilayered structures. Applied pressures closes voids within the device active layer and improve interfacial surface contacts, which reduces trapping of carriers and layer and interfacial defects. Hence, annealing at temperatures up to 150° C. improves charge transport in OSCs, while applied pressure reduces defect lengths and enhances charge transport across interfaces in BHJ structures.

Hence, the improvements in photoconversion efficiencies due to mechanical pressure and thermal annealing effects are attributed to the improved P3HT:PCBM film texture and interfacial surface contacts. The decrease in device performance, for pressure application above ˜8 MPa, is attributed to the sink-in of impurities that are present at the interfaces between the layers or inclusions at the defect sites. Such sink-in phenomena have been modeled in prior work and shown to promote “damage phenomena” that decrease the device performance, in cases where the applied pressures exceed ˜8 MPa.

### Effects of Pressure on Interfacial Defects

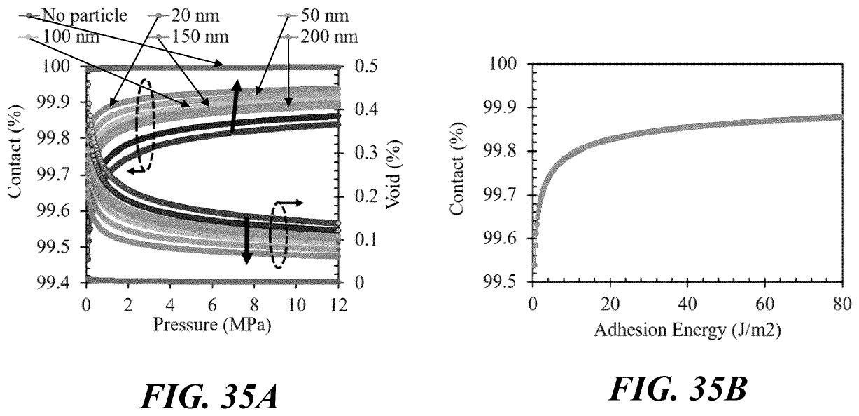

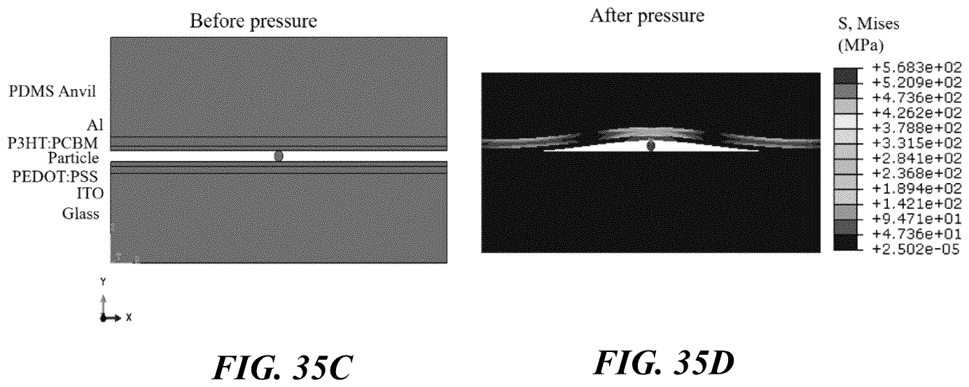

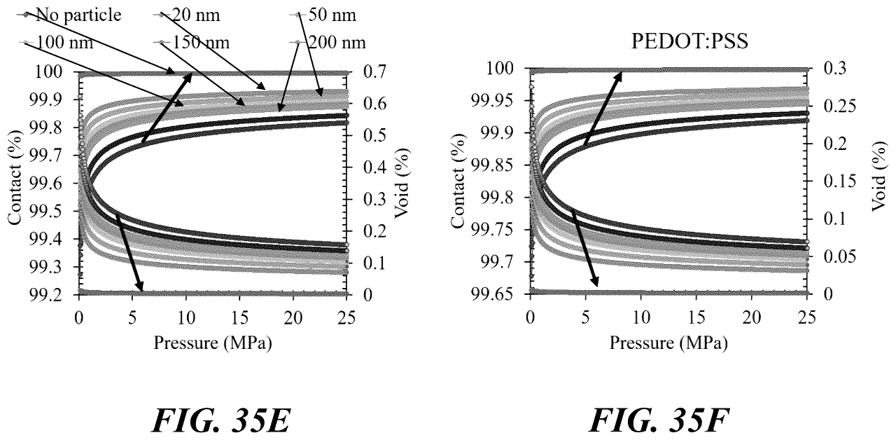

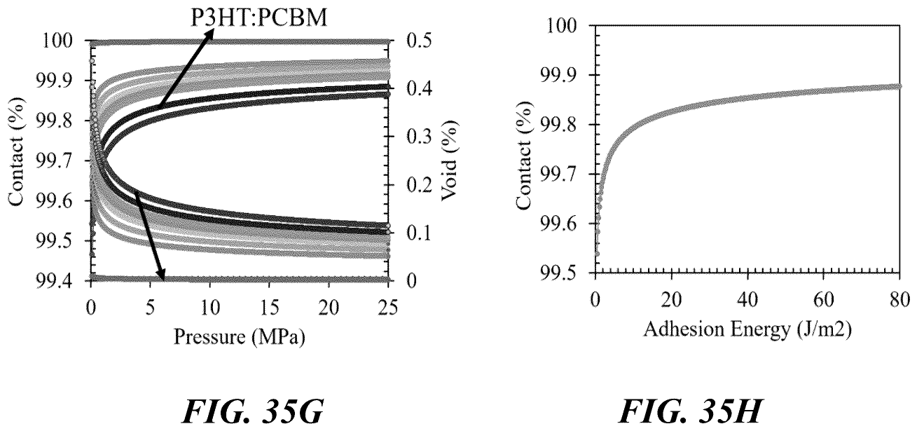

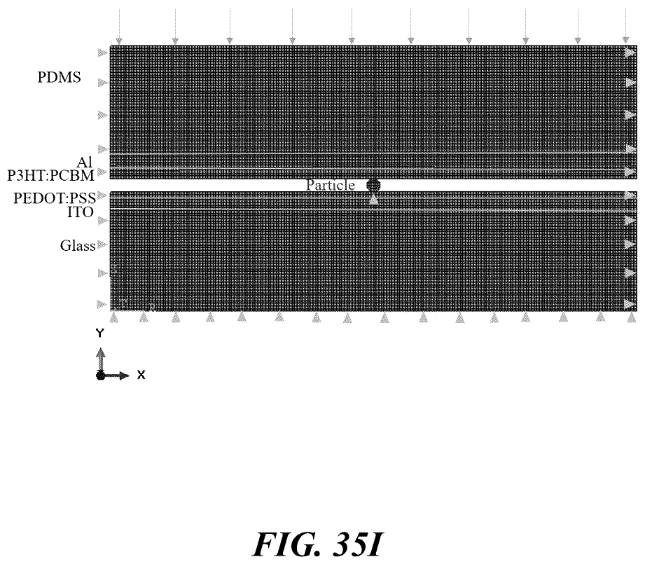

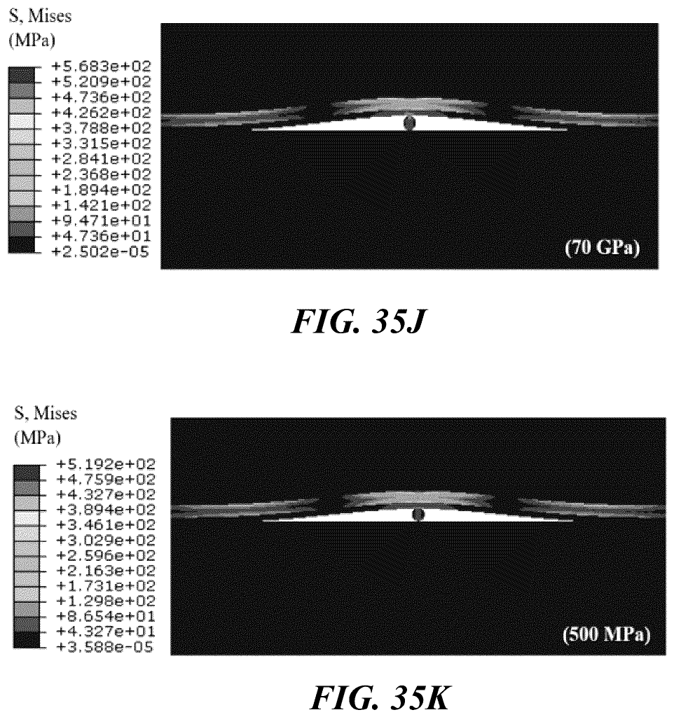

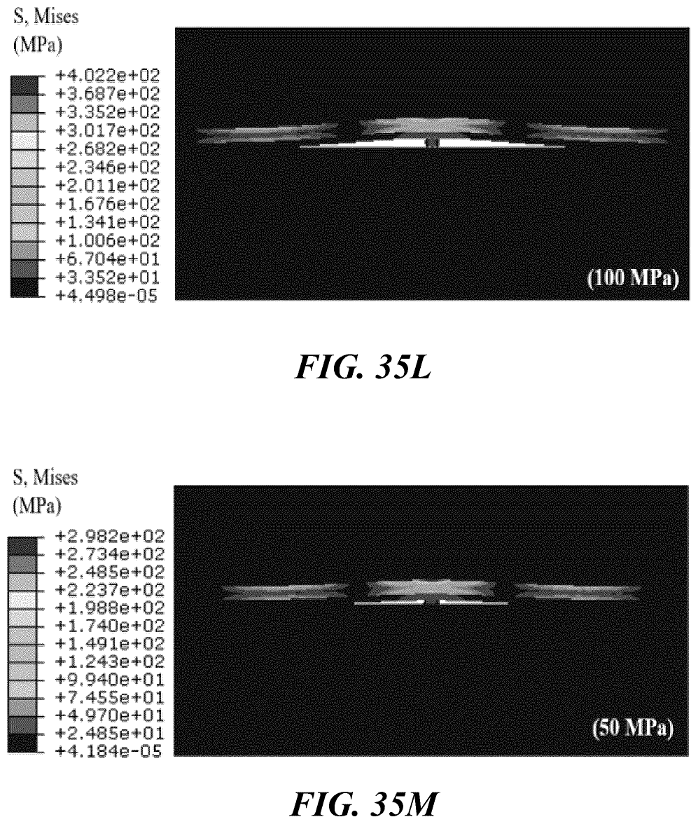

FIGS. 35A-35D depict modeling of effects of mechanical pressure on interfacial surface contacts. FIG. 35A depicts analytical modeling of interfacial surface contacts and voids vs pressure for particles of different sizes. FIG. 35B depicts interfacial surface contact vs adhesion energy. FIGS. 35C and 35D depicts computational modeling of interfacial surface contacts before (FIG. 35C) and after (FIG. 35D) pressure application. The modeling considers the interface between P3HT:PCBM and PEDOT:PSS of the device.

The effects of mechanical pressure on interfacial defects using analytical and computational modeling. The estimated interfacial surface contact lengths (for different sizes of the particles) are presented in FIG. 35A as a function of the applied pressure. The P3HT:PCBM photoactive layer showed an improved interfacial surface contacts with increasing applied pressures FIG. 35A. The presence of defects/voids also reduces with the increased pressure. The surface contact lengths and voids between the active P3HT:PCBM layer and the adjacent layers were calculated at different applied pressures between 0 and 12 MPa [using Eqs. (1) and (2)]. As expected, the results showed increased contacts as the interfacial adhesion energy increased FIG. 35B. More results on the improved interfacial surface contacts between the different layers of OSCs are presented in FIGS. 35E-35H, which depict effects of applied pressure on interfacial surface contacts for different layers of organic solar cells: (FIG. 35E) cathode Aluminum layer, (FIG. 35F) PEDOT:PSS layer, and (FIG. 35G) P3HT:PCBM. (FIG. 35H) Interfacial surface contact versus interfacial adhesion energy for P3HT:PCBM. The results also show that, for small particle sizes, OSC films require less pressure for surface contact to occur between adjacent layers compared to large particle sizes.

The interfacial surface contacts are simulated using the ABAQUS software package (ABAQUS, Pawtucket, RI, USA). The detailed finite element analysis (FEA) model for the pressure treatment of OSCs is presented in FIG. 35I. Our results of the simulated interfacial contacts between the photoactive layer and the hole-transporting layer (PEDOT:PSS), before and after pressure application, are presented in FIGS. 35C and 35D. The PDMS anvil deforms and curls around the particle as the surface contact increases. It is important to note that interfacial surface contacts depend on mechanical properties of particles. Compliant particles deform very easily with increasing pressure, compared to the limited deformation of rigid particles. The distribution of stresses in the structures is lower for compliant particles (with better interfacial surface contacts) compared with that of rigid particles FIGS. 35J-35M, which depict interfacial contacts with particles of different mechanical properties.

### CONCLUSION

Example 5 explores the effects of pressure application and thermal annealing on the structure and performance characteristics of polymer solar cells with blended P3HT:PCBM active layers. The results show that thermal treatment at temperatures up to 150° C. enhances the agglomeration of PCBM-rich domains in the active material, P3HT:PCBM, of the OSCs. These structural changes lead to improved optical absorption, increased mobility, and increased lifetime of the optically excited charge carriers and, as a result, to an increase in the PCEs of the solar cells from ˜2.3% for cells annealed at room temperature to 3.7% for solar cells annealed at 150° C. At higher annealing temperatures, the crystallinity decrease, accompanied by pinhole formation, results in a decrease in photoconductivity and the degradation of the PCEs of the OSCs. The application of pressure (up to pressures of ˜8 MPa) also increases the device PCEs from 3.8% to 5.4%. This improvement is attributed to the reduction in interfacial defect sizes due to pressure application. At pressures beyond 8 MPa, the induced damage (sink-in) of the OSC structures results in a reduction in PCEs.

As utilized herein, the terms “comprises” and “comprising” are intended to be construed as being inclusive, not exclusive. As utilized herein, the terms “exemplary”, “example”, and “illustrative”, are intended to mean “serving as an example, instance, or illustration” and should not be construed as indicating, or not indicating, a preferred or advantageous configuration relative to other configurations. As utilized herein, the terms “about”, “generally”, and “approximately” are intended to cover variations that may existing in the upper and lower limits of the ranges of subjective or objective values, such as variations in properties, parameters, sizes, and dimensions. In one non-limiting example, the terms “about”, “generally”, and “approximately” mean at, or plus 10 percent or less, or minus 10 percent or less. In one non-limiting example, the terms “about”, “generally”, and “approximately” mean sufficiently close to be deemed by one of skill in the art in the relevant field to be included. As utilized herein, the term “substantially” refers to the complete or nearly complete extend or degree of an action, characteristic, property, state, structure, item, or result, as would be appreciated by one of skill in the art. For example, an object that is “substantially” circular would mean that the object is either completely a circle to mathematically determinable limits, or nearly a circle as would be recognized or understood by one of skill in the art. The exact allowable degree of deviation from absolute completeness may in some instances depend on the specific context. However, in general, the nearness of completion will be to have the same overall result as if absolute and total completion were achieved or obtained. The use of “substantially” is equally applicable when utilized in a negative connotation to refer to the complete or near complete lack of an action, characteristic, property, state, structure, item, or result, as would be appreciated by one of skill in the art.

Numerous modifications and alternative embodiments of the present disclosure will be apparent to those skilled in the art in view of the foregoing description. Accordingly, this description is to be construed as illustrative only and is for the purpose of teaching those skilled in the art the best mode for carrying out the present disclosure. Details of the structure may vary substantially without departing from the spirit of the present disclosure, and exclusive use of all modifications that come within the scope of the appended claims is reserved. Within this specification embodiments have been described in a way which enables a clear and concise specification to be written, but it is intended and will be appreciated that embodiments may be variously combined or separated without parting from the present disclosure. It is intended that the present disclosure be limited only to the extent required by the appended claims and the applicable rules of law.

What is claimed is:

1. A method for fabricating photovoltaic devices, the method comprising:
forming a photovoltaic device comprising an active layer with one or more interfacial layers adjacent the active layer, wherein the active layer comprises a photovoltaic material and the one or more interfacial layers comprise a material configured to collect charge carriers generated in the photovoltaic material;
applying pressure onto the photovoltaic device to increase an amount of electrical contact between the active layer and the one or more interfacial layers; and
annealing the photovoltaic device.

2. The method of claim 1, wherein the photovoltaic material is perovskite material.

3. The method of claim 1, wherein applying pressure comprises applying a pressure between 5 and 10 MPa.

4. The method of claim 1, wherein the one or more interfacial layers comprise an electron transport layer in electrical contact with the active layer.

5. The method of claim 1, wherein the photovoltaic device is annealed at a temperature between 140 and 160 Celsius.

6. The method of claim 1, wherein the application of pressure deforms the active layer around one or more interlayer particles disposed between the active layer and the one or more interfacial layers.

7. The method of claim 1, wherein the pressure is determined based on a thickness of the active layer.

8. The method of claim 1, wherein the efficiency of the photovoltaic device is increased between 10% and 15%.

9. The method of claim 1, wherein the turn-on voltage of the photovoltaic device is reduced by 1 Volt.

10. The method of claim 1, wherein forming a photovoltaic device comprises:
depositing, on a substrate, a first conductive layer;
depositing, on the first conductive layer, a first interfacial layer comprising an electron transport material;
depositing the active layer on the first interfacial layer;
depositing, on the active layer, a second interfacial layer comprising a hole transport material; and
depositing, on the second interfacial layer, a second conductive layer,
wherein the pressure is applied after the second conductive layer is deposited to increase the amount of contact between the layers.

11. A system for fabricating photovoltaic devices comprising:
a photovoltaic device comprising an active layer with one or more interfacial layers the active layer, wherein the active layer comprises a photovoltaic material and the one or more interfacial layers comprise a material configured to collect charge carriers generated in the photovoltaic material;
a pressure applicator configured to apply pressure onto the photovoltaic device to increase an amount of electrical contact between the active layer and the one or more interfacial layers; and
an oven configured to anneal the photovoltaic device.

12. The system of claim 11, wherein the photovoltaic material is perovskite material.

13. The system of claim 11, wherein the pressure is between 5 and 10 MPa.

14. The system of claim 11, wherein the one or more interfacial layers comprise an electron transport layer in electrical contact with the active layer.

15. The system of claim 11, wherein the efficiency of the photovoltaic device is increased by up to 15%.

16. The system of claim 11, wherein the photovoltaic device comprises:
depositing, on a substrate, a first conductive layer;
depositing, on the first conductive layer, a first interfacial layer comprising an electron transport material;
depositing the active layer on the first interfacial layer;
depositing, on the active layer, a second interfacial layer comprising a hole transport material; and
depositing, on the second interfacial layer, a second conductive layer,
wherein the pressure is applied after the second conductive layer is deposited to increase the amount of contact between the layers.

17. The system of claim 11, wherein the photovoltaic device is annealed at a temperature between 140 and 160 Celsius.

18. A method for fabricating photovoltaic devices, the method comprising:
forming a photovoltaic device comprising an active layer comprising perovskite material and one or more interfacial layers adjacent the active layer, wherein the active layer comprises a photovoltaic material and the one or more interfacial layers comprise a material configured to collect charge carriers generated in the photovoltaic material;
applying pressure onto the photovoltaic device, the pressure being sufficient to deforms the active layer around one or more interlayer particles disposed between the active layer and the one or more interfacial layers to increase an amount of electrical contact between the active layer and the one or more interfacial layers; and
annealing the photovoltaic device.

19. The method of claim 18, wherein applying pressure between 5 and 10 MPA comprises applying a pressure of 7 MPa.

20. The method of claim 18, wherein the photovoltaic device is annealed at a temperature between 140 and 160 Celsius.
